(19) United States
(12) Patent Application Publication
(10) Pub. No.: US 2025/0072286 A1
(43) Pub. Date: Feb. 27, 2025

(54) POLYCYCLIC COMPOUND AND ORGANOELECTRO LUMINESCENT DEVICE USING THE SAME

(71) Applicant: SFC CO., LTD., Cheongju-si (KR)

(72) Inventors: Jin-hwi CHO, Cheongju-si (KR); So-young SHIM, Cheongju-si (KR)

(73) Assignee: SFC CO., LTD., Cheongju-si (KR)

(21) Appl. No.: 18/811,376

(22) Filed: Aug. 21, 2024

(30) Foreign Application Priority Data
Aug. 21, 2023 (KR) 10-2023-0109104
Jul. 22, 2024 (KR) 10-2024-0096646

(51) Int. Cl. H10K 85/60; C07F 5/02; C07F 19/00; C09K 11/02; C09K 11/06; H10K 50/12; H10K 85/40; H10K 101/00

(52) U.S. Cl. CPC H10K 85/658; C07F 5/027; C07F 19/00; C09K 11/02; C09K 11/06; H10K 85/40; C09K 2211/1007; C09K 2211/1011; C09K 2211/1014; C09K 2211/1022; H10K 50/12; H10K 2101/27

(57) ABSTRACT

The present invention relates to a polycyclic compound having a characteristic fused ring structure represented by the following [Formula 1], and a high-efficiency and long-lifetime organic electroluminescent device having excellent luminous efficiency and significantly improved lifetime and the like by employing the same in a light emitting layer in the organic electroluminescent device.

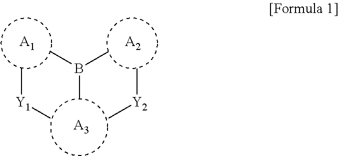

### TECHNICAL FIELD

The present invention relates to a polycyclic compound employed in an organic layer such as a light emitting layer in an organic electroluminescent device, and an organic electroluminescent device including the same.

### BACKGROUND ART

Organic electroluminescent devices are self-luminous devices in which electrons injected from an electron injecting electrode (cathode) recombine with holes injected from a hole injecting electrode (anode) in a light emitting layer to form excitons, which emit light while releasing energy. Such organic electroluminescent devices have the advantages of low driving voltage, high luminance, large viewing angle, and short response time and can be applied to full-color light emitting flat panel displays. Due to these advantages, organic electroluminescent devices have received attention as next-generation light sources.

The above characteristics of organic electroluminescent devices are achieved by structural optimization of organic layers of the devices and are supported by stable and efficient materials for the organic layers, such as hole injecting materials, hole transport materials, light emitting materials, electron transport materials, electron injecting materials, and electron blocking materials. However, more research still needs to be done to develop structurally optimized structures of organic layers for organic electroluminescent devices and stable and efficient materials for organic layers of organic electroluminescent devices.

Particularly, for maximum efficiency in a light emitting layer, an appropriate combination of energy band gaps of a host and a dopant is required such that holes and electrons migrate to the dopant through stable electrochemical paths to form excitons.

### DETAILED DESCRIPTION OF THE INVENTION

### Problems to be Solved by the Invention

Therefore, the present invention is intended to provide a polycyclic compound having a characteristic fused ring structure, and a high-efficiency and long-lifetime organic electroluminescent device having significantly improved luminous efficiency and lifetime by employing the same as a host or dopant material in a light emitting layer.

### Means for Solving the Problems

One aspect of the present invention provides a polycyclic compound represented by [Formula 1] having a characteristic fused ring structure as below, and an organic electroluminescent device including the same as a host or a dopant in a light emitting layer.

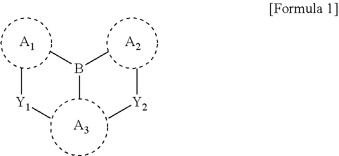

In [Formula 1], at least one of A₁ to A₃ is fused with the following [Structural Formula 1] to form a ring.

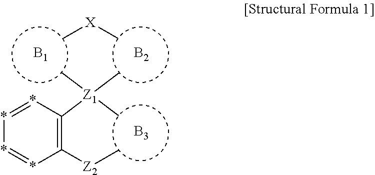

Specific structures of [Formula 1] and [Structural Formula 1], specific compounds according to the present invention obtained therefrom, and a definition of each substituent will be described later.

### Effects of the Invention

The present invention relates to a polycyclic compound having a characteristic fused ring structure, and an organic electroluminescent device employing the same as a host or a dopant of a light emitting layer. As a result, a high-efficiency and long-lifetime organic electroluminescent device can be obtained, which is useful for not only lighting devices but also a variety of display devices such as flat panel displays, flexible displays, wearable displays, displays for automotives or aircraft, and displays for virtual or augmented reality.

### BEST MODE FOR CARRYING OUT THE INVENTION

Hereinafter, the present invention will be described in more detail.

One aspect of the present invention relates to a polycyclic compound represented by the following [Formula 1].

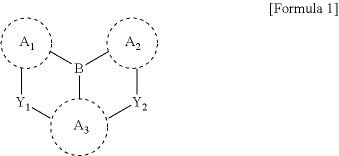

In [Formula 1],

Y₁ and Y₂ are the same as or different from each other, and each independently any one selected from O, S, NR₁, CR₂R₃, SiR₄R₅ and GeR₆R₇.

According to one embodiment of the present invention, Y₁ and Y₂ are the same as or different from each other, and may be each independently any one selected from NR₁, O and S.

A₁ to A₃ are the same as or different from each other, and each independently any one selected from substituted or unsubstituted C₆-C₃₀ aromatic hydrocarbon rings, substituted or unsubstituted C₃-C₃₀ aliphatic hydrocarbon rings, substituted or unsubstituted C₂-C₃₀ aromatic heterocyclic rings, substituted or unsubstituted C₂-C₃₀ aliphatic heterocyclic rings, and substituted or unsubstituted cyclic groups in which a C₃-C₂₄ aliphatic ring and a C₅-C₂₄ aromatic ring are fused together.

At least one of A₁ to A₃ is fused with the following [Structural Formula 1] to form a ring.

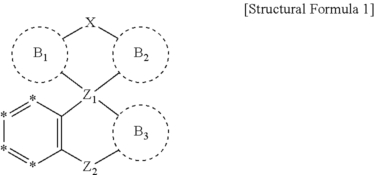

Herein, when A₁ is [Structural Formula 1], two adjacent ‘*’s are linked to B and Y₁ in [Formula 1] to form a ring, and when A₂ is [Structural Formula 1], two adjacent ‘*’s are linked to B and Y₂ in [Formula 1] to form a ring, and when A₃ is [Structural Formula 1], three adjacent ‘*’s are linked to B, Y₁ and Y₂ in [Formula 1] to form a ring.

In addition, the remaining ‘*’s not participating in the ring formation are each independently CR.

Rs are the same as or different from each other, and each independently any one selected from hydrogen, deuterium, substituted or unsubstituted C₁-C₃₀ alkyl, substituted or unsubstituted C₂-C₃₀ alkynyl, substituted or unsubstituted C₂-C₃₀ alkenyl, substituted or unsubstituted C₆-C₅₀ aryl, substituted or unsubstituted C₃-C₅₀ cycloalkyl, substituted or unsubstituted C₂-C₅₀ heterocycloalkyl, substituted or unsubstituted C₂-C₅₀ heteroaryl, substituted or unsubstituted cyclic groups in which a C₃-C₃₀ aliphatic ring and a C₅-C₃₀ aromatic ring are fused together, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted amine, substituted or unsubstituted silyl, substituted or unsubstituted germanium, nitro, cyano and halogen.

According to one embodiment of the present invention, R of the remaining ‘*’s not participating in the ring formation in [Structural Formula 1] may be hydrogen or deuterium.

According to one embodiment of the present invention, A₁ is [Structural Formula 1], and herein, A₂ and A₃ except A₁ are the same as or different from each other, and may be each independently any one selected from substituted or unsubstituted C₆-C₂₀ aromatic hydrocarbon rings, substituted or unsubstituted C₂-C₂₀ aromatic heterocyclic rings, and substituted or unsubstituted cyclic groups in which a C₃-C₁₄ aliphatic ring and a C₅-C₁₄ aromatic ring are fused together.

B₁ to B₃ are the same as or different from each other, and each independently any one selected from substituted or unsubstituted C₆-C₃₀ aromatic hydrocarbon rings, substituted or unsubstituted C₃-C₃₀ aliphatic hydrocarbon rings, substituted or unsubstituted C₂-C₃₀ aromatic heterocyclic rings, substituted or unsubstituted C₂-C₃₀ aliphatic heterocyclic rings, and substituted or unsubstituted cyclic groups in which a C₃-C₂₄ aliphatic ring and a C₅-C₂₄ aromatic ring are fused together.

According to one embodiment of the present invention, B₁ to B₃ in [Structural Formula 1] are the same as or different from each other, and may be each independently any one selected from substituted or unsubstituted C₆-C₂₀ aromatic hydrocarbon rings, substituted or unsubstituted C₂-C₂₀ aromatic heterocyclic rings, and substituted or unsubstituted cyclic groups in which a C₃-C₁₄ aliphatic ring and a C₅-C₁₄ aromatic ring are fused together.

X is any one selected from O, S, NR₈, CR₉R₁₀, SiR₁₁R₁₂ and GeR₁₃R₁₄, and, according to one embodiment of the present invention, may be any one selected from NR₈, O and S.

According to one embodiment of the present invention, X may be any one selected from O or S.

Z₁ is C or Si.

Z₂ is a single bond, or O or S.

According to one embodiment of the present invention, Z₁ is C, and at the same time, Z₂ may be a single bond.

R₁ to R₁₄ are the same as or different from each other, and each independently any one selected from hydrogen, deuterium, substituted or unsubstituted C₁-C₃₀ alkyl, substituted or unsubstituted C₂-C₃₀ alkynyl, substituted or unsubstituted C₂-C₃₀ alkenyl, substituted or unsubstituted C₆-C₅₀ aryl, substituted or unsubstituted C₃-C₅₀ cycloalkyl, substituted or unsubstituted C₂-C₅₀ heterocycloalkyl, substituted or unsubstituted C₂-C₅₀ heteroaryl, substituted or unsubstituted cyclic groups in which a C₃-C₃₀ aliphatic ring and a C₅-C₃₀ aromatic ring are fused together, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted amine, substituted or unsubstituted silyl, substituted or unsubstituted germanium, nitro, cyano and halogen.

In addition, R₁ to R₇ are each optionally linked to the rings A₁ to A₃ to further form an alicyclic or aromatic monocyclic or polycyclic ring.

In addition, R₂ and R₃, R₄ and R₅, R₆ and R₇, R₉ and R₁₀, R₁₁ and R₁₂, and R₁₃ and R₁₄ are optionally linked to each other to further form an alicyclic or aromatic monocyclic or polycyclic ring.

Meanwhile, the term ‘substituted’ in the ‘substituted or unsubstituted’ in [Formula 1] and [Structural Formula 1] means being substituted with one or more substituents selected from the group consisting of deuterium, C₁-C₂₄ alkyl, C₁-C₂₄ haloalkyl, C₂-C₂₄ alkenyl, C₂-C₂₄ alkynyl, C₃-C₃₀ cycloalkyl, C₁-C₂₄ heteroalkyl, C₆-C₃₀ aryl, C₇-C₃₀ arylalkyl, C₇-C₃₀ alkylaryl, C₂-C₃₀ heteroaryl, C₂-C₃₀ heteroarylalkyl, cyclic groups in which a C₃-C₂₄ aliphatic ring and a C₅-C₂₄ aromatic ring are fused together, C₁-C₂₄ alkoxy, C₁-C₃₀ amine, C₁-C₃₀ silyl, C₁-C₃₀ germanium, C₆-C₂₄ aryloxy, C₆-C₂₄ arylthionyl, cyano, halogen, hydroxyl and nitro, and when there are two or more substituents, they are the same as or different from each other, and one or more hydrogen atoms in each of the substituents are optionally substituted with deuterium atoms.

According to one embodiment of the present invention, [Formula 1] may be any one represented by the following [Formula A-1] to [Formula A-6].

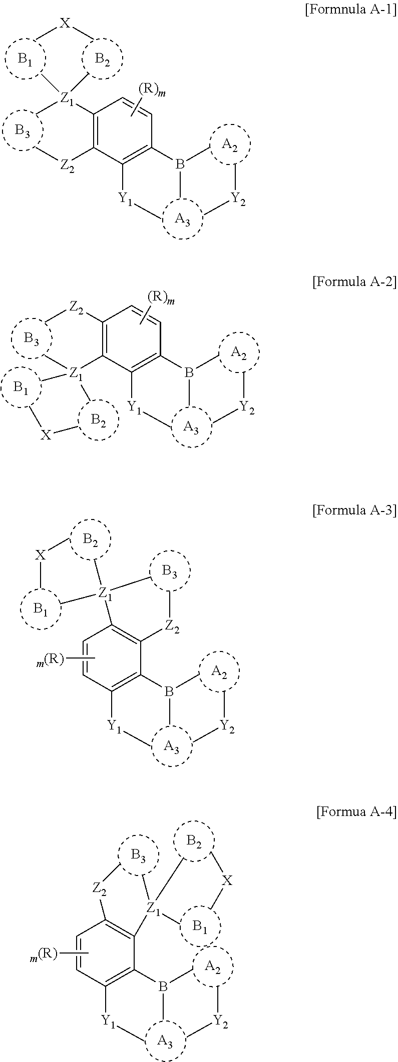

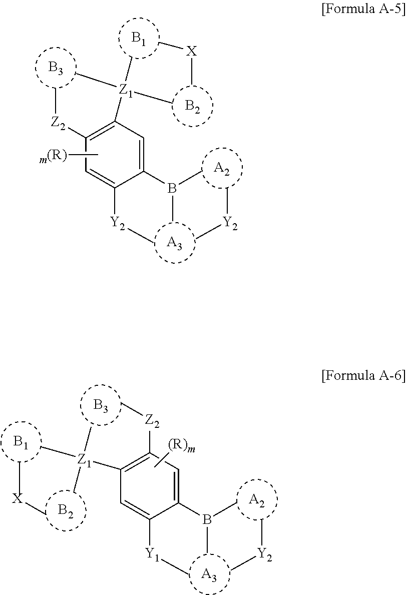

In [Formula A-1] to [Formula A-6],

Y₁ and Y₂ are the same as or different from each other, and each independently any one selected from O, S, NR₁, CR₂R₃, SiR₄R₅ and GeR₆R₇.

A₂ and A₃ are the same as or different from each other, and each independently any one selected from substituted or unsubstituted C₆-C₃₀ aromatic hydrocarbon rings, substituted or unsubstituted C₃-C₃₀ aliphatic hydrocarbon rings, substituted or unsubstituted C₂-C₃₀ aromatic heterocyclic rings, substituted or unsubstituted C₂-C₃₀ aliphatic heterocyclic rings, and substituted or unsubstituted cyclic groups in which a C₃-C₂₄ aliphatic ring and a C₅-C₂₄ aromatic ring are fused together.

B₁ to B₃ are the same as or different from each other, and each independently any one selected from substituted or unsubstituted C₆-C₃₀ aromatic hydrocarbon rings, substituted or unsubstituted C₃-C₃₀ aliphatic hydrocarbon rings, substituted or unsubstituted C₂-C₃₀ aromatic heterocyclic rings, substituted or unsubstituted C₂-C₃₀ aliphatic heterocyclic rings, and substituted or unsubstituted cyclic groups in which a C₃-C₂₄ aliphatic ring and a C₅-C₂₄ aromatic ring are fused together.

Z₁ is C or Si.

Z₂ is a single bond, or O or S.

X is any one selected from O, S, NR₈, CR₉R₁₀, SiR₁₁R₁₂ and GeR₁₃R₁₄.

R and R₁ to R₁₄ are the same as or different from each other, and each independently any one selected from hydrogen, deuterium, substituted or unsubstituted C₁-C₃₀ alkyl, substituted or unsubstituted C₂-C₃₀ alkynyl, substituted or unsubstituted C₂-C₃₀ alkenyl, substituted or unsubstituted C₆-C₅₀ aryl, substituted or unsubstituted C₃-C₅₀ cycloalkyl, substituted or unsubstituted C₂-C₅₀ heterocycloalkyl, substituted or unsubstituted C₂-C₅₀ heteroaryl, substituted or unsubstituted cyclic groups in which a C₃-C₃₀ aliphatic ring and a C₅-C₃₀ aromatic ring are fused together, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted amine, substituted or unsubstituted silyl, substituted or unsubstituted germanium, nitro, cyano and halogen.

m is an integer of 2, and Rs are the same as or different from each other.

R₁ to R₇ are each optionally linked to the rings A₂ and A₃ to further form an alicyclic or aromatic monocyclic or polycyclic ring.

R₂ and R₃, R₄ and R₅, R₆ and R₇, R₉ and R₁₀, R₁₁ and R₁₂, and R₁₃ and R₁₄ are optionally linked to each other to further form an alicyclic or aromatic monocyclic or polycyclic ring.

The term ‘substituted’ in the ‘substituted or unsubstituted’ in [Formula A-1] to [Formula A-6] has the same definition as in [Formula 1].

According to one embodiment of the present invention, [Formula 1] may be any one represented by the following [Formula B-1] to [Formula B-12].

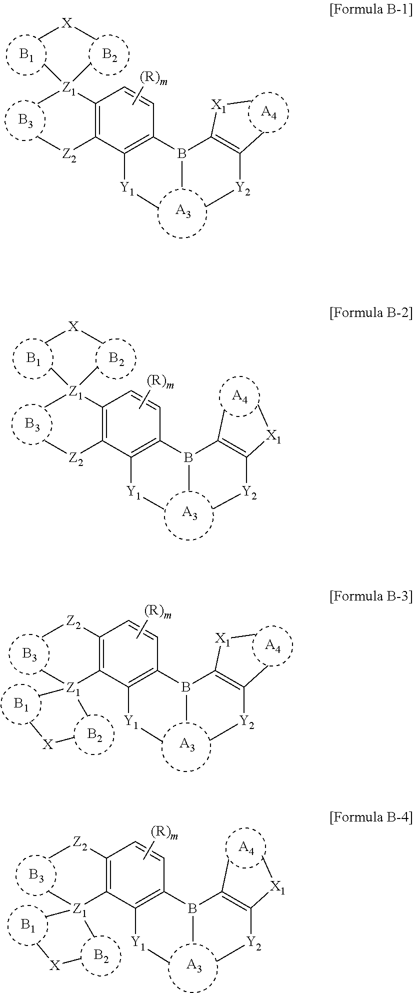

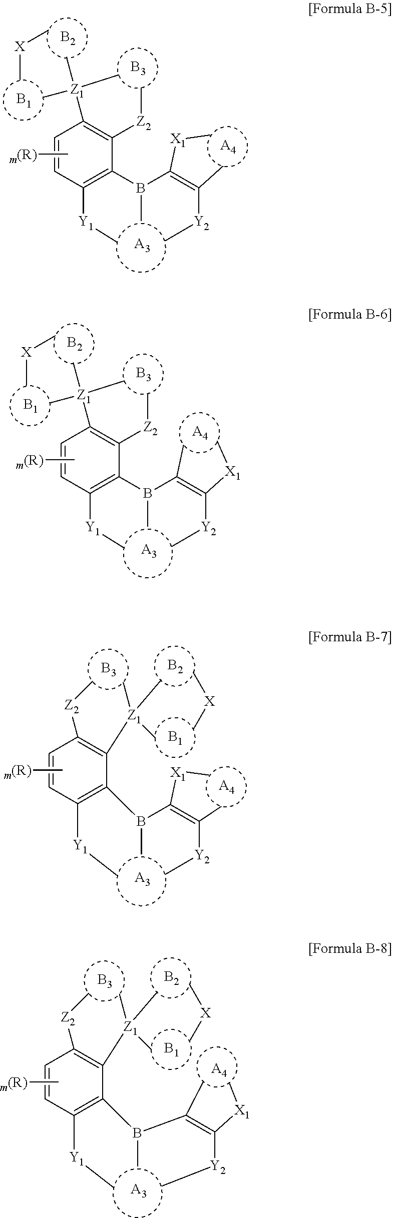

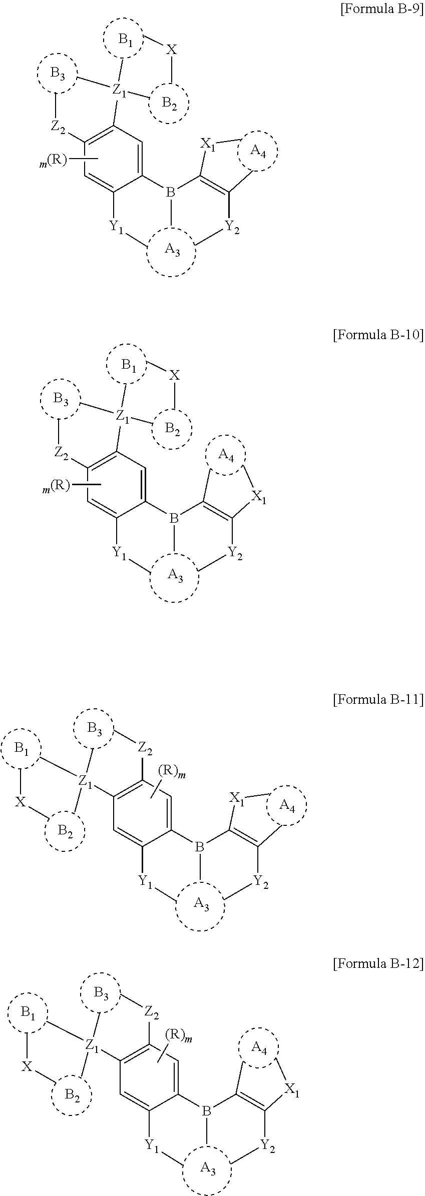

In [Formula B-1] to [Formula B-12],

Y₁ and Y₂ are the same as or different from each other, and each independently any one selected from O, S, NR₁, CR₂R₃, SiR₄R₅ and GeR₆R₇.

X₁ is O or S.

A₃ and A₄ are the same as or different from each other, and each independently any one selected from substituted or unsubstituted C₆-C₃₀ aromatic hydrocarbon rings, substituted or unsubstituted C₃-C₃₀ aliphatic hydrocarbon rings, substituted or unsubstituted C₂-C₃₀ aromatic heterocyclic rings, substituted or unsubstituted C₂-C₃₀ aliphatic heterocyclic rings, and substituted or unsubstituted cyclic groups in which a C₃-C₂₄ aliphatic ring and a C₅-C₂₄ aromatic ring are fused together.

B₁ to B₃ are the same as or different from each other, and each independently any one selected from substituted or unsubstituted C₆-C₃₀ aromatic hydrocarbon rings, substituted or unsubstituted C₃-C₃₀ aliphatic hydrocarbon rings, substituted or unsubstituted C₂-C₃₀ aromatic heterocyclic rings, substituted or unsubstituted C₂-C₃₀ aliphatic heterocyclic rings, and substituted or unsubstituted cyclic groups in which a C₃-C₂₄ aliphatic ring and a C₅-C₂₄ aromatic ring are fused together.

Z₁ is C or Si.

Z₂ is a single bond, or O or S.

X is any one selected from O, S, NR₈, CR₉R₁₀, SiR₁₁R₁₂ and GeR₁₃R₁₄.

R and R₁ to R₁₄ are the same as or different from each other, and each independently any one selected from hydrogen, deuterium, substituted or unsubstituted C₁-C₃₀ alkyl, substituted or unsubstituted C₂-C₃₀ alkynyl, substituted or unsubstituted C₂-C₃₀ alkenyl, substituted or unsubstituted C₆-C₅₀ aryl, substituted or unsubstituted C₃-C₅₀ cycloalkyl, substituted or unsubstituted C₂-C₅₀ heterocycloalkyl, substituted or unsubstituted C₂-C₅₀ heteroaryl, substituted or unsubstituted cyclic groups in which a C₃-C₃₀ aliphatic ring and a C₅-C₃₀ aromatic ring are fused together, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted amine, substituted or unsubstituted silyl, substituted or unsubstituted germanium, nitro, cyano and halogen.

m is an integer of 2, and Rs are the same as or different from each other.

R₁ to R₇ are each optionally linked to the rings A₃ and A₄ to further form an alicyclic or aromatic monocyclic or polycyclic ring.

R₂ and R₃, R₄ and R₅, R₆ and R₇, R₉ and R₁₀, R₁₁ and R₁₂, and R₁₃ and R₁₄ are optionally linked to each other to further form an alicyclic or aromatic monocyclic or polycyclic ring.

The term ‘substituted’ in the ‘substituted or unsubstituted’ in [Formula B-1] to [Formula B-12] has the same definition as in [Formula 1].

Meanwhile, in the “substituted or unsubstituted C₁-C₃₀ alkyl”, “substituted or unsubstituted C₆-C₅₀ aryl” and the like, the number of carbon atoms in the alkyl or aryl group indicates the number of carbon atoms constituting the unsubstituted alkyl or aryl moiety without considering the number of carbon atoms in the substituent(s). For example, a phenyl group substituted with a butyl group at the para-position corresponds to a C₆ aryl group substituted with a C₄ butyl group.

As used herein, the expression “optionally linked to each other or an adjacent group to form a ring” means that the corresponding adjacent substituents are bonded to each other or each of the corresponding substituents is bonded to an adjacent group to form a substituted or unsubstituted alicyclic or aromatic ring. The term “adjacent group” may mean a substituent on an atom directly attached to an atom substituted with the corresponding substituent, a substituent disposed sterically closest to the corresponding substituent or another substituent on an atom substituted with the corresponding substituent. For example, two substituents substituted at the ortho position of a benzene ring or two substituents on the same carbon in an aliphatic ring may be considered “adjacent” to each other. Optionally, the paired substituents each lose one hydrogen radical and are linked to each other to form a ring. The carbon atoms in the resulting alicyclic, aromatic mono- or polycyclic ring may be replaced by heteroatoms such as N, O, S, Si or Ge.

In the present invention, the alkyl groups may be straight or branched. Specific examples of the alkyl groups include, but are not limited to, methyl, ethyl, propyl, n-propyl, isopropyl, butyl, n-butyl, isobutyl, tert-butyl, sec-butyl, 1-methylbutyl, 1-ethylbutyl, pentyl, n-pentyl, isopentyl, neopentyl, tert-pentyl, hexyl, n-hexyl, 1-methylpentyl, 2-methylpentyl, 4-methyl-2-pentyl, 3,3-dimethylbutyl, 2-ethylbutyl, heptyl, n-heptyl, 1-methylhexyl, cyclopentylmethyl, cyclohexylmethyl, octyl, n-octyl, tert-octyl, 1-methylheptyl, 2-ethylhexyl, 2-propylpentyl, n-nonyl, 2,2-dimethylheptyl, 1-ethylpropyl, 1,1-dimethylpropyl, isohexyl, 2-methylpentyl, 4-methylhexyl, and 5-methylhexyl groups.

In the present invention, specific examples of the arylalkyl groups include, but are not limited to, phenylmethyl(benzyl), phenylethyl, phenylpropyl, naphthylmethyl, and naphthylethyl.

In the present invention, specific examples of the alkylaryl groups include, but are not limited to, tolyl, xylenyl, dimethylnaphthyl, t-butylphenyl, t-butylnaphthyl, and t-butylphenanthryl.

The alkenyl group is intended to include straight and branched ones and may be optionally substituted with one or more other substituents. The alkenyl group may be specifically a vinyl, 1-propenyl, isopropenyl, 1-butenyl, 2-butenyl, 3-butenyl, 1-pentenyl, 2-pentenyl, 3-pentenyl, 3-methyl-1-butenyl, 1,3-butadienyl, allyl, 1-phenylvinyl-1-yl, 2-phenylvinyl-1-yl, 2,2-diphenylvinyl-1-yl, 2-phenyl-2-(naphthyl-1-yl)vinyl-1-yl, 2,2-bis(diphenyl-1-yl)vinyl-1-yl, stilbenyl or styrenyl group but is not limited thereto.

The alkynyl group is intended to include straight and branched ones and may be optionally substituted with one or more other substituents. The alkynyl group may be, for example, ethynyl or 2-propynyl but is not limited thereto.

The cycloalkenyl group is a non-aromatic cyclic unsaturated hydrocarbon group having one or more carbon-carbon double bonds. The cycloalkenyl group may be, for example, cyclopropenyl, cyclobutenyl, cyclopentenyl, cyclohexenyl, cycloheptenyl, 1,3-cyclohexadienyl, 1,4-cyclohexadienyl, 2,4-cycloheptadienyl or 1,5-cyclooctadienyl but is not limited thereto.

The aromatic hydrocarbon rings or aryl groups may be monocyclic or polycyclic ones. As used herein, the term “polycyclic” means that the aromatic hydrocarbon ring may be directly attached or fused to one or more other cyclic groups. The other cyclic groups may be aromatic hydrocarbon rings and other examples thereof include aliphatic heterocyclic rings, aliphatic hydrocarbon rings, and aromatic heterocyclic rings. Examples of the monocyclic aryl groups include, but are not limited to, phenyl, biphenyl, and terphenyl. Examples of the polycyclic aryl groups include naphthyl, anthracenyl, phenanthrenyl, pyrenyl, perylenyl, tetracenyl, chrysenyl, fluorenyl, acenaphathcenyl, triphenylene, and fluoranthrene groups but the scope of the present invention is not limited thereto.

The aromatic heterocyclic rings or heteroaryl groups refer to aromatic groups containing one or more heteroatoms such as O, S, N, P, Si, and Ge. Examples of the aromatic heterocyclic rings or heteroaryl groups include, but are not limited to, thiophene, furan, pyrrole, imidazole, thiazole, oxazole, oxadiazole, triazole, pyridyl, bipyridyl, pyrimidyl, triazine, triazole, acridyl, pyridazine, pyrazinyl, quinolinyl, quinazoline, quinoxalinyl, phthalazinyl, pyridopyrimidinyl, pyridopyrazinyl, pyrazinopyrazinyl, isoquinoline, indole, carbazole, benzoxazole, benzimidazole, benzothiazole, benzocarbazole, benzothiophene, dibenzothiophene, benzofuranyl, dibenzofuranyl, phenanthroline, thiazolyl, isoxazolyl, oxadiazolyl, thiadiazolyl, benzothiazolyl, and phenothiazinyl groups.

The aliphatic hydrocarbon rings or cycloalkyl groups refer to non-aromatic rings consisting only of carbon and hydrogen atoms. The aliphatic hydrocarbon ring is intended to include monocyclic and polycyclic ones and may be optionally substituted with one or more other substituents. As used herein, the term “polycyclic” means that the aliphatic hydrocarbon ring may be directly attached or fused to one or more other cyclic groups. The other cyclic groups may be aliphatic hydrocarbon rings and other examples thereof include aliphatic heterocyclic, aryl, and heteroaryl groups. Specific examples of the aliphatic hydrocarbon rings include, but are not limited to, cycloalkyl groups such as cyclopropyl, cyclobutyl, cyclopentyl, adamantyl, 3-methylcyclopentyl, 2,3-dimethylcyclopentyl, cyclohexyl, 3-methylcyclohexyl, 4-methylcyclohexyl, 2,3-dimethylcyclohexyl, 3,4,5-trimethylcyclohexyl, 4-tert-butylcyclohexyl, cycloheptyl, and cyclooctyl, cycloalkanes such as cyclohexane and cyclopentane, and cycloalkenes such as cyclohexene and cyclobutene.

The aliphatic heterocyclic rings or heterocycloalkyl groups refer to aliphatic rings containing one or more heteroatoms such as O, S, Se, N, Si and Ge. The aliphatic heterocyclic ring is intended to include monocyclic or polycyclic ones and may be optionally substituted with one or more other substituents. As used herein, the term “polycyclic” means that the aliphatic heterocyclic ring such as heterocycloalkyl, heterocycloalkane or heterocycloalkene may be directly attached or fused to one or more other cyclic groups. The other cyclic groups may be aliphatic heterocyclic rings and other examples thereof include aliphatic hydrocarbon rings, aryl groups, and heteroaryl groups.

The cyclic groups in which an aliphatic ring and an aromatic ring are fused together refers to mixed aliphatic-aromatic cyclic groups in which at least one aliphatic ring and at least one aromatic ring are linked and fused together and which are overall non-aromatic. More specifically, the cyclic groups in which an aliphatic ring and an aromatic ring are fused together may be an aromatic hydrocarbon cyclic group fused with an aliphatic hydrocarbon ring, an aromatic hydrocarbon cyclic group fused with an aliphatic heterocyclic ring, an aromatic heterocyclic group fused with an aliphatic hydrocarbon ring, an aromatic heterocyclic group fused with an aliphatic heterocyclic ring, an aliphatic hydrocarbon cyclic group fused with an aromatic hydrocarbon ring, an aliphatic hydrocarbon cyclic group fused with an aromatic hydrocarbon ring, an aliphatic heterocyclic group fused with an aromatic hydrocarbon ring, and an aliphatic heterocyclic group fused with an aromatic heterocyclic ring. Specific examples of the cyclic groups in which an aliphatic ring and an aromatic ring are fused together include tetrahydronaphthyl, tetrahydrobenzocycloheptene, tetrahydrophenanthrene, tetrahydroanthracenyl, octahydrotriphenylene, tetrahydrobenzothiophene, tetrahydrobenzofuranyl, tetrahydrocarbazole, and tetrahydroquinoline. In addition, the cyclic groups in which an aliphatic ring and an aromatic ring are fused together may be substituted by heteroatoms such as O, S, N, P, Si or Ge other than carbon.

The alkoxy group may be specifically a methoxy, ethoxy, propoxy, isobutyloxy, sec-butyloxy, pentyloxy, iso-amyloxy or hexyloxy group but is not limited thereto.

The silyl group is intended to include —SiH₃, alkylsilyl, arylsilyl, alkylarylsilyl, arylheteroarylsilyl, and heteroarylsilyl. The arylsilyl refers to a silyl group obtained by substituting one, two or three of the hydrogen atoms in —SiH₃ with aryl groups. The alkylsilyl refers to a silyl group obtained by substituting one, two or three of the hydrogen atoms in —SiH₃ with alkyl groups. The alkylarylsilyl refers to a silyl group obtained by substituting one of the hydrogen atoms in —SiH₃ with an alkyl group and the other two hydrogen atoms with aryl groups or substituting two of the hydrogen atoms in —SiH₃ with alkyl groups and the remaining hydrogen atom with an aryl group. The arylheteroarylsilyl refers to a silyl group obtained by substituting one of the hydrogen atoms in —SiH₃ with an aryl group and the other two hydrogen atoms with heteroaryl groups or substituting two of the hydrogen atoms in —SiH₃ with aryl groups and the remaining hydrogen atom with a heteroaryl group. The heteroarylsilyl refers to a silyl group obtained by substituting one, two or three of the hydrogen atoms in —SiH₃ with heteroaryl groups. The arylsilyl group may be, for example, substituted or unsubstituted monoarylsilyl, substituted or unsubstituted diarylsilyl, or substituted or unsubstituted triarylsilyl. The same applies to the alkylsilyl and heteroarylsilyl groups.

Each of the aryl groups in the arylsilyl, heteroarylsilyl, and arylheteroarylsilyl groups may be a monocyclic or polycyclic one. Each of the heteroaryl groups in the arylsilyl, heteroarylsilyl, and arylheteroarylsilyl groups may be a monocyclic or polycyclic one.

Specific examples of the silyl groups include trimethylsilyl, triethylsilyl, triphenylsilyl, trimethoxysilyl, dimethoxyphenylsilyl, diphenylmethylsilyl, diphenylvinylsilyl, methylcyclobutylsilyl, and dimethylfurylsilyl. One or more of the hydrogen atoms in each of the silyl groups may be substituted with the substituents mentioned in the aryl groups.

The amine group is intended to include —NH₂, alkylamine, arylamine, arylheteroarylamine, and heteroarylamine. The arylamine refers to an amine group obtained by substituting one or two of the hydrogen atoms in —NH₂ with aryl groups. The alkylamine refers to an amine group obtained by substituting one or two of the hydrogen atoms in —NH₂ with alkyl groups. The alkylarylamine refers to an amine group obtained by substituting one of the hydrogen atoms in —NH₂ with an alkyl group and the other hydrogen atom with an aryl group. The arylheteroarylamine refers to an amine group obtained by substituting one of the hydrogen atoms in —NH₂ with an aryl group and the other hydrogen atom with a heteroaryl group. The heteroarylamine refers to an amine group obtained by substituting one or two of the hydrogen atoms in —NH₂ with heteroaryl groups. The arylamine may be, for example, substituted or unsubstituted monoarylamine, substituted or unsubstituted diarylamine, or substituted or unsubstituted triarylamine. The same applies to the alkylamine and heteroarylamine groups.

Each of the aryl groups in the arylamine, heteroarylamine, and arylheteroarylamine groups may be a monocyclic or polycyclic one. Each of the heteroaryl groups in the arylamine, heteroarylamine, and arylheteroarylamine groups may be a monocyclic or polycyclic one.

The germanium group is intended to include —GeH₃, alkylgermanium, arylgermanium, heteroarylgermanium, alkylarylgermanium, alkylheteroarylgermanium, and arylheteroarylgermanium. The definitions of the substituents in the germanium groups follow those described for the silyl groups, except that the silicon (Si) atom in each silyl group is changed to a germanium (Ge) atom.

Specific examples of the germanium groups include trimethylgermane, triethylgermane, triphenylgermane, trimethoxygermane, dimethoxyphenylgermane, diphenylmethylgermane, diphenylvinylgermane, methylcyclobutylgermane, and dimethylfurylgermane. One or more of the hydrogen atoms in each of the germanium groups may be substituted with the substituents mentioned in the aryl groups.

The cycloalkyl, aryl, and heteroaryl groups in the cycloalkyloxy, aryloxy, heteroaryloxy, cycloalkylthioxy, arylthioxy, and heteroarylthioxy groups are the same as those exemplified above. Specific examples of the aryloxy groups include, but are not limited to, phenoxy, p-tolyloxy, m-tolyloxy, 3,5-dimethylphenoxy, 2,4,6-trimethylphenoxy, p-tert-butylphenoxy, 3-biphenyloxy, 4-biphenyloxy, 1-naphthyloxy, 2-naphthyloxy, 4-methyl-1-naphthyloxy, 5-methyl-2-naphthyloxy, 1-anthryloxy, 2-anthryloxy, 9-anthryloxy, 1-phenanthryloxy, 3-phenanthryloxy, and 9-phenanthryloxy groups. Specific examples of the arylthioxy groups include, but are not limited to, phenylthioxy, 2-methylphenylthioxy, and 4-tert-butylphenylthioxy groups.

The halogen group may be, for example, fluorine, chlorine, bromine or iodine.

According to one embodiment of the present invention, the polycyclic compound represented by [Formula 1] may be any one selected from compounds represented by the following formulae, but is not limited thereto.

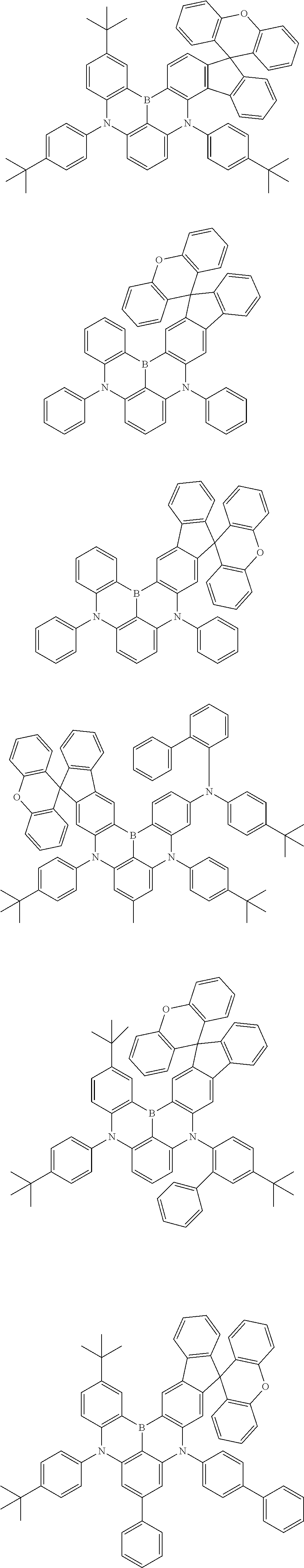

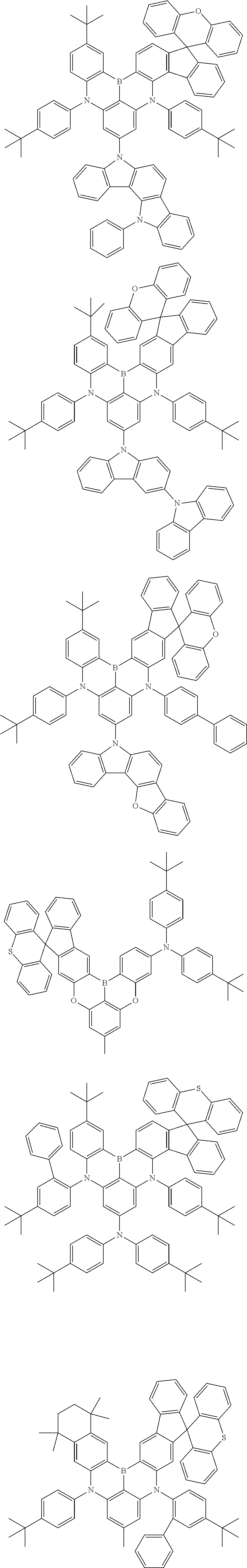

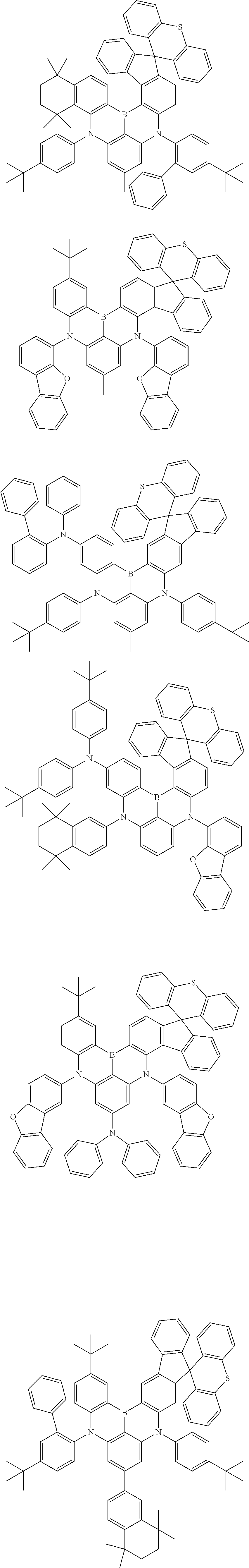

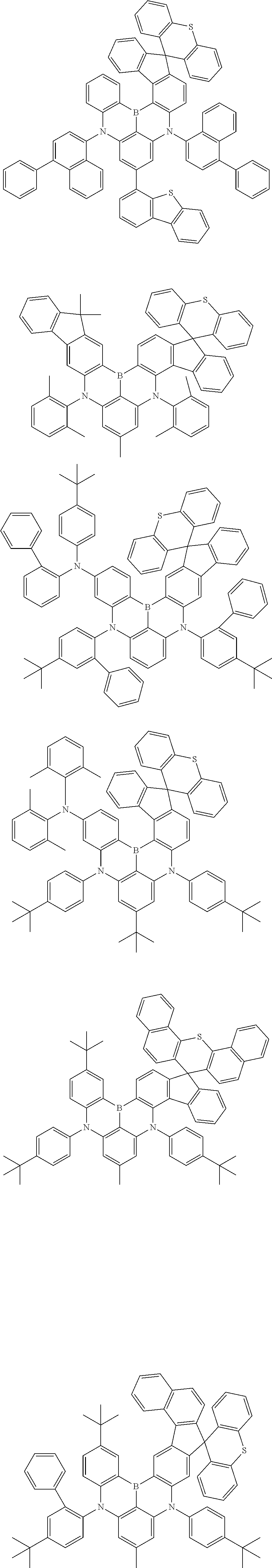

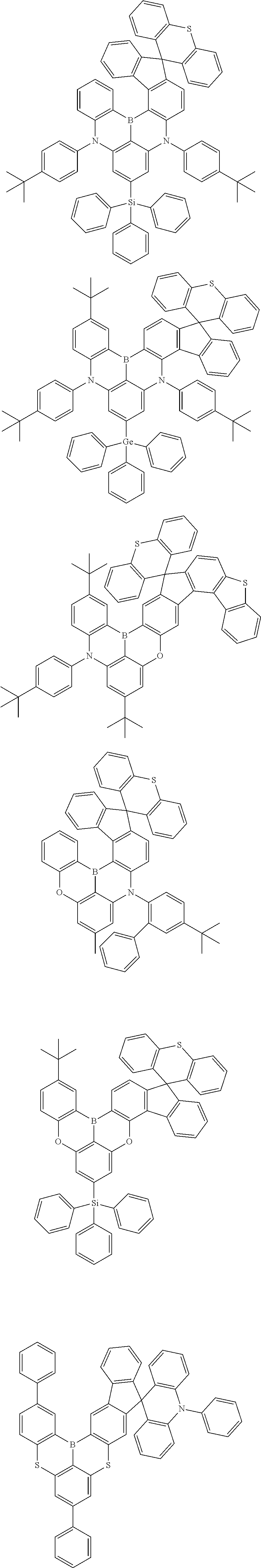

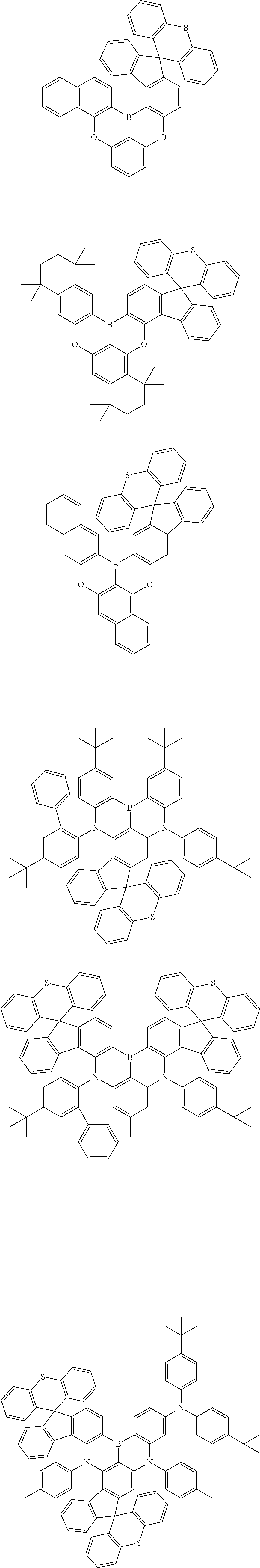

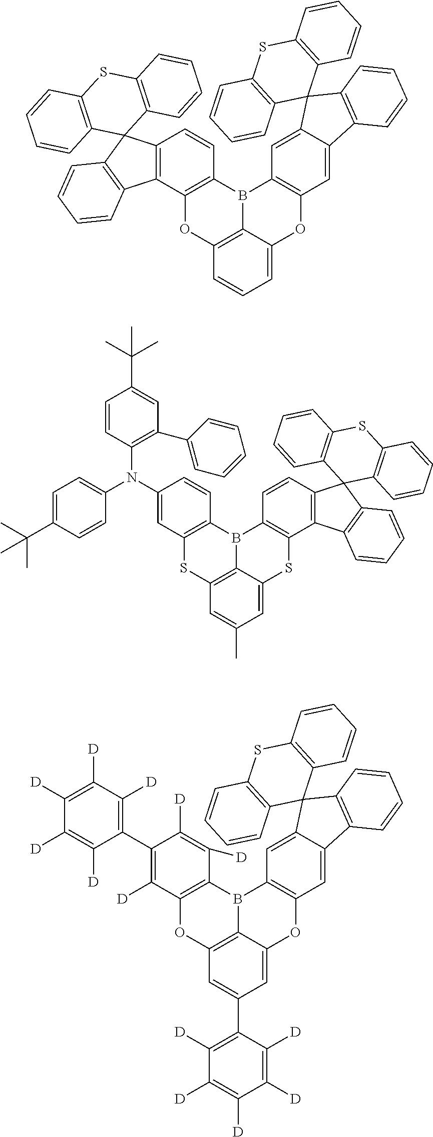 [SMILES: c1cc2c3c(c1)Oc1c(ccc4c1-c1ccccc1C41c4ccccc4Sc4ccccc41)B3c1cc3c(cc1O2)-c1ccccc1C31c2ccccc2Sc2ccccc21 ; Cc1cc2c3c(c1)Sc1c(ccc4c1-c1ccccc1C41c4ccccc4Sc4ccccc41)B3c1ccc(N(c3ccc(C(C)(C)C)cc3)c3ccc(C(C)(C)C)cc3-c3ccccc3)cc1S2 ; [2H]c1c([2H])c([2H])c(-c2cc3c4c(c2)Oc2c([2H])c(-c5c([2H])c([2H])c([2H])c([2H])c5[2H])c([2H])c([2H])c2B4c2cc4c(cc2O3)-c2ccccc2C42c3ccccc3Sc3ccccc32)c([2H])c1[2H]]

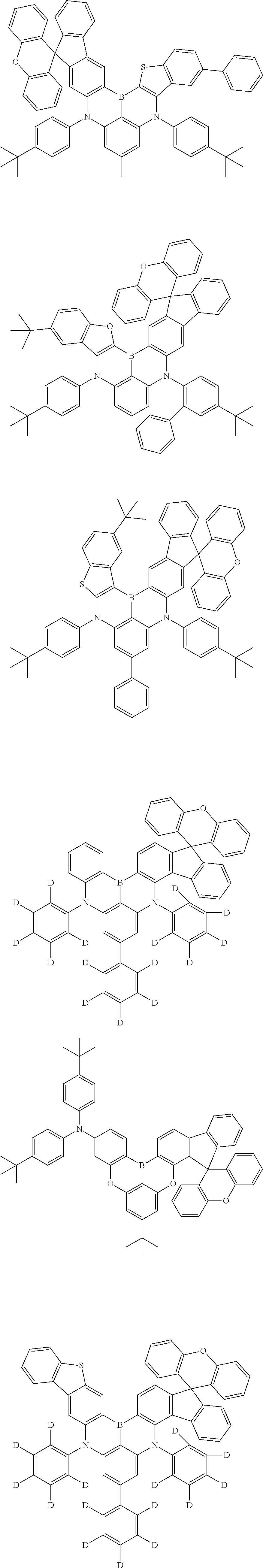

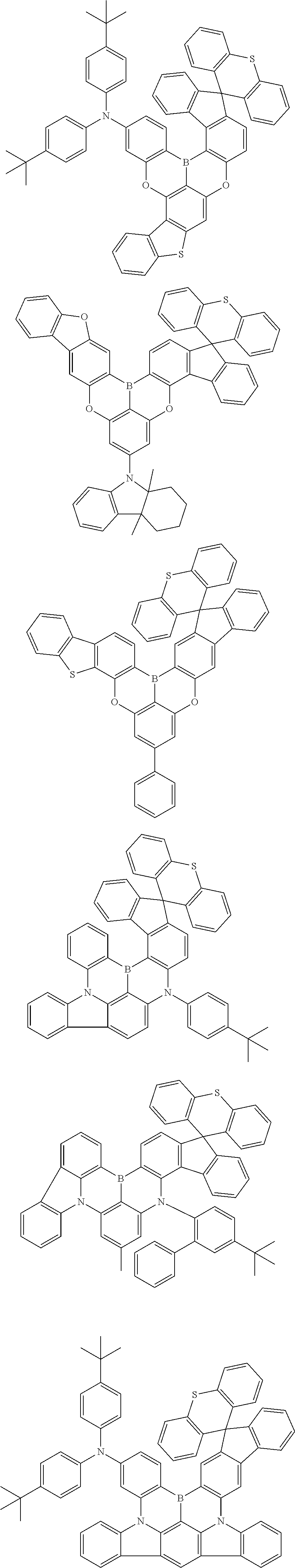

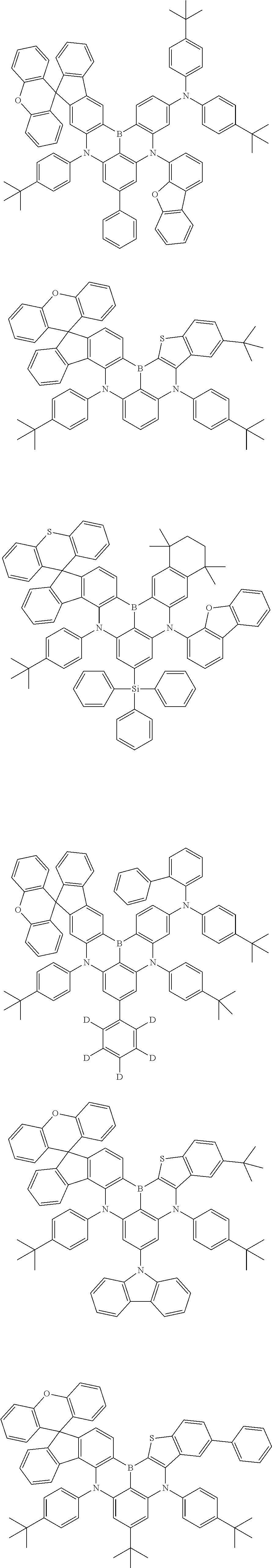

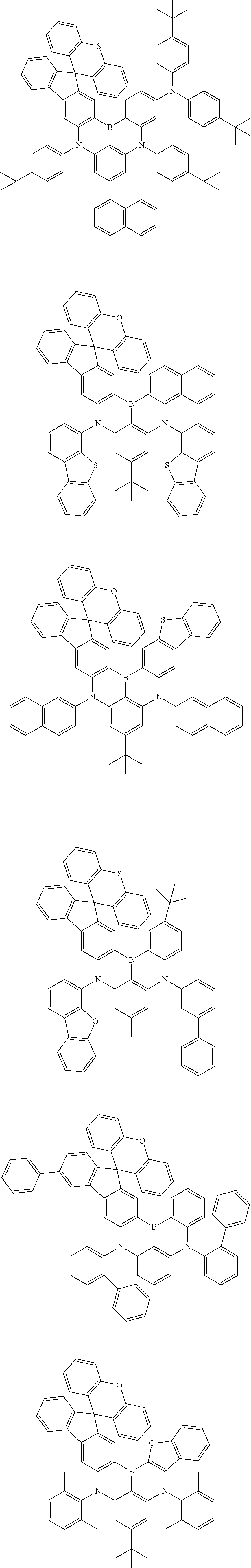

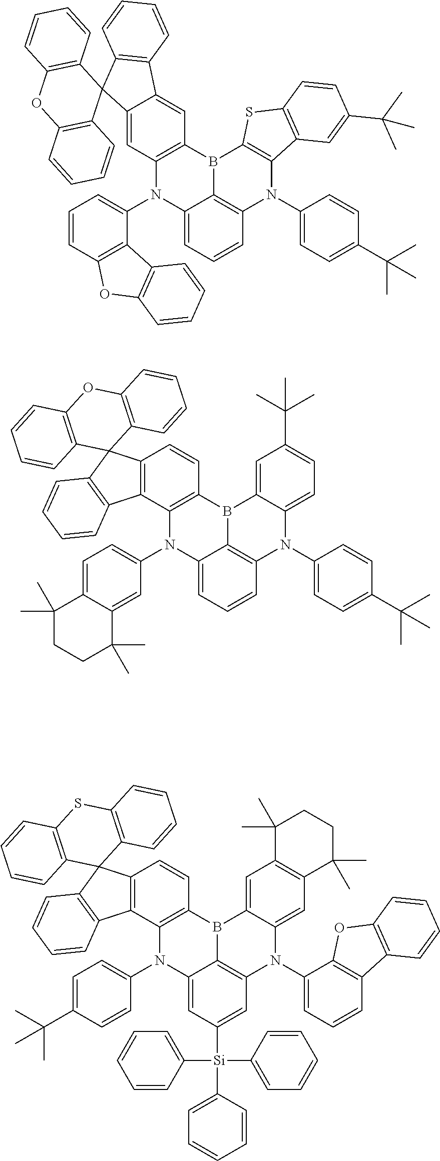 [SMILES: CC(C)(C)c1ccc(N2c3cccc4c3B(c3cc5c(cc3N4c3cccc4oc6ccccc6c34)C3(c4ccccc4Oc4ccccc43)c3ccccc3-5)c3sc4ccc(C(C)(C)C)cc4c32)cc1 ; CC(C)(C)c1ccc(N2c3ccc(C(C)(C)C)cc3B3c4ccc5c(c4N(c4ccc6c(c4)C(C)(C)CCC6(C)C)c4cccc2c43)-c2ccccc2C52c3ccccc3Oc3ccccc32)cc1 ; CC(C)(C)c1ccc(N2c3cc([Si](c4ccccc4)(c4ccccc4)c4ccccc4)cc4c3B(c3cc5c(cc3N4c3cccc4c3oc3ccccc34)C(C)(C)CCC5(C)C)c3ccc4c(c32)-c2ccccc2C42c3ccccc3Sc3ccccc32)cc1]

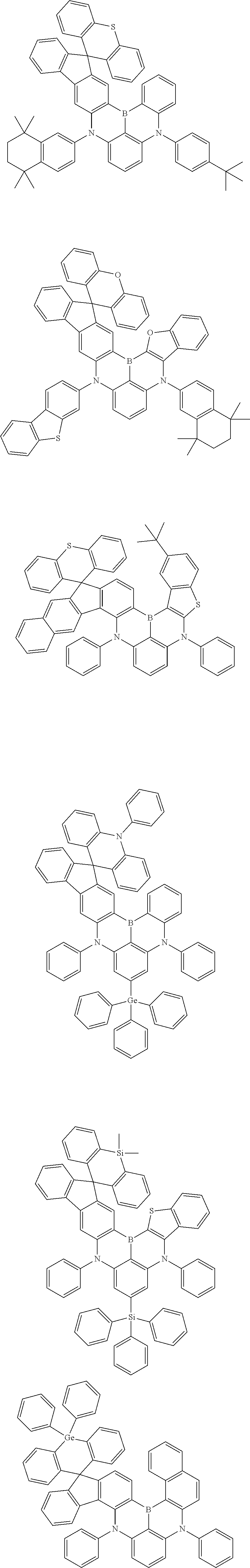

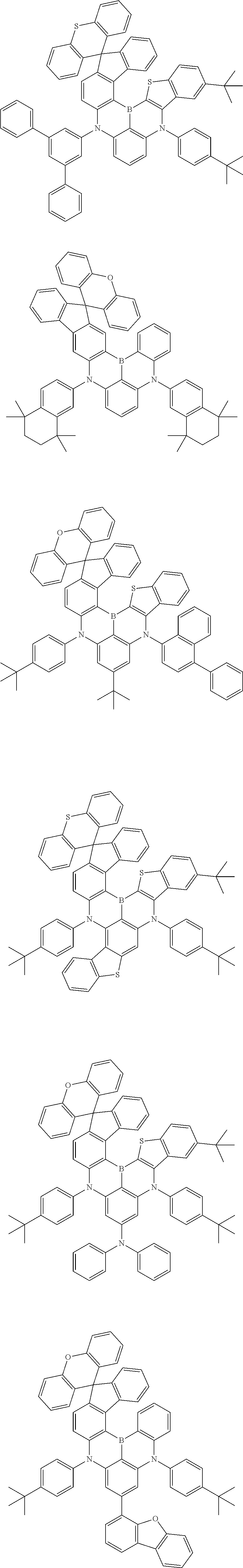

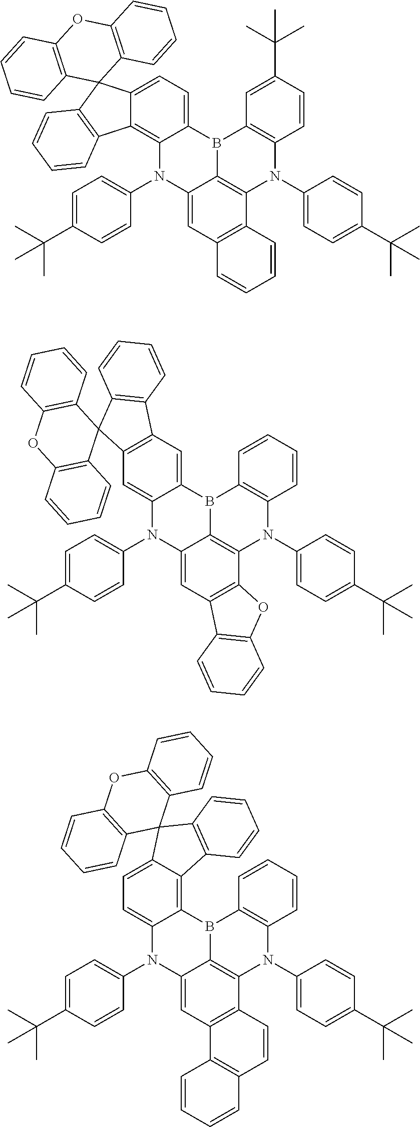

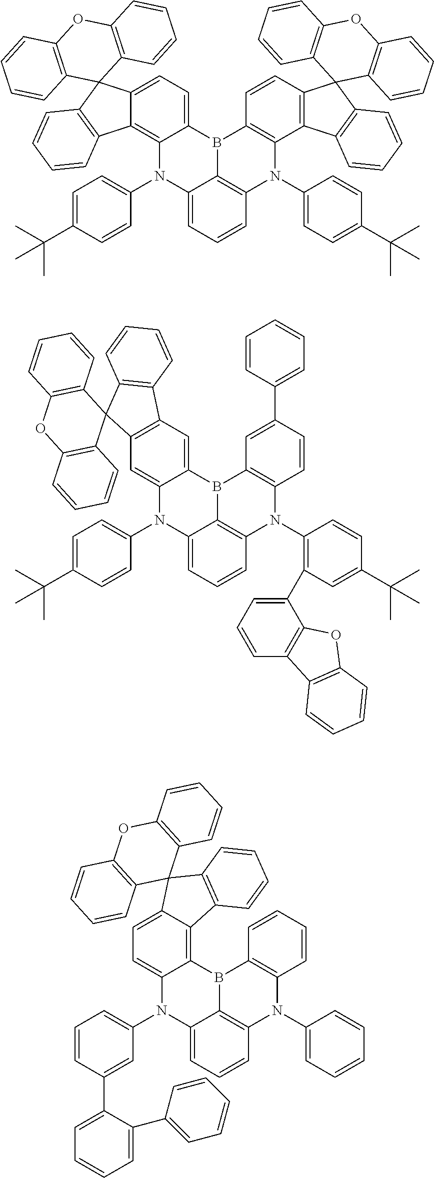 [SMILES: CC(C)(C)c1ccc(N2c3cccc4c3B(c3ccc5c(c32)-c2ccccc2C52c3ccccc3Oc3ccccc32)c2ccc3c(c2N4c2ccc(C(C)(C)C)cc2)-c2ccccc2C32c3ccccc3Oc3ccccc32)cc1 ; CC(C)(C)c1ccc(N2c3cc4c(cc3B3c5cc(-c6ccccc6)ccc5N(c5ccc(C(C)(C)C)cc5-c5cccc6c5oc5ccccc56)c5cccc2c53)-c2ccccc2C42c3ccccc3Oc3ccccc32)cc1 ; c1ccc(-c2ccccc2-c2cccc(N3c4cccc5c4B(c4ccccc4N5c4ccccc4)c4c3ccc3c4-c4ccccc4C34c3ccccc3Oc3ccccc34)c2)cc1]

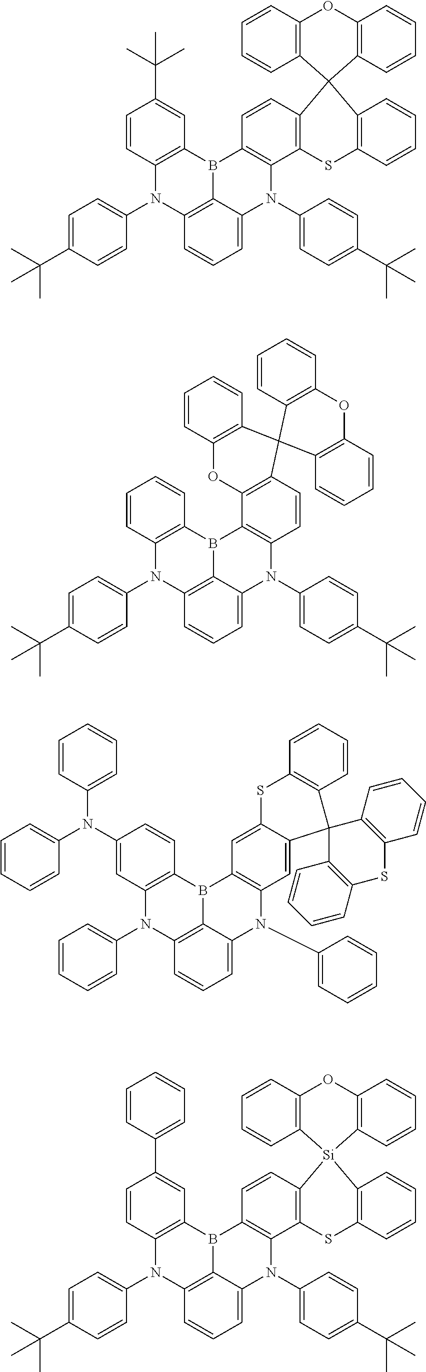

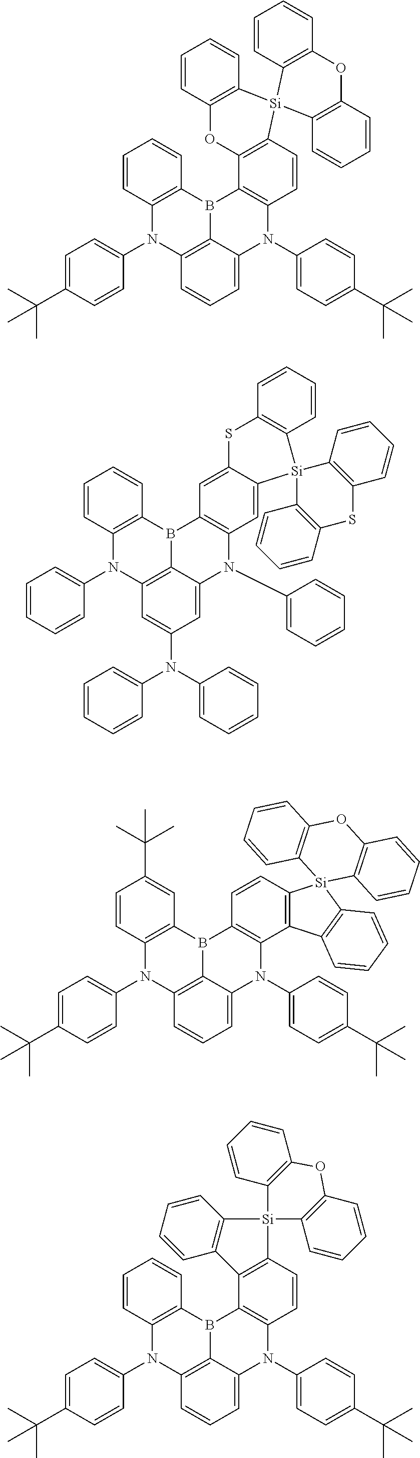

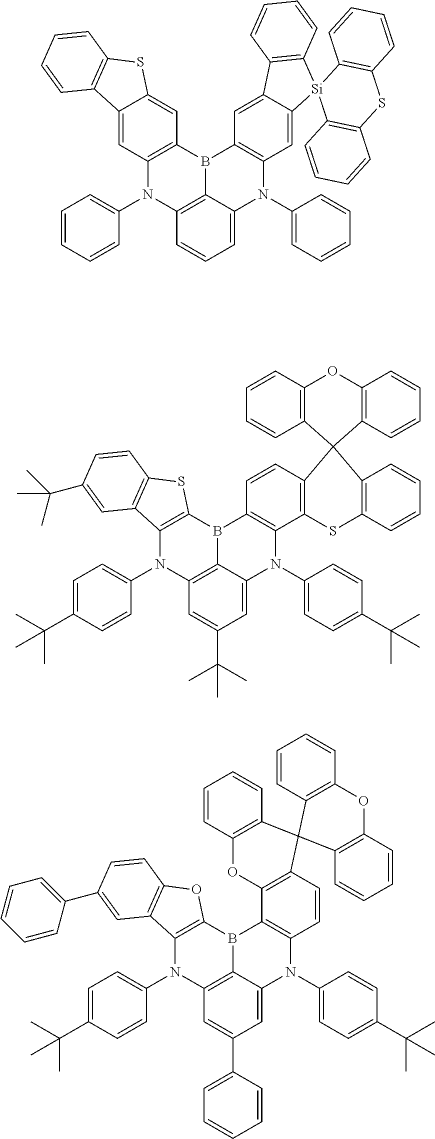 [SMILES: c1ccc(N2c3cc4c(cc3B3c5cc6sc7ccccc7c6cc5N(c5ccccc5)c5cccc2c53)-c2ccccc2[Si]42c3ccccc3Sc3ccccc32)cc1 ; CC(C)(C)c1ccc(N2c3cc(C(C)(C)C)cc4c3B(c3ccc5c(c32)Sc2ccccc2C52c3ccccc3Oc3ccccc32)c2sc3ccc(C(C)(C)C)cc3c2N4c2ccc(C(C)(C)C)cc2)cc1 ; CC(C)(C)c1ccc(N2c3cc(-c4ccccc4)cc4c3B(c3oc5ccc(-c6ccccc6)cc5c3N4c3ccc(C(C)(C)C)cc3)c3c2ccc2c3Oc3ccccc3C23c2ccccc2Oc2ccccc23)cc1]

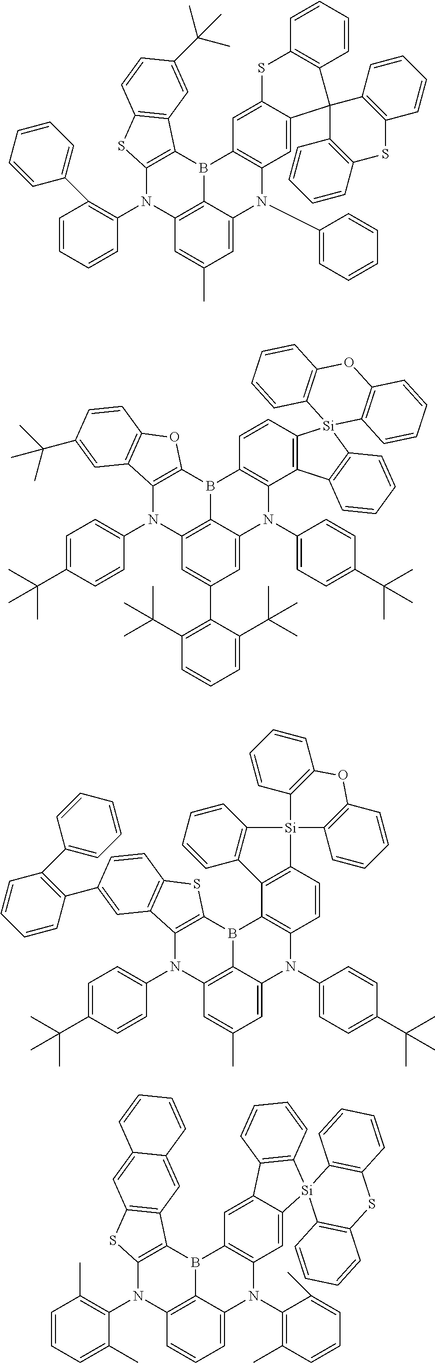

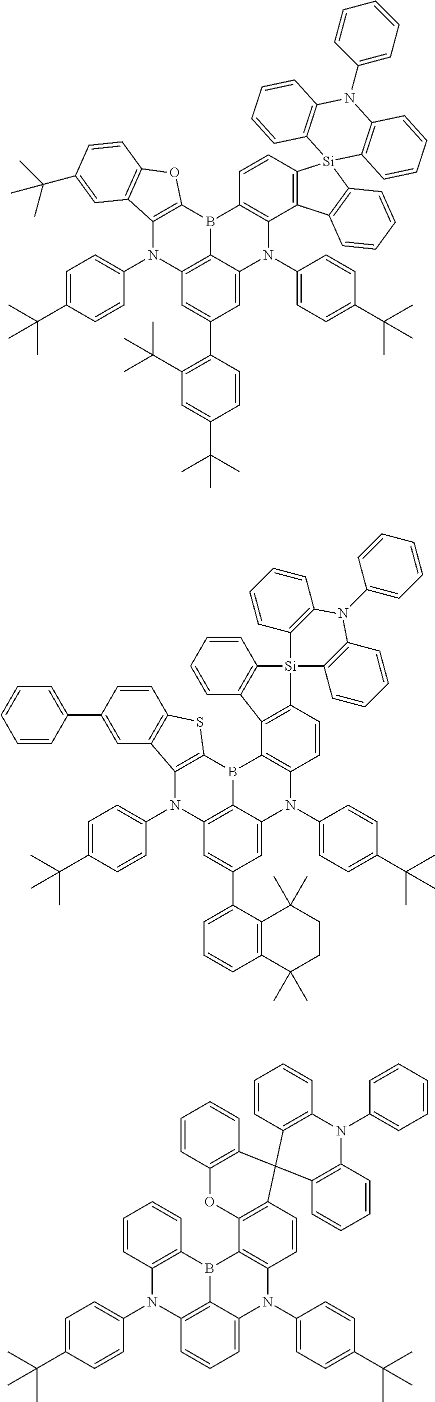

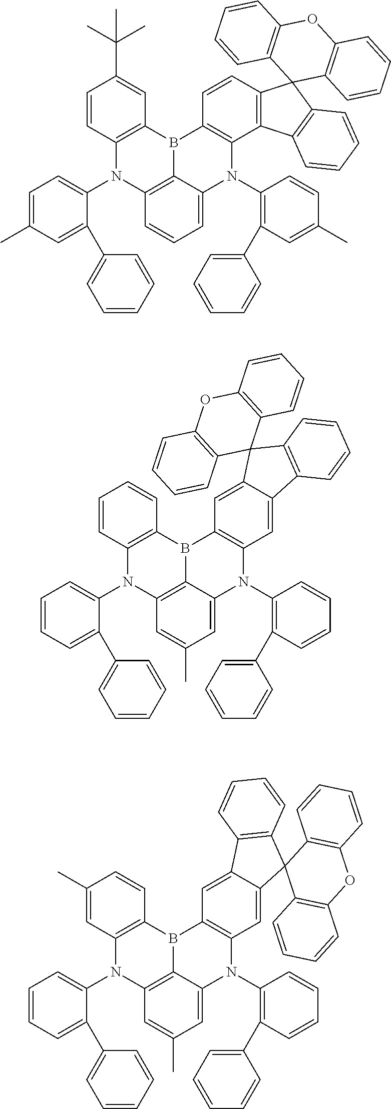 [SMILES: Cc1ccc(N2c3ccc(C(C)(C)C)cc3B3c4ccc5c(c4N(c4ccc(C)cc4-c4ccccc4)c4cccc2c43)-c2ccccc2C52c3ccccc3Oc3ccccc32)c(-c2ccccc2)c1 ; Cc1cc2c3c(c1)N(c1ccccc1-c1ccccc1)c1cc4c(cc1B3c1ccccc1N2c1ccccc1-c1ccccc1)C1(c2ccccc2Oc2ccccc21)c1ccccc1-4 ; Cc1ccc2c(c1)N(c1ccccc1-c1ccccc1)c1cc(C)cc3c1B2c1cc2c(cc1N3c1ccccc1-c1ccccc1)C1(c3ccccc3Oc3ccccc31)c1ccccc1-2]

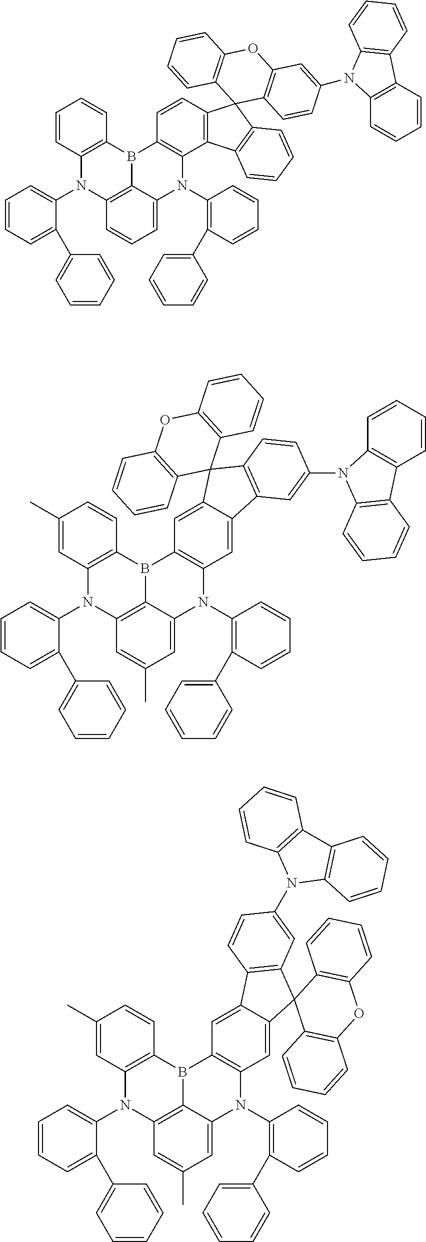 [SMILES: c1ccc(-c2ccccc2N2c3ccccc3B3c4ccc5c(c4N(c4ccccc4-c4ccccc4)c4cccc2c43)-c2ccccc2C52c3ccccc3Oc3cc(-n4c5ccccc5c5ccccc54)ccc32)cc1 ; Cc1ccc2c(c1)N(c1ccccc1-c1ccccc1)c1cc(C)cc3c1B2c1cc2c(cc1N3c1ccccc1-c1ccccc1)-c1cc(-n3c4ccccc4c4ccccc43)ccc1C21c2ccccc2Oc2ccccc21 ; Cc1ccc2c(c1)N(c1ccccc1-c1ccccc1)c1cc(C)cc3c1B2c1cc2c(cc1N3c1ccccc1-c1ccccc1)C1(c3ccccc3Oc3ccccc31)c1cc(-n3c4ccccc4c4ccccc43)ccc1-2]

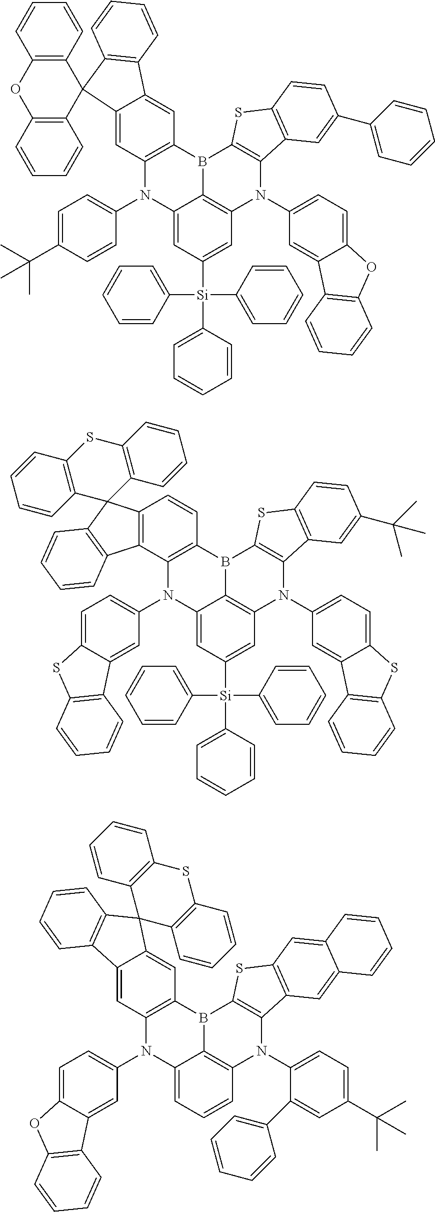

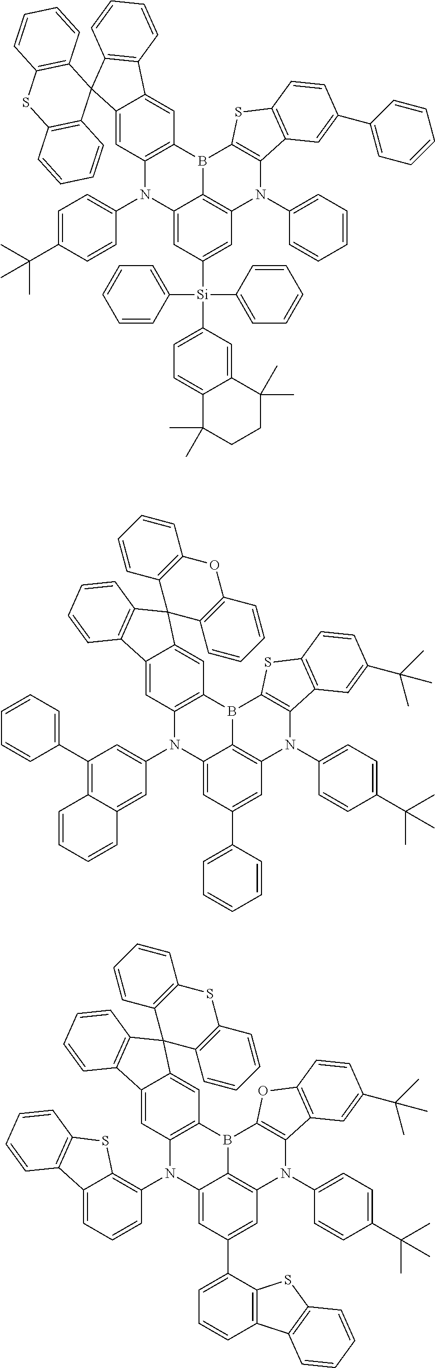 [SMILES: CC(C)(C)c1ccc(N2c3cc4c(cc3B3c5sc6ccc(-c7ccccc7)cc6c5N(c5ccccc5)c5cc([Si](c6ccccc6)(c6ccccc6)c6ccc7c(c6)C(C)(C)CCC7(C)C)cc2c53)-c2ccccc2C42c3ccccc3Sc3ccccc32)cc1 ; CC(C)(C)c1ccc(N2c3cc(-c4ccccc4)cc4c3B(c3cc5c(cc3N4c3cc(-c4ccccc4)c4ccccc4c3)-c3ccccc3C53c4ccccc4Oc4ccccc43)c3sc4ccc(C(C)(C)C)cc4c32)cc1 ; CC(C)(C)c1ccc(N2c3cc(-c4cccc5c4sc4ccccc45)cc4c3B(c3cc5c(cc3N4c3cccc4c3sc3ccccc34)-c3ccccc3C53c4ccccc4Sc4ccccc43)c3oc4ccc(C(C)(C)C)cc4c32)cc1]

In addition, another aspect of the present invention relates to an organic electroluminescent device including: a first electrode; a second electrode; and one or more organic layers interposed between the first electrode and the second electrode, wherein the organic layer, preferably a light emitting layer, includes the compound represented by [Formula 1] as a host or a dopant.

The light emitting layer has a structure formed with a host and a dopant, and may further include other host or dopant materials in addition to the compound according to the present invention. Herein, the content of the dopant may be typically selected in a range of about 0.01 parts by weight to about 20 parts by weight based on about 100 parts by weight of the host, however, the content is not limited thereto.

In addition, the light emitting layer may further include various dopant and host materials in addition to the host and dopant compounds according to the present invention, and accordingly, in the light emitting layer, one or more types of compounds different from each other may be mixed or stacked and used as the dopant material as well as the host.

Additionally, the compound represented by [Formula 1] according to the present invention is used as a phosphorescent dopant when used as a host in the light emitting layer, and may be used as a fluorescent or delayed fluorescent dopant when used as a dopant.

Accordingly, the light emitting layer in the organic electroluminescent device according to the present invention may include an anthracene compound represented by the following [Formula 2] as a host material when the compound represented by [Formula 1] is used as a fluorescent or delayed fluorescent dopant in the light emitting layer.

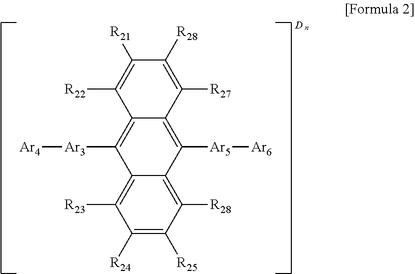

In [Formula 2],

R₂₁ to R₂₈ are the same as or different from each other, and each independently any one selected from hydrogen, deuterium, substituted or unsubstituted C₁-C₃₀ alkyl, substituted or unsubstituted C₂-C₃₀ alkynyl, substituted or unsubstituted C₂-C₃₀ alkenyl, substituted or unsubstituted C₆-C₅₀ aryl, substituted or unsubstituted C₃-C₅₀ cycloalkyl, substituted or unsubstituted C₂-C₅₀ heterocycloalkyl, substituted or unsubstituted C₂-C₅₀ heteroaryl, substituted or unsubstituted cyclic groups in which a C₃-C₃₀ aliphatic ring and a C₅-C₃₀ aromatic ring are fused together, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted amine, substituted or unsubstituted silyl, substituted or unsubstituted germanium, nitro, cyano and halogen.

Ar₃ and Ar₅ are the same as or different from each other, and each independently a single bond, or any one selected from substituted or unsubstituted C₆-C₃₀ arylene, substituted or unsubstituted C₅-C₃₀ heteroarylene, and substituted or unsubstituted divalent cyclic groups in which a C₃-C₃₀ aliphatic ring and a C₅-C₃₀ aromatic ring are fused together.

Ar₄ and Ar₆ are the same as or different from each other, and each independently any one selected from substituted or unsubstituted C₆-C₅₀ aryl, substituted or unsubstituted C₃-C₃₀ cycloalkyl, substituted or unsubstituted C₃-C₃₀ heterocycloalkyl, substituted or unsubstituted C₂-C₅₀ heteroaryl, and substituted or unsubstituted cyclic groups in which a C₃-C₃₀ aliphatic ring and a C₅-C₃₀ aromatic ring are fused together.

Dₙ means the number of hydrogen atoms of [Formula 2] replaced by deuterium atoms, and n is an integer of 0 to 60.

According to one embodiment of the present invention, the anthracene compound represented by [Formula 2] may be any one selected from compounds represented by the following formulae, but is not limited thereto.

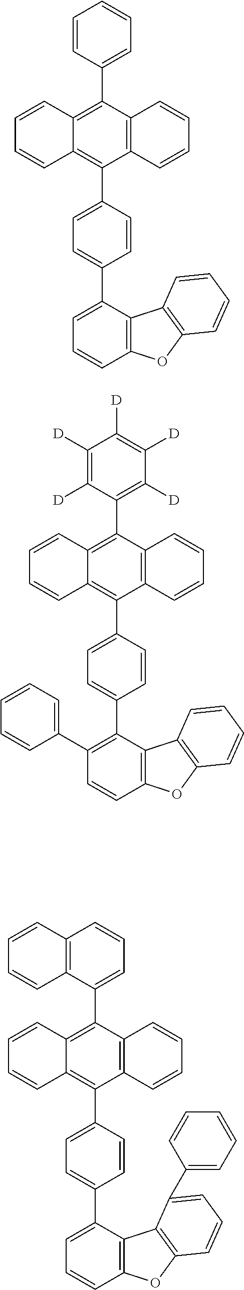

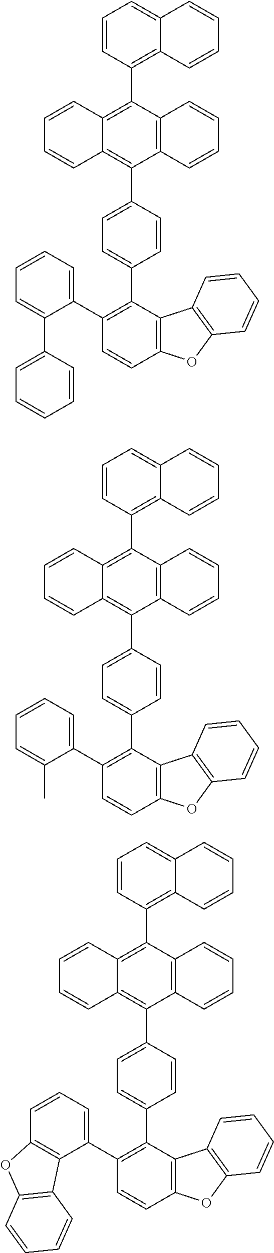

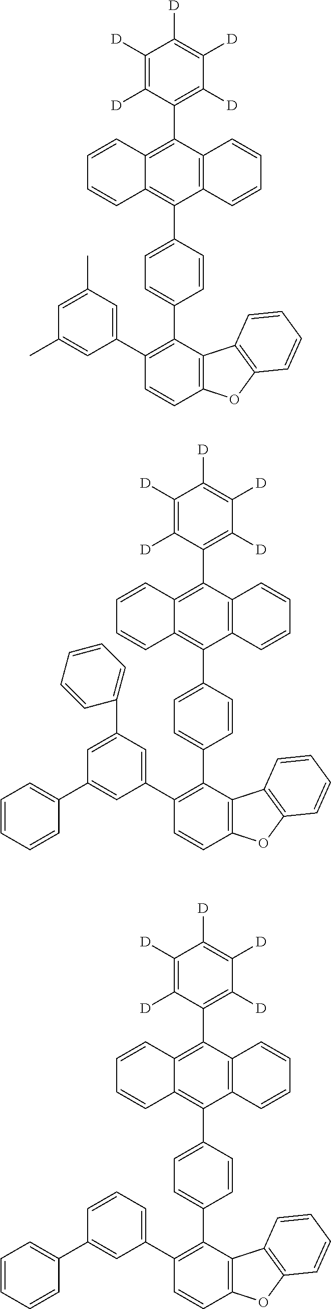 [SMILES: [2H]c1c([2H])c([2H])c(-c2c3ccccc3c(-c3ccc(-c4c(-c5cc(C)cc(C)c5)ccc5oc6ccccc6c45)cc3)c3ccccc23)c([2H])c1[2H] ; [2H]c1c([2H])c([2H])c(-c2c3ccccc3c(-c3ccc(-c4c(-c5cc(-c6ccccc6)cc(-c6ccccc6)c5)ccc5oc6ccccc6c45)cc3)c3ccccc23)c([2H])c1[2H] ; [2H]c1c([2H])c([2H])c(-c2c3ccccc3c(-c3ccc(-c4c(-c5cccc(-c6ccccc6)c5)ccc5oc6ccccc6c45)cc3)c3ccccc23)c([2H])c1[2H]]

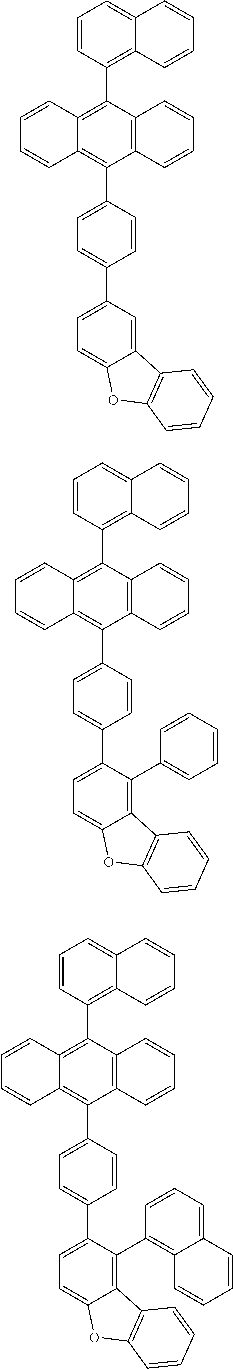

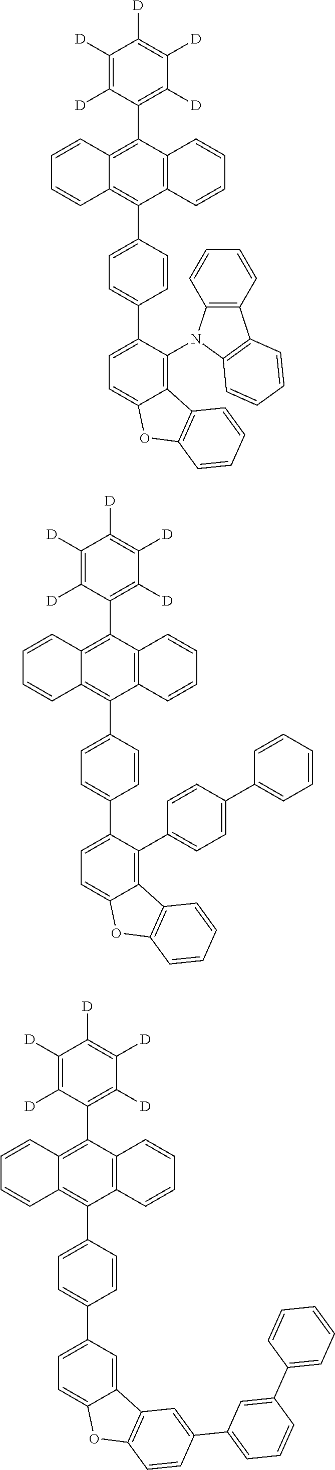 [SMILES: [2H]c1c([2H])c([2H])c(-c2c3ccccc3c(-c3ccc(-c4ccc5oc6ccccc6c5c4-n4c5ccccc5c5ccccc54)cc3)c3ccccc23)c([2H])c1[2H] ; [2H]c1c([2H])c([2H])c(-c2c3ccccc3c(-c3ccc(-c4ccc5oc6ccccc6c5c4-c4ccc(-c5ccccc5)cc4)cc3)c3ccccc23)c([2H])c1[2H] ; [2H]c1c([2H])c([2H])c(-c2c3ccccc3c(-c3ccc(-c4ccc5oc6ccc(-c7cccc(-c8ccccc8)c7)cc6c5c4)cc3)c3ccccc23)c([2H])c1[2H]]

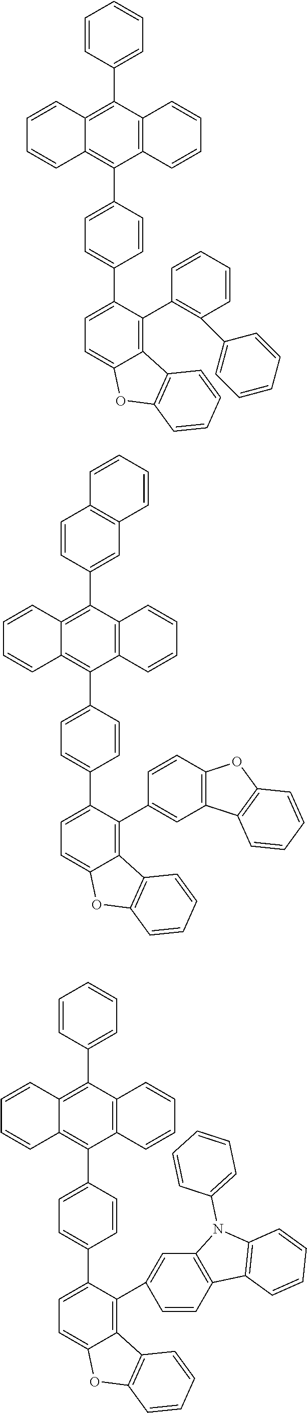 [SMILES: c1ccc(-c2ccccc2-c2c(-c3ccc(-c4c5ccccc5c(-c5ccccc5)c5ccccc45)cc3)ccc3oc4ccccc4c23)cc1 ; c1ccc2cc(-c3c4ccccc4c(-c4ccc(-c5ccc6oc7ccccc7c6c5-c5ccc6oc7ccccc7c6c5)cc4)c4ccccc34)ccc2c1 ; c1ccc(-c2c3ccccc3c(-c3ccc(-c4ccc5oc6ccccc6c5c4-c4ccc5c6ccccc6n(-c6ccccc6)c5c4)cc3)c3ccccc23)cc1]

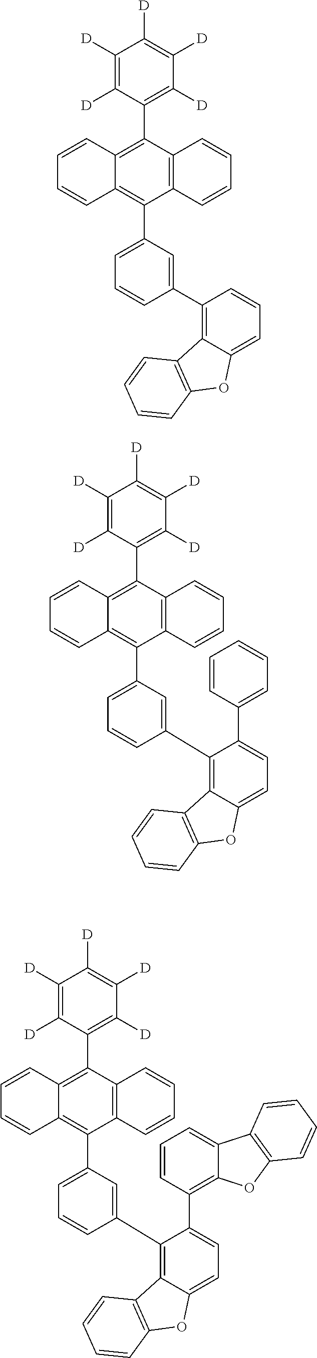

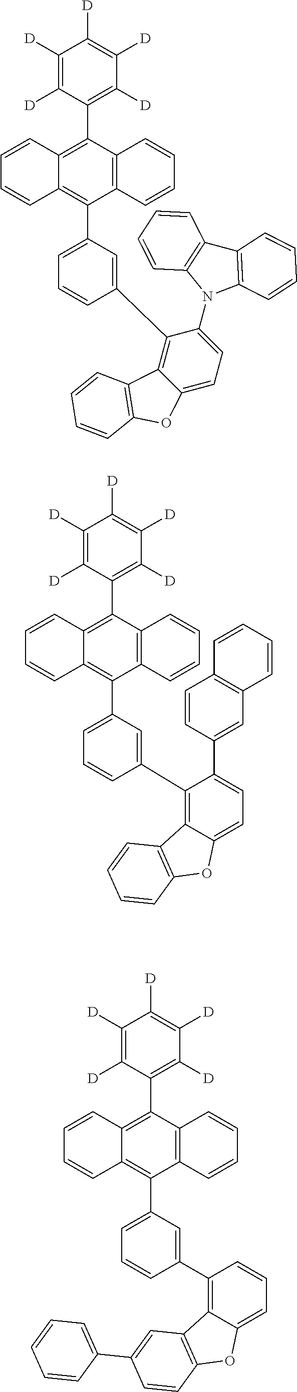

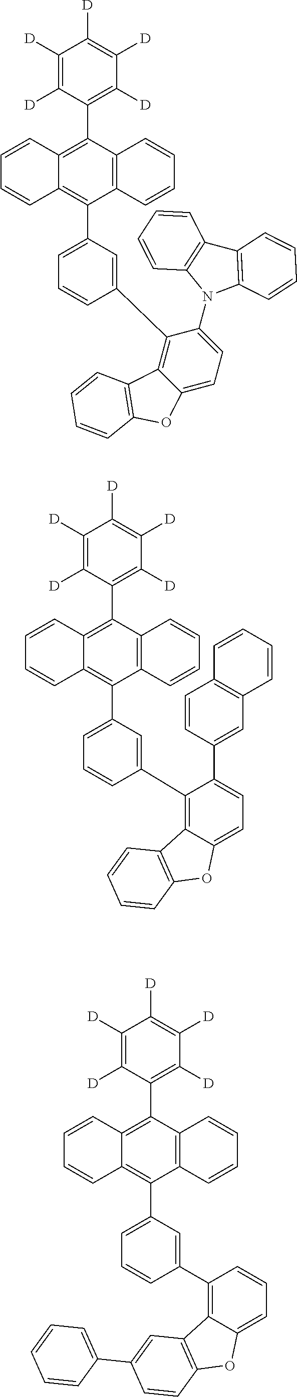 [SMILES: [2H]c1c([2H])c([2H])c(-c2c3ccccc3c(-c3cccc(-c4c(-n5c6ccccc6c6ccccc65)ccc5oc6ccccc6c45)c3)c3ccccc23)c([2H])c1[2H] ; [2H]c1c([2H])c([2H])c(-c2c3ccccc3c(-c3cccc(-c4c(-c5ccc6ccccc6c5)ccc5oc6ccccc6c45)c3)c3ccccc23)c([2H])c1[2H] ; [2H]c1c([2H])c([2H])c(-c2c3ccccc3c(-c3cccc(-c4cccc5oc6ccc(-c7ccccc7)cc6c45)c3)c3ccccc23)c([2H])c1[2H]]

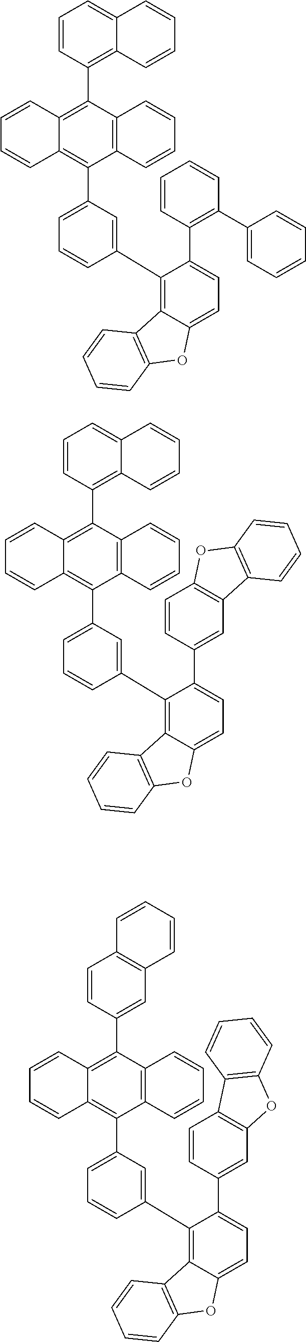

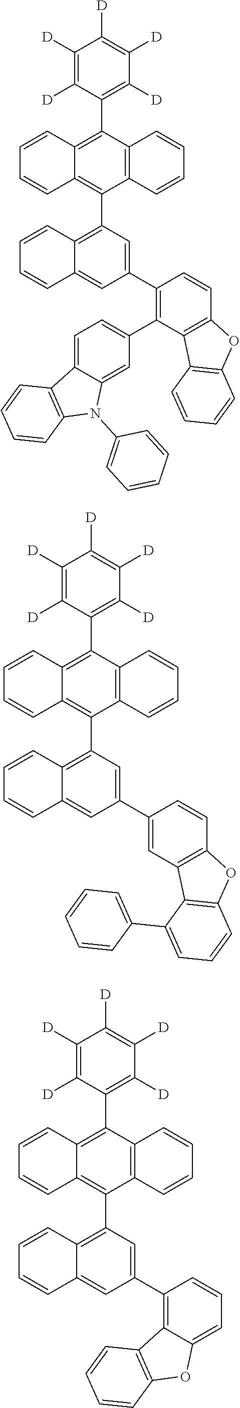

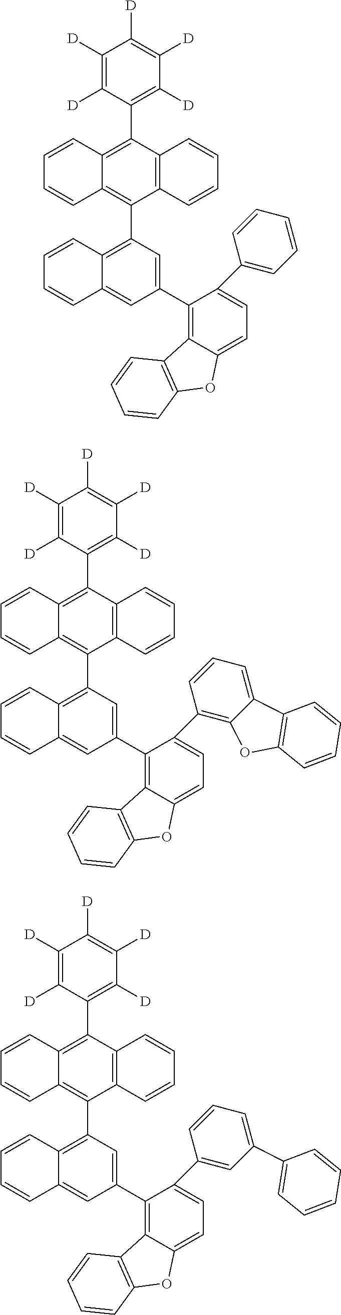

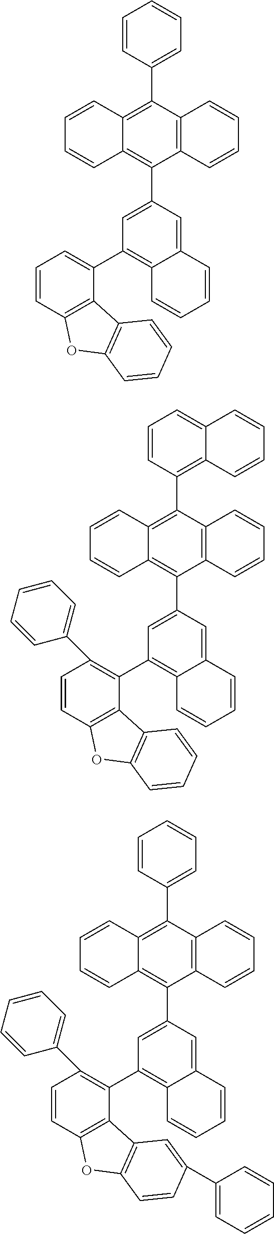

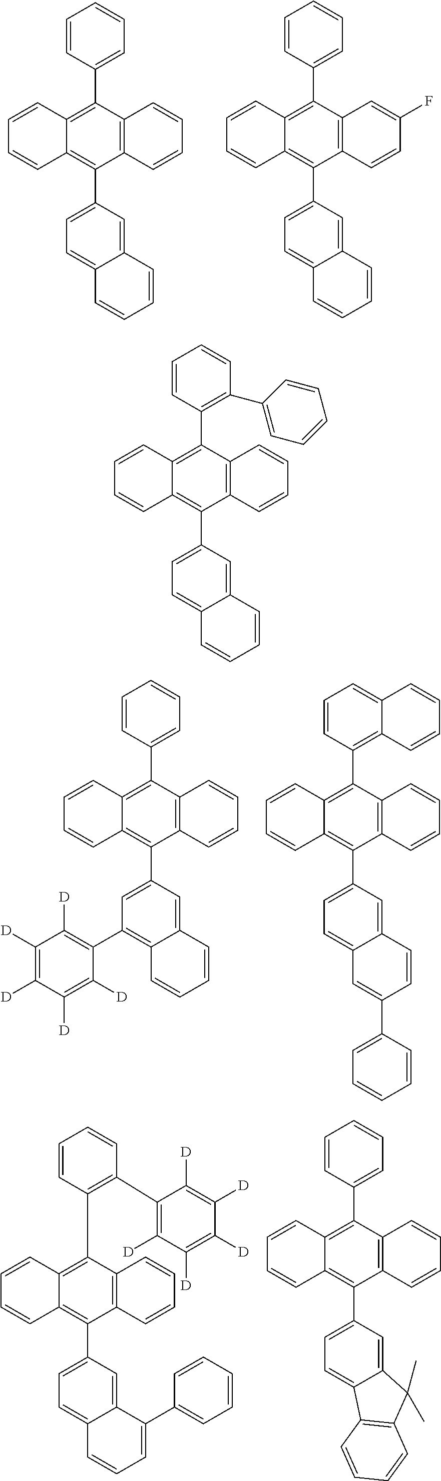

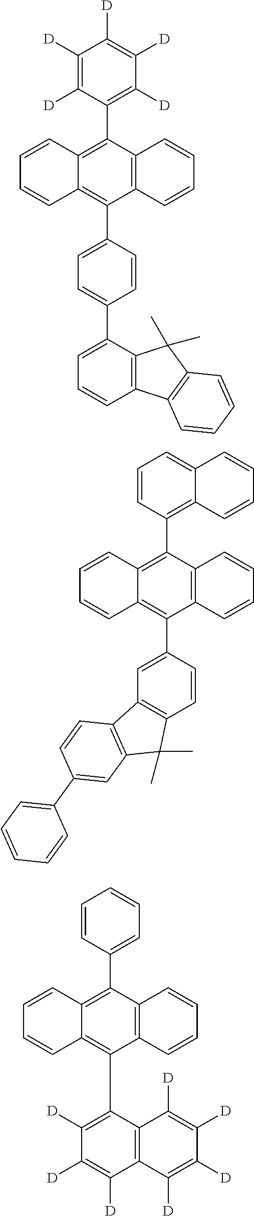

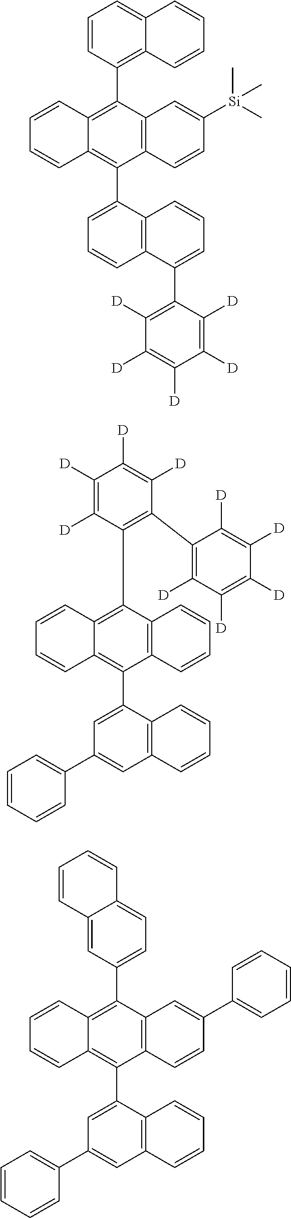

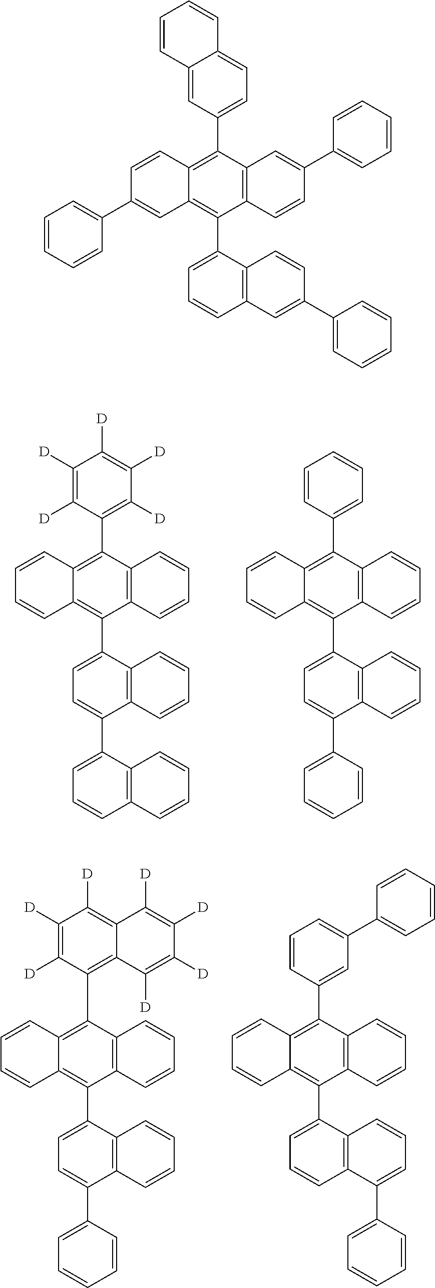

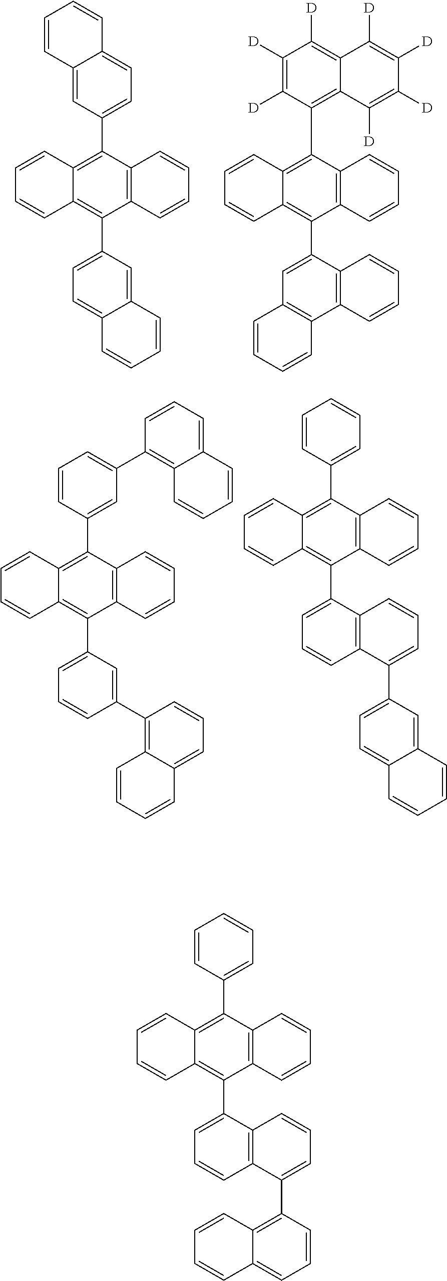

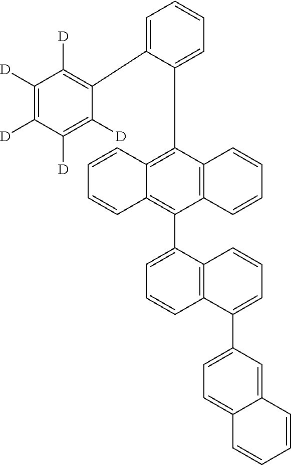 [SMILES: [2H]c1c([2H])c([2H])c(-c2ccccc2-c2c3ccccc3c(-c3cccc4c(-c5ccc6ccccc6c5)cccc34)c3ccccc23)c([2H])c1[2H]]

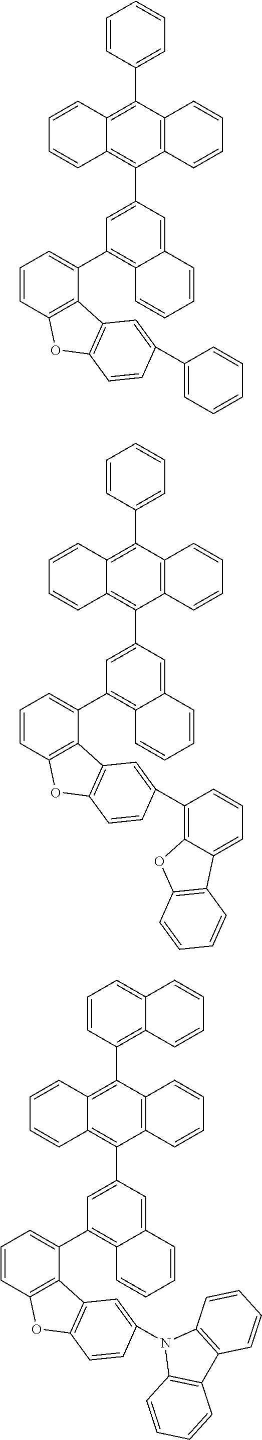

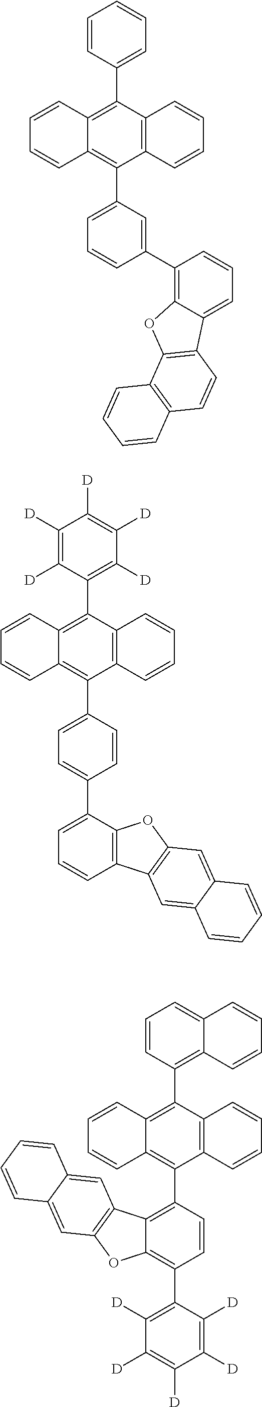 [SMILES: c1ccc(-c2c3ccccc3c(-c3cccc(-c4cccc5c4oc4c6ccccc6ccc54)c3)c3ccccc23)cc1 ; [2H]c1c([2H])c([2H])c(-c2c3ccccc3c(-c3ccc(-c4cccc5c4oc4cc6ccccc6cc45)cc3)c3ccccc23)c([2H])c1[2H] ; [2H]c1c([2H])c([2H])c(-c2ccc(-c3c4ccccc4c(-c4cccc5ccccc45)c4ccccc34)c3c2oc2cc4ccccc4cc23)c([2H])c1[2H]]

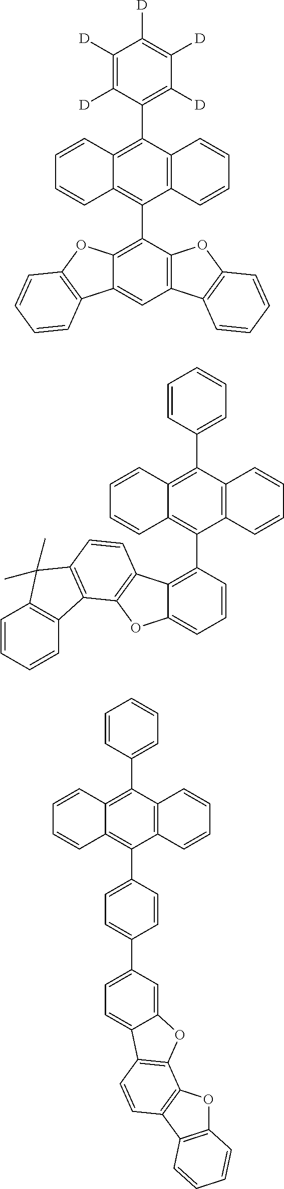

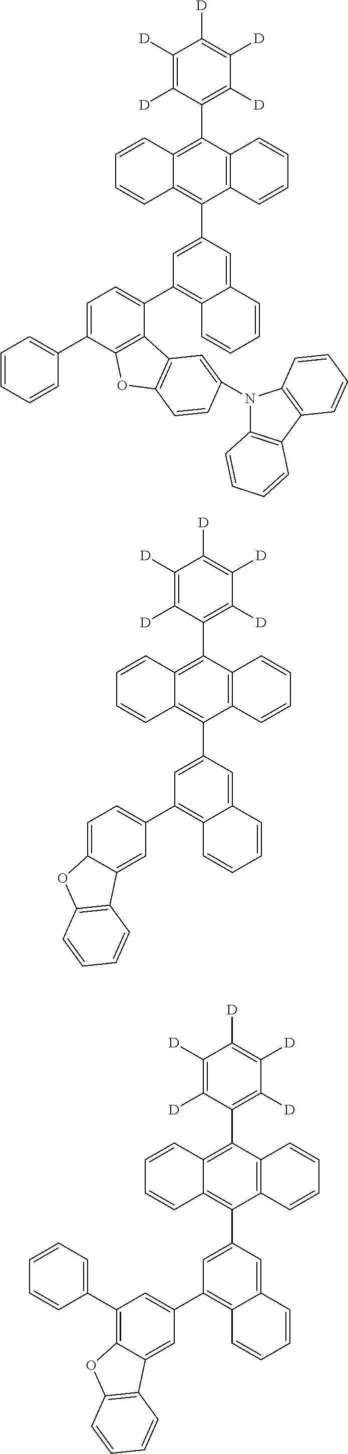

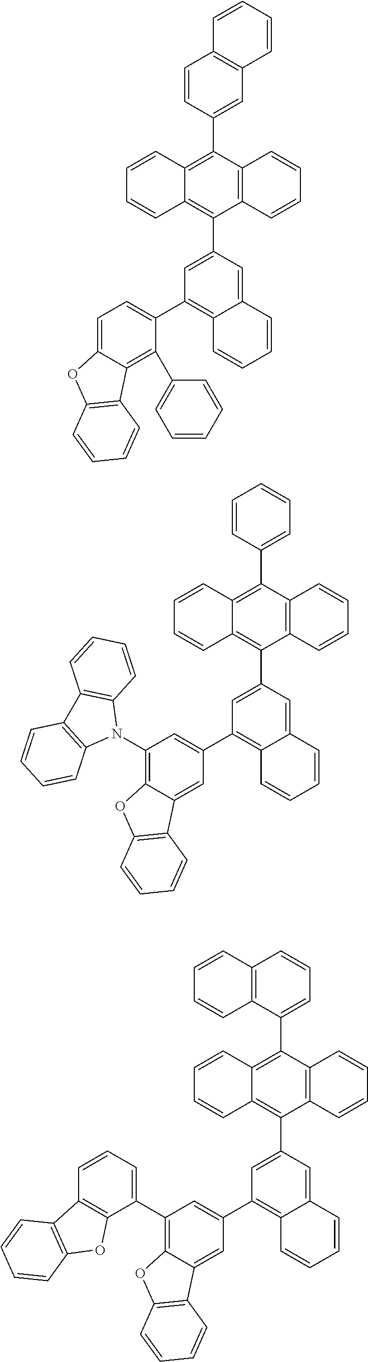 [SMILES: c1ccc(-c2c(-c3cc(-c4c5ccccc5c(-c5ccc6ccccc6c5)c5ccccc45)cc4ccccc34)ccc3oc4ccccc4c23)cc1 ; c1ccc(-c2c3ccccc3c(-c3cc(-c4cc(-n5c6ccccc6c6ccccc65)c5oc6ccccc6c5c4)c4ccccc4c3)c3ccccc23)cc1 ; c1ccc2c(-c3cc(-c4cccc5c4oc4ccccc45)c4oc5ccccc5c4c3)cc(-c3c4ccccc4c(-c4cccc5ccccc45)c4ccccc34)cc2c1]

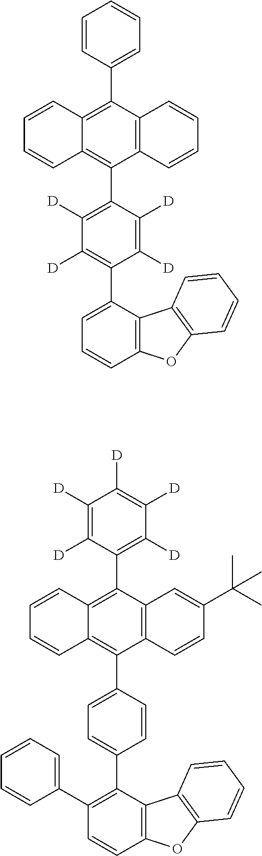 [SMILES: [2H]c1c([2H])c(-c2cccc3oc4ccccc4c23)c([2H])c([2H])c1-c1c2ccccc2c(-c2ccccc2)c2ccccc12 ; [2H]c1c([2H])c([2H])c(-c2c3ccccc3c(-c3ccc(-c4c(-c5ccccc5)ccc5oc6ccccc6c45)cc3)c3ccc(C(C)(C)C)cc23)c([2H])c1[2H]]

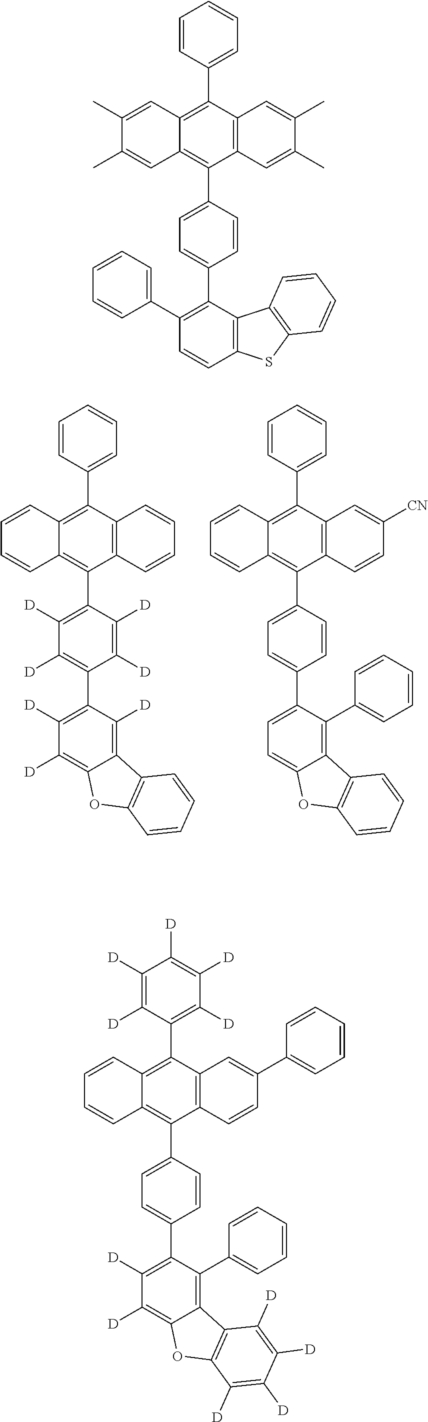

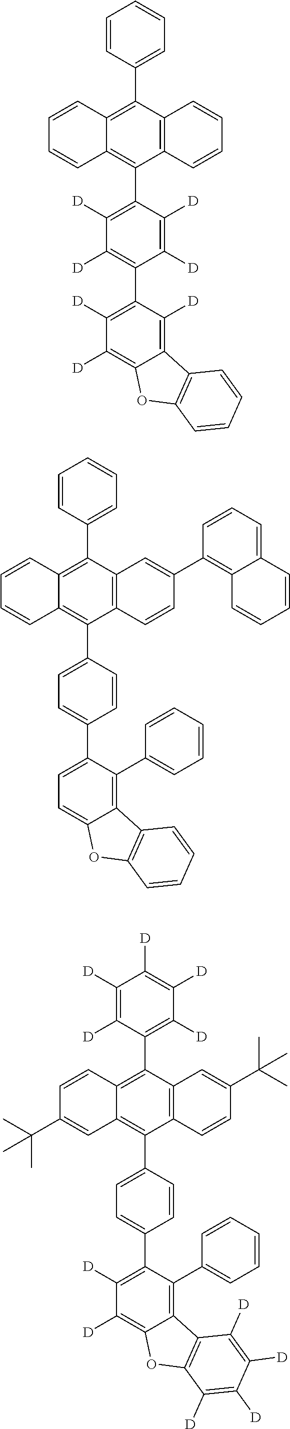 [SMILES: [2H]c1c([2H])c(-c2c3ccccc3c(-c3ccccc3)c3ccccc23)c([2H])c([2H])c1-c1c([2H])c([2H])c2oc3ccccc3c2c1[2H] ; c1ccc(-c2c3ccccc3c(-c3ccc(-c4ccc5oc6ccccc6c5c4-c4ccccc4)cc3)c3ccc(-c4cccc5ccccc45)cc23)cc1 ; [2H]c1c([2H])c([2H])c(-c2c3ccc(C(C)(C)C)cc3c(-c3ccc(-c4c([2H])c([2H])c5oc6c([2H])c([2H])c([2H])c([2H])c6c5c4-c4ccccc4)cc3)c3ccc(C(C)(C)C)cc23)c([2H])c1[2H]]

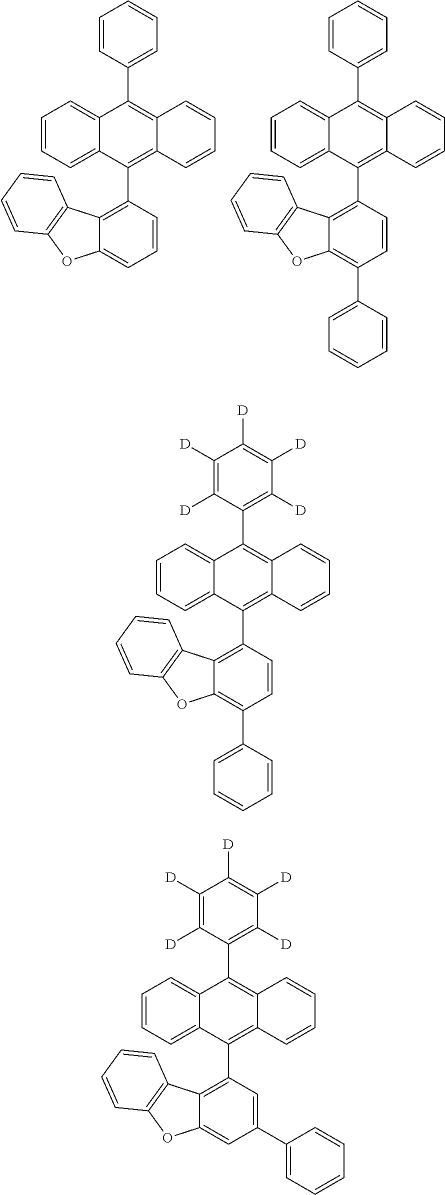

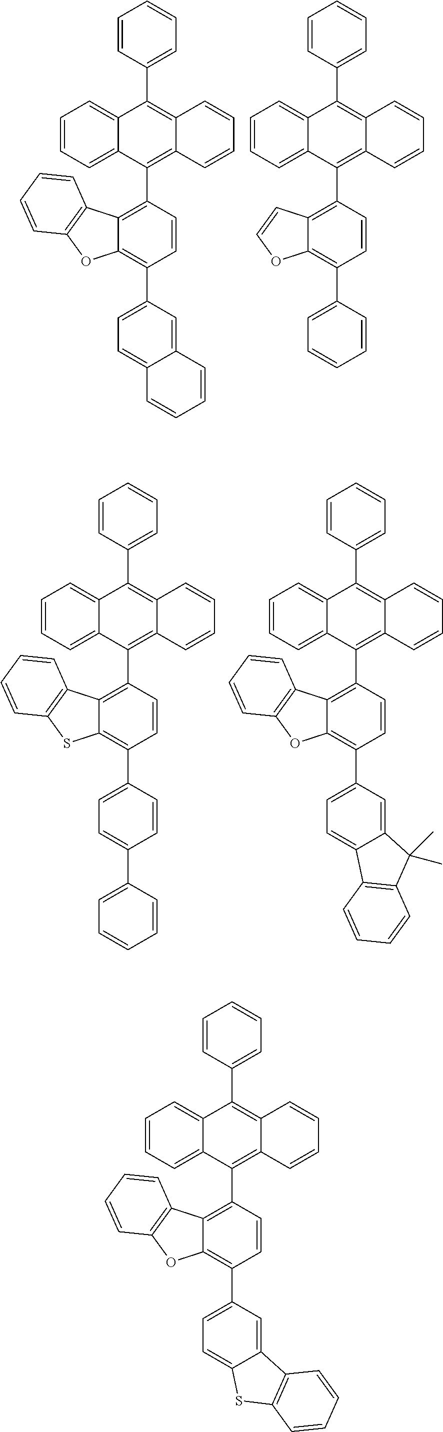

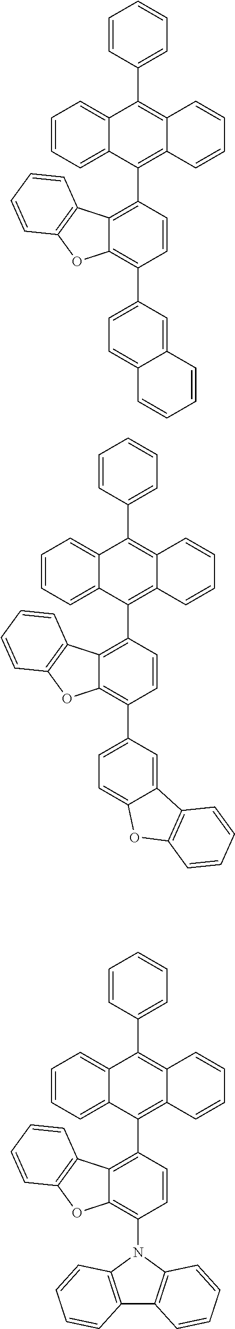

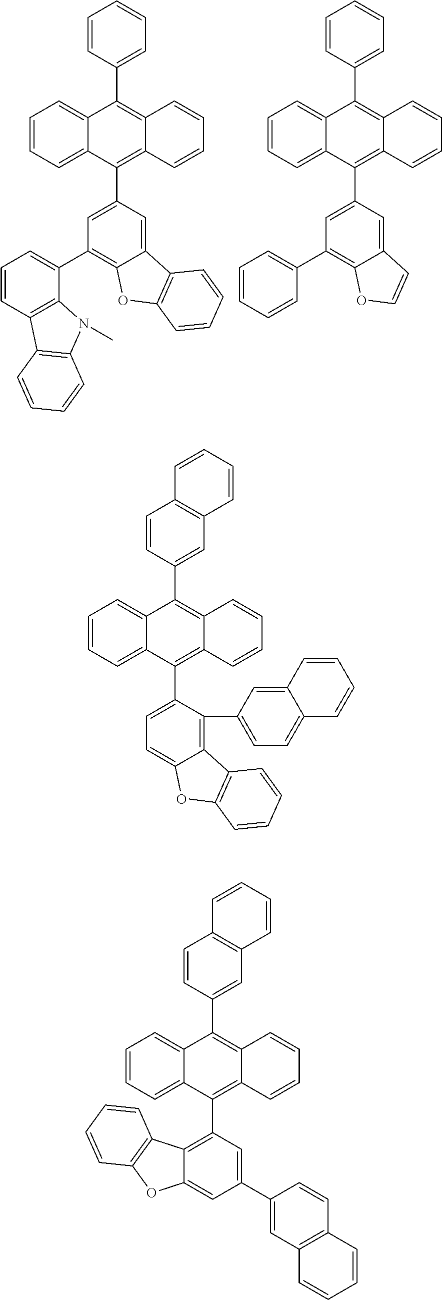

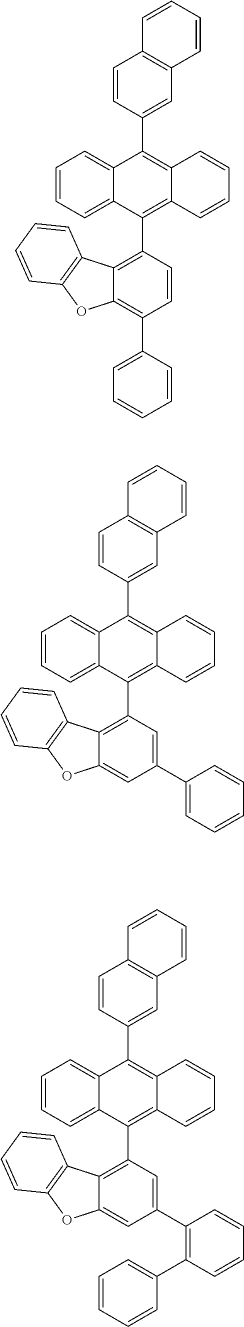 [SMILES: c1ccc(-c2ccc(-c3c4ccccc4c(-c4ccc5ccccc5c4)c4ccccc34)c3c2oc2ccccc23)cc1 ; c1ccc(-c2cc(-c3c4ccccc4c(-c4ccc5ccccc5c4)c4ccccc34)c3c(c2)oc2ccccc23)cc1 ; c1ccc(-c2ccccc2-c2cc(-c3c4ccccc4c(-c4ccc5ccccc5c4)c4ccccc34)c3c(c2)oc2ccccc23)cc1]

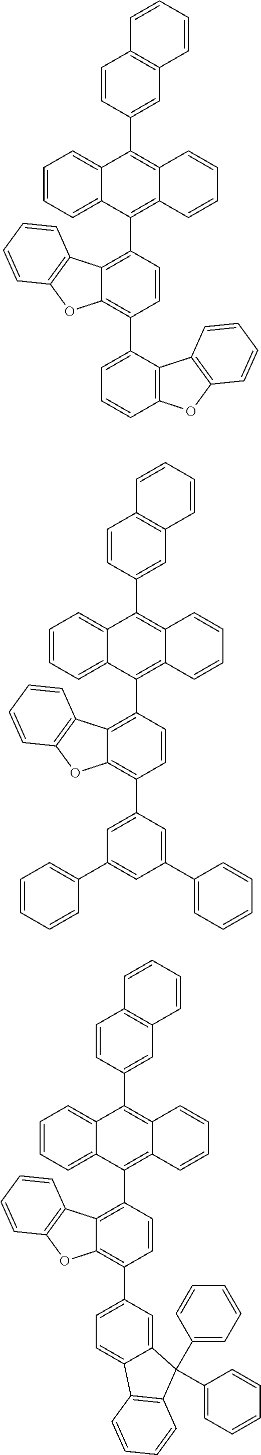 [SMILES: c1ccc2cc(-c3c4ccccc4c(-c4ccc(-c5cccc6oc7ccccc7c56)c5oc6ccccc6c45)c4ccccc34)ccc2c1 ; c1ccc(-c2cc(-c3ccccc3)cc(-c3ccc(-c4c5ccccc5c(-c5ccc6ccccc6c5)c5ccccc45)c4c3oc3ccccc34)c2)cc1 ; c1ccc(C2(c3ccccc3)c3ccccc3-c3ccc(-c4ccc(-c5c6ccccc6c(-c6ccc7ccccc7c6)c6ccccc56)c5c4oc4ccccc45)cc32)cc1]

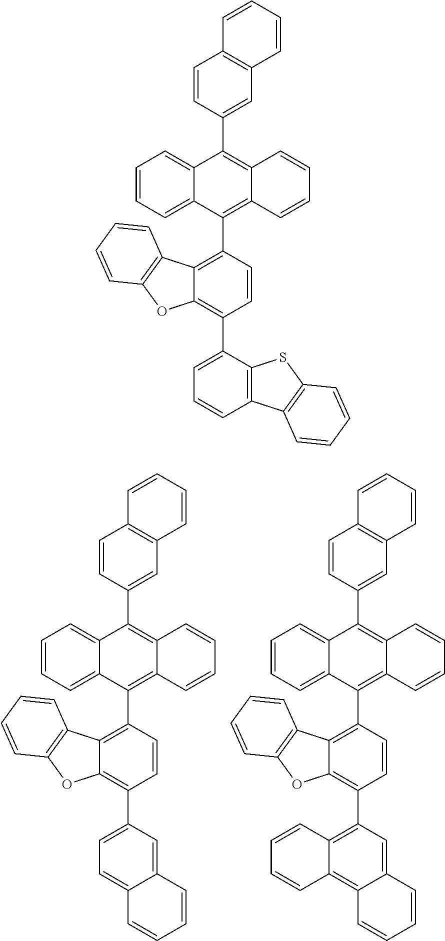

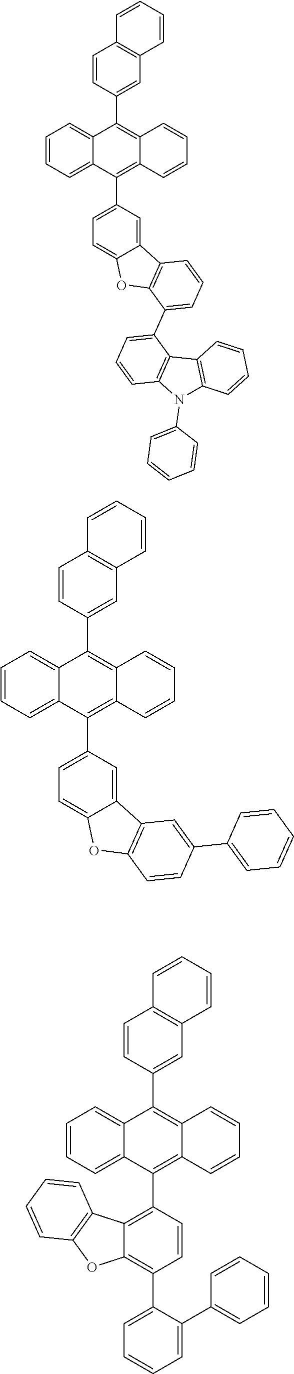

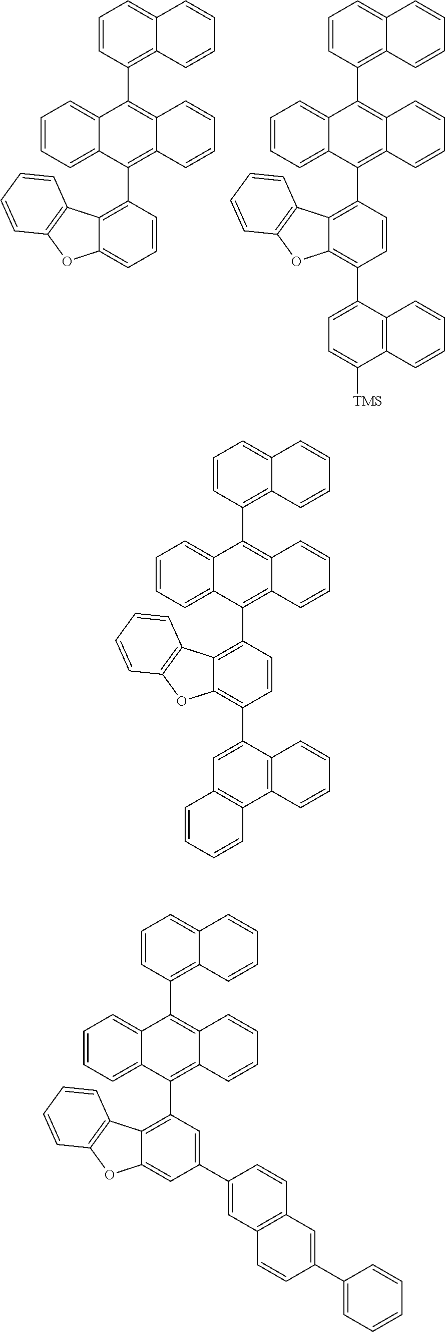

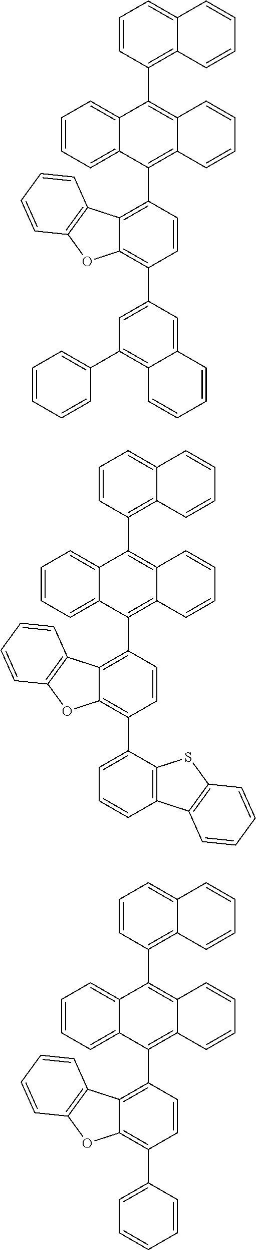

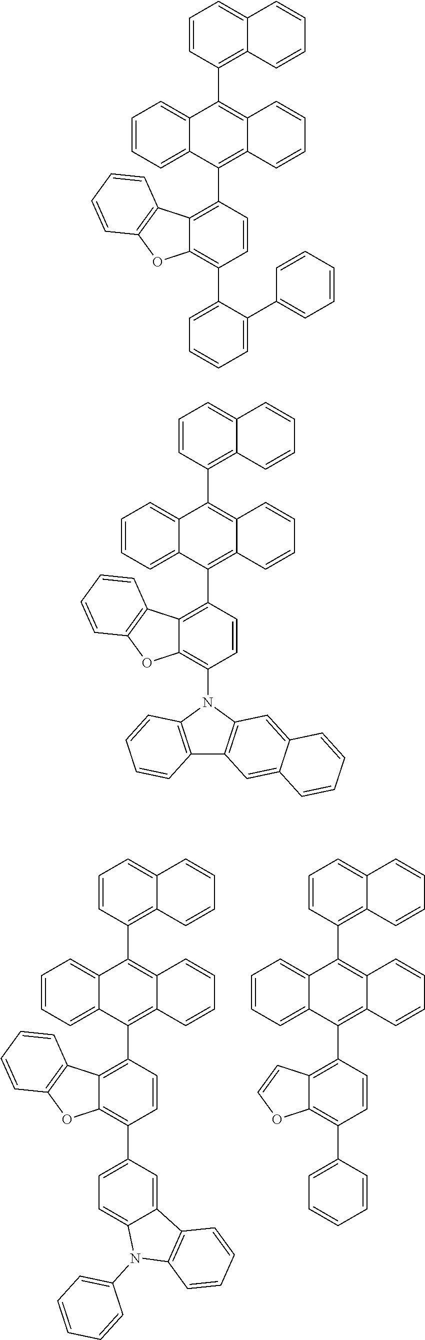

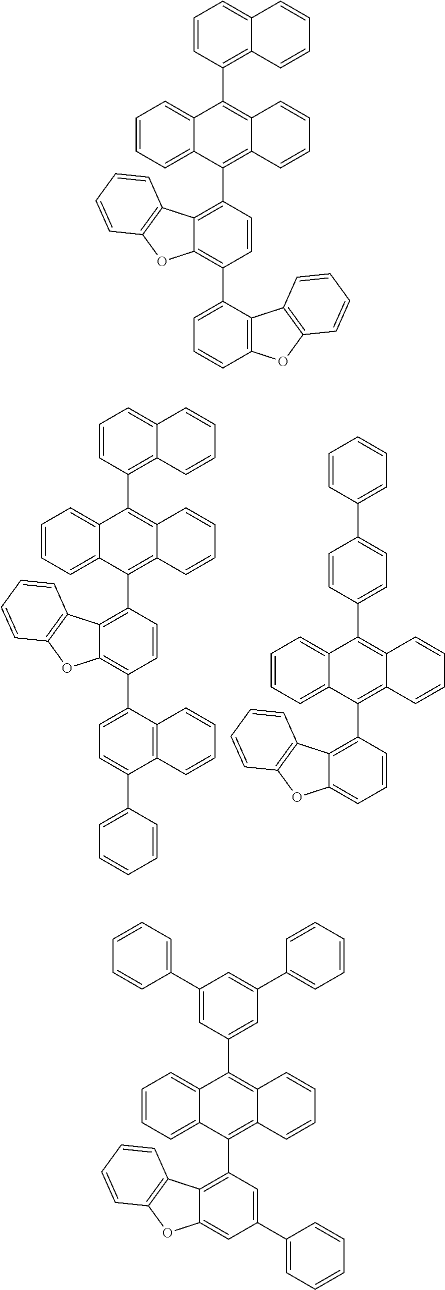

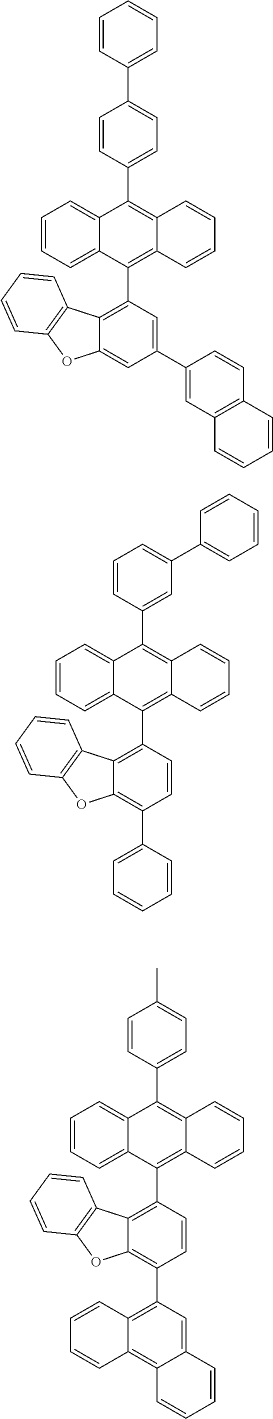

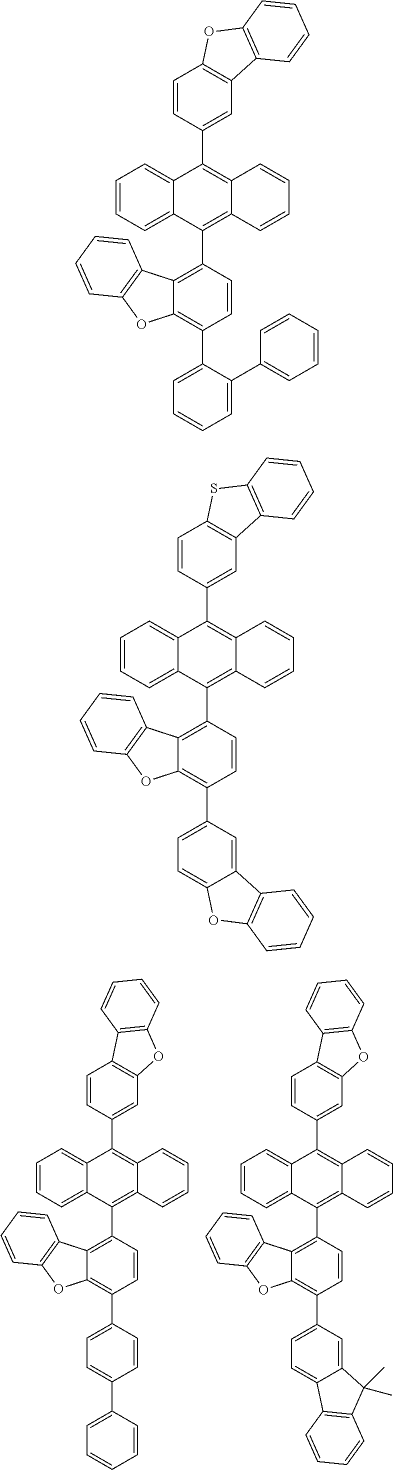

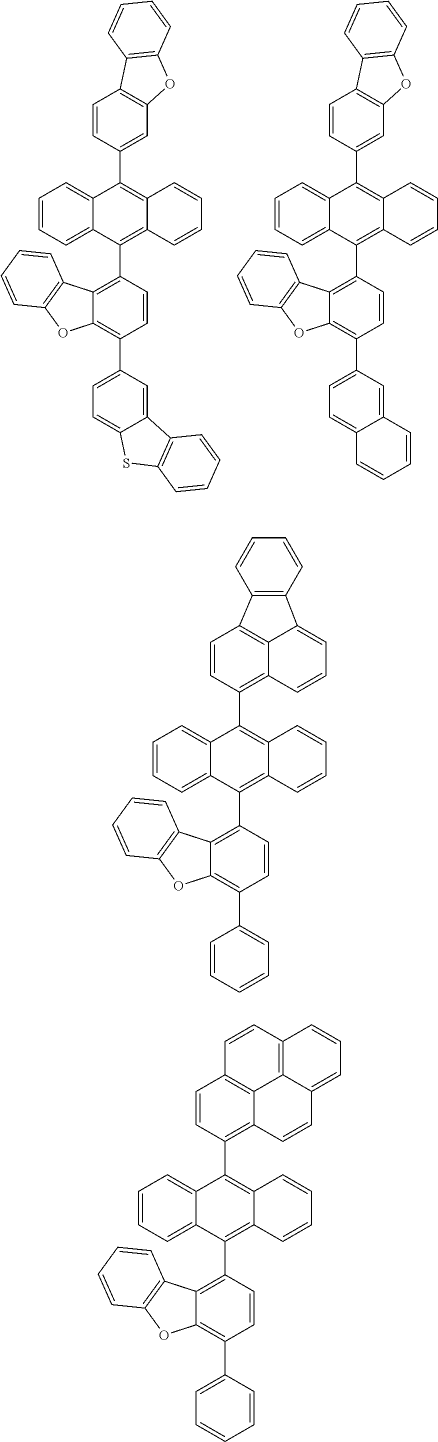

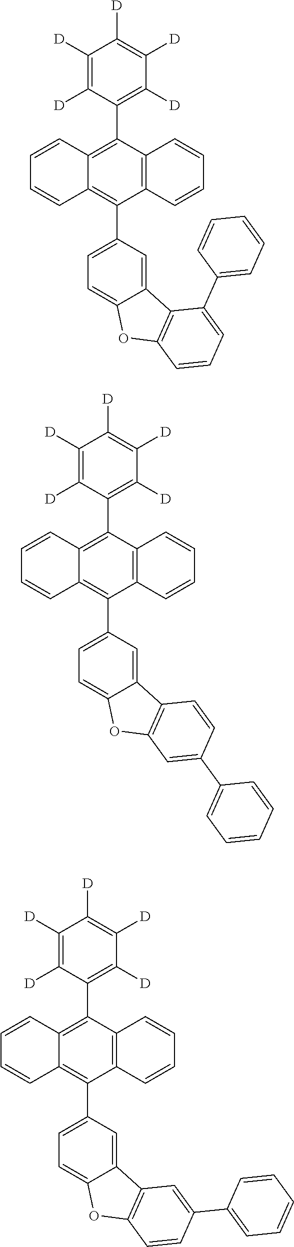 [SMILES: [2H]c1c([2H])c([2H])c(-c2c3ccccc3c(-c3ccc4oc5cccc(-c6ccccc6)c5c4c3)c3ccccc23)c([2H])c1[2H] ; [2H]c1c([2H])c([2H])c(-c2c3ccccc3c(-c3ccc4oc5cc(-c6ccccc6)ccc5c4c3)c3ccccc23)c([2H])c1[2H] ; [2H]c1c([2H])c([2H])c(-c2c3ccccc3c(-c3ccc4oc5ccc(-c6ccccc6)cc5c4c3)c3ccccc23)c([2H])c1[2H]]

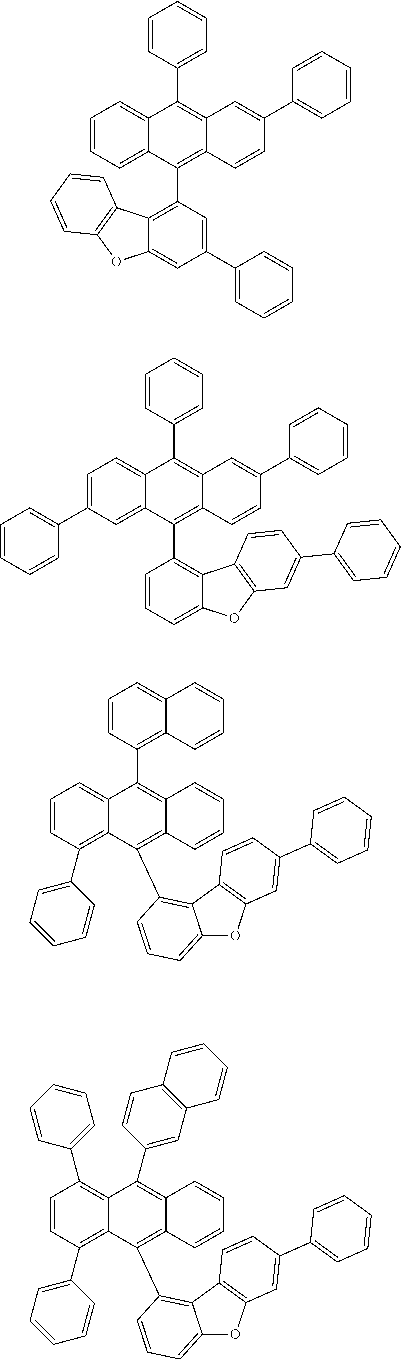 [SMILES: c1ccc(-c2cc(-c3c4ccccc4c(-c4ccccc4)c4cc(-c5ccccc5)ccc34)c3c(c2)oc2ccccc23)cc1 ; c1ccc(-c2ccc3c(c2)oc2cccc(-c4c5ccc(-c6ccccc6)cc5c(-c5ccccc5)c5ccc(-c6ccccc6)cc45)c23)cc1 ; c1ccc(-c2ccc3c(c2)oc2cccc(-c4c5ccccc5c(-c5cccc6ccccc56)c5cccc(-c6ccccc6)c45)c23)cc1 ; c1ccc(-c2ccc3c(c2)oc2cccc(-c4c5ccccc5c(-c5ccc6ccccc6c5)c5c(-c6ccccc6)ccc(-c6ccccc6)c45)c23)cc1]

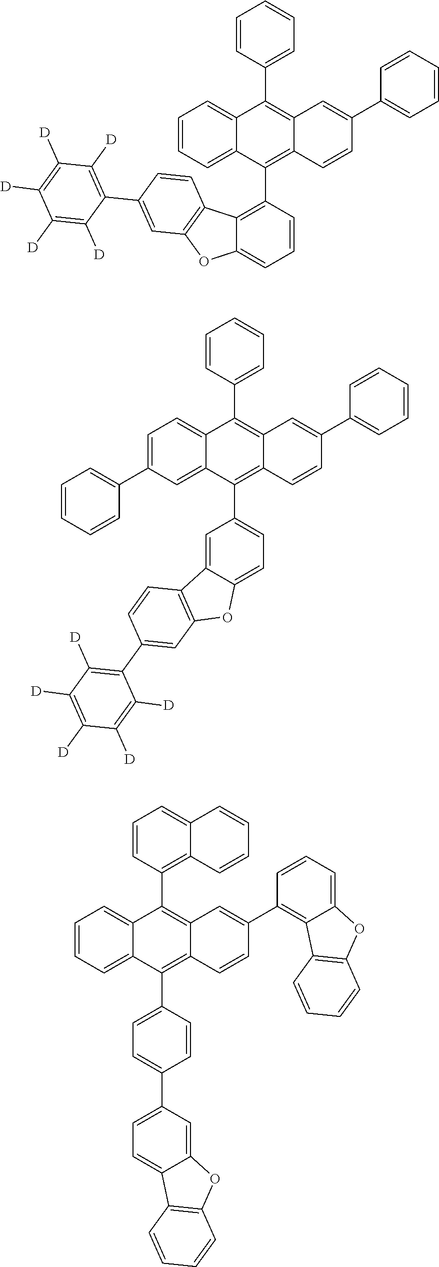 [SMILES: [2H]c1c([2H])c([2H])c(-c2ccc3c(c2)oc2cccc(-c4c5ccccc5c(-c5ccccc5)c5cc(-c6ccccc6)ccc45)c23)c([2H])c1[2H] ; [2H]c1c([2H])c([2H])c(-c2ccc3c(c2)oc2ccc(-c4c5ccc(-c6ccccc6)cc5c(-c5ccccc5)c5ccc(-c6ccccc6)cc45)cc23)c([2H])c1[2H] ; c1ccc2c(-c3c4ccccc4c(-c4ccc(-c5ccc6c(c5)oc5ccccc56)cc4)c4ccc(-c5cccc6oc7ccccc7c56)cc34)cccc2c1]

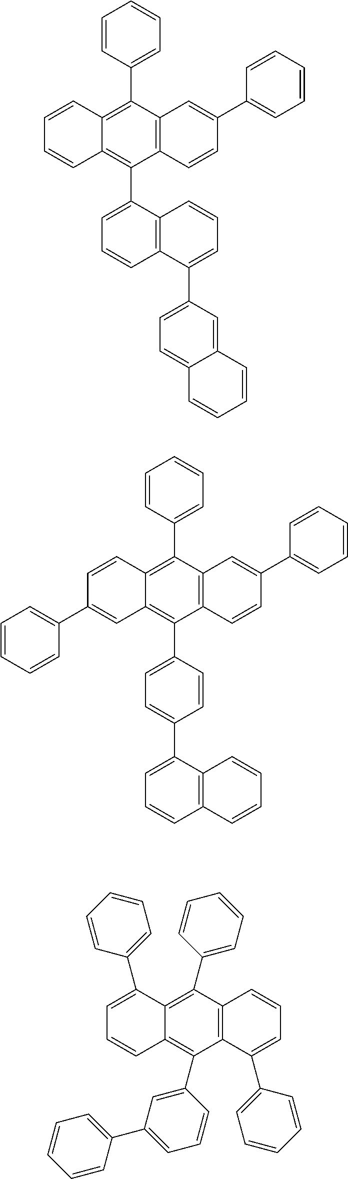

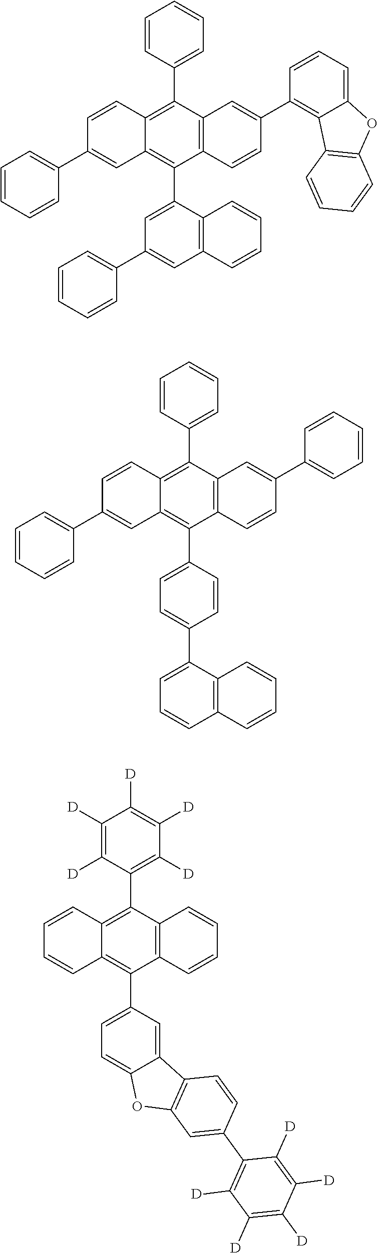

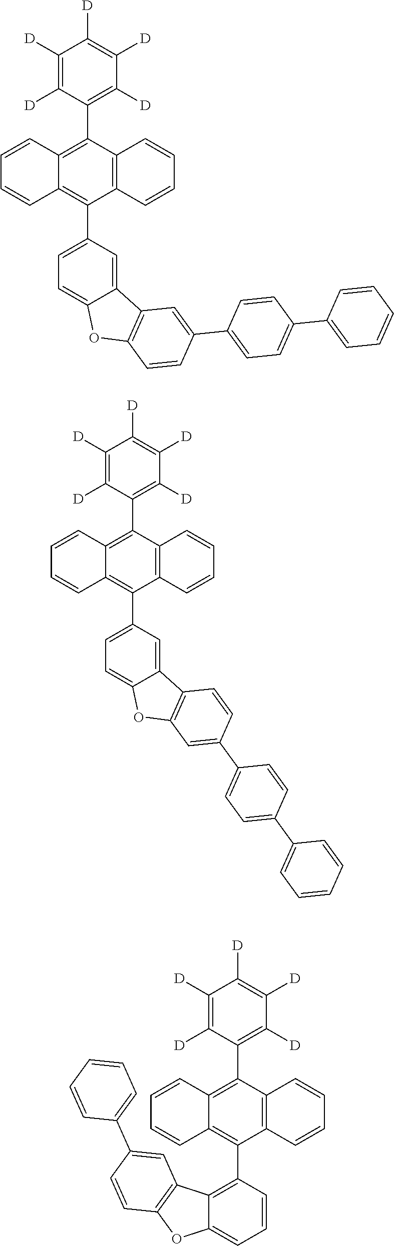

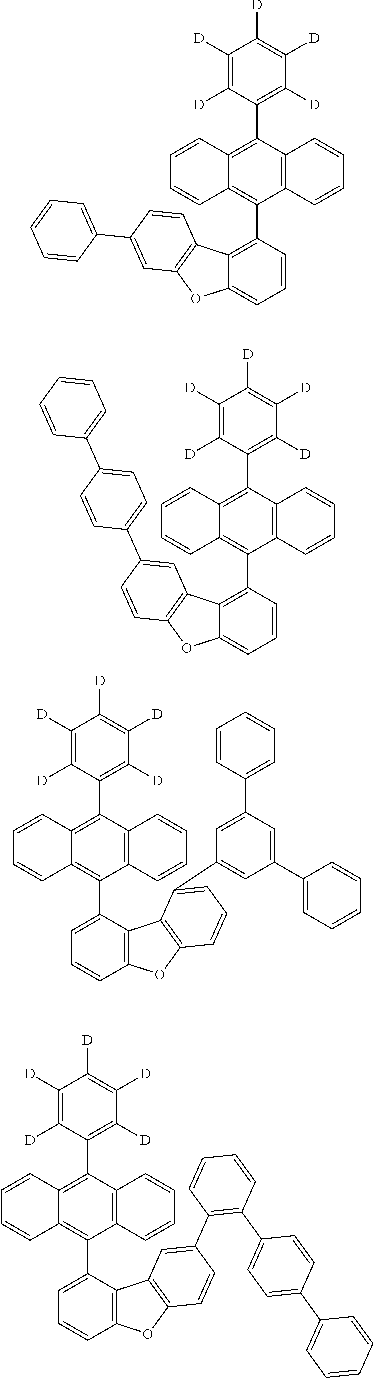 [SMILES: [2H]c1c([2H])c([2H])c(-c2c3ccccc3c(-c3cccc4oc5cc(-c6ccccc6)ccc5c34)c3ccccc23)c([2H])c1[2H] ; [2H]c1c([2H])c([2H])c(-c2c3ccccc3c(-c3cccc4oc5ccc(-c6ccc(-c7ccccc7)cc6)cc5c34)c3ccccc23)c([2H])c1[2H] ; [2H]c1c([2H])c([2H])c(-c2c3ccccc3c(-c3cccc4oc5cccc(-c6cc(-c7ccccc7)cc(-c7ccccc7)c6)c5c34)c3ccccc23)c([2H])c1[2H] ; [2H]c1c([2H])c([2H])c(-c2c3ccccc3c(-c3cccc4oc5ccc(-c6ccccc6-c6ccc(-c7ccccc7)cc6)cc5c34)c3ccccc23)c([2H])c1[2H]]

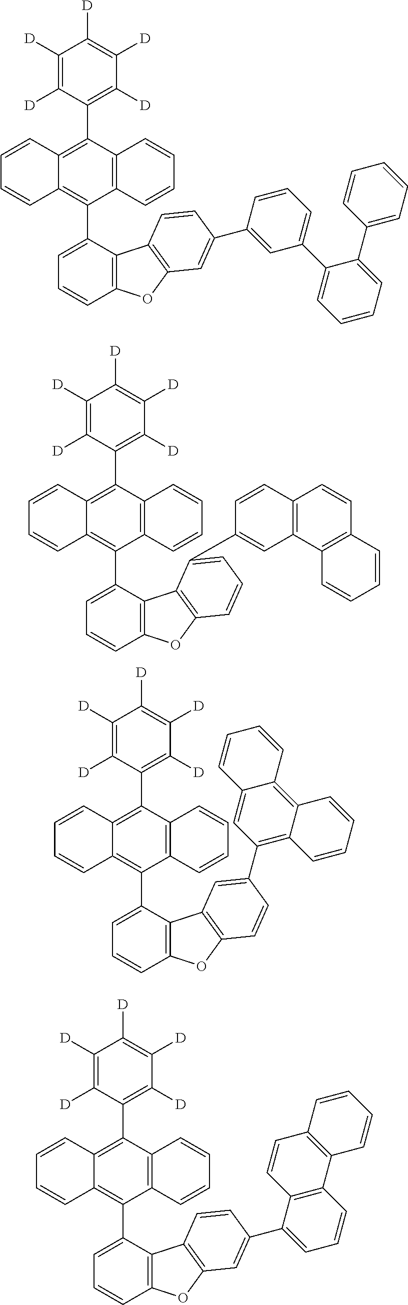

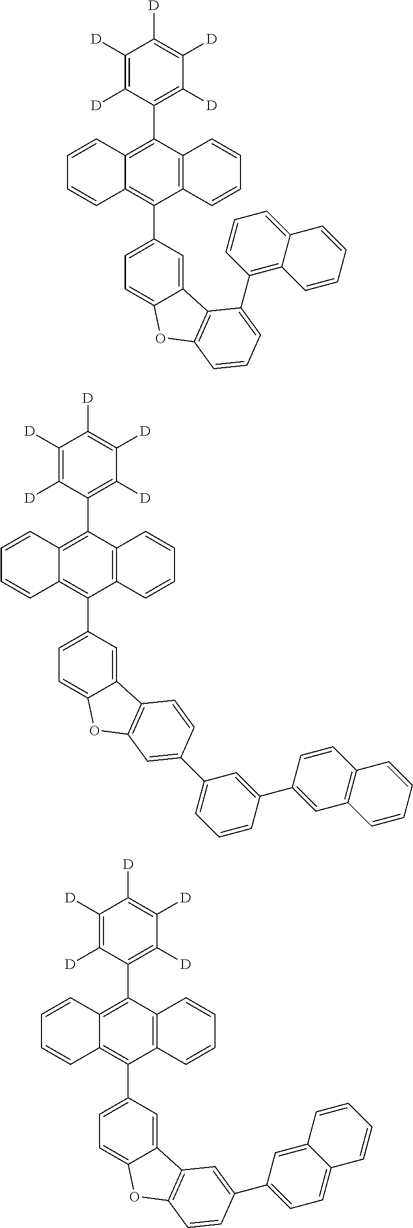 [SMILES: [2H]c1c([2H])c([2H])c(-c2c3ccccc3c(-c3ccc4oc5cccc(-c6cccc7ccccc67)c5c4c3)c3ccccc23)c([2H])c1[2H] ; [2H]c1c([2H])c([2H])c(-c2c3ccccc3c(-c3ccc4oc5cc(-c6cccc(-c7ccc8ccccc8c7)c6)ccc5c4c3)c3ccccc23)c([2H])c1[2H] ; [2H]c1c([2H])c([2H])c(-c2c3ccccc3c(-c3ccc4oc5ccc(-c6ccc7ccccc7c6)cc5c4c3)c3ccccc23)c([2H])c1[2H]]

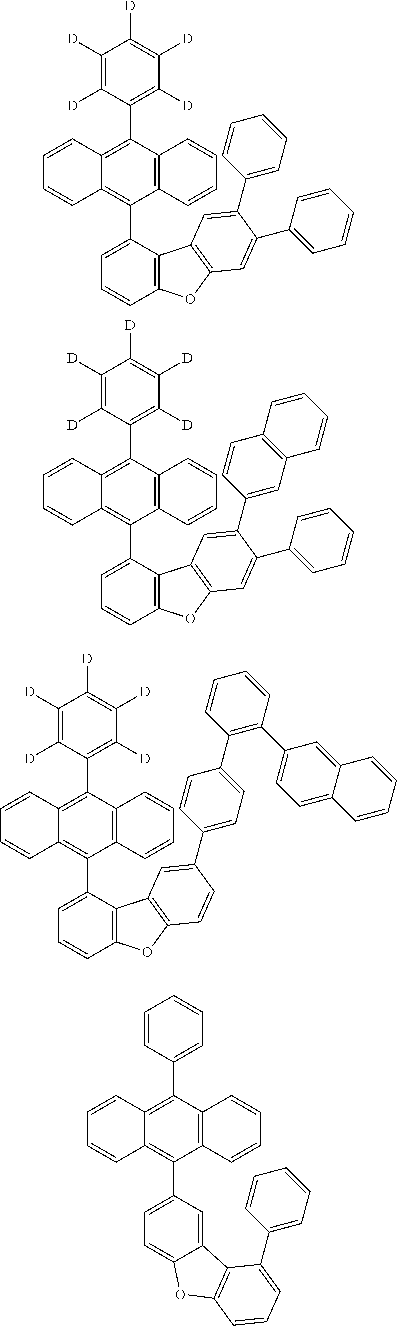

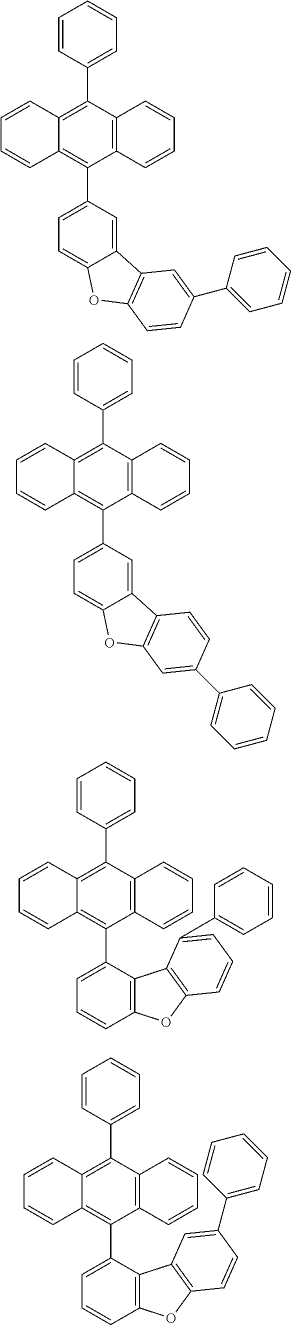

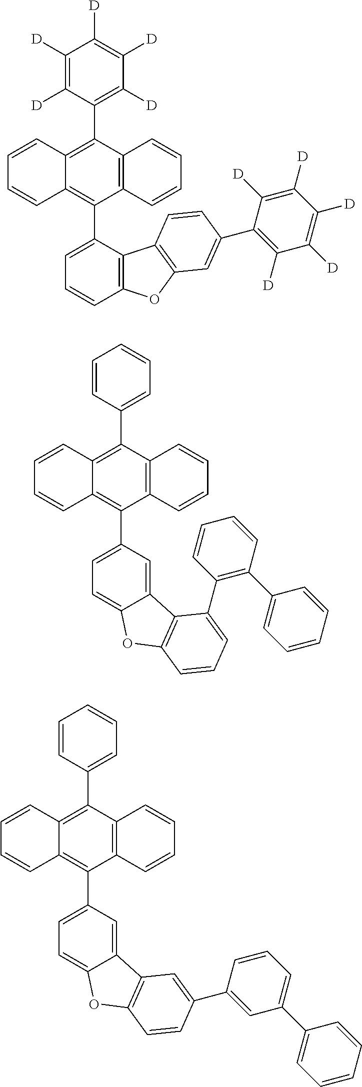 [SMILES: [2H]c1c([2H])c([2H])c(-c2ccc3c(c2)oc2cccc(-c4c5ccccc5c(-c5c([2H])c([2H])c([2H])c([2H])c5[2H])c5ccccc45)c23)c([2H])c1[2H] ; c1ccc(-c2ccccc2-c2cccc3oc4ccc(-c5c6ccccc6c(-c6ccccc6)c6ccccc56)cc4c23)cc1 ; c1ccc(-c2cccc(-c3ccc4oc5ccc(-c6c7ccccc7c(-c7ccccc7)c7ccccc67)cc5c4c3)c2)cc1]

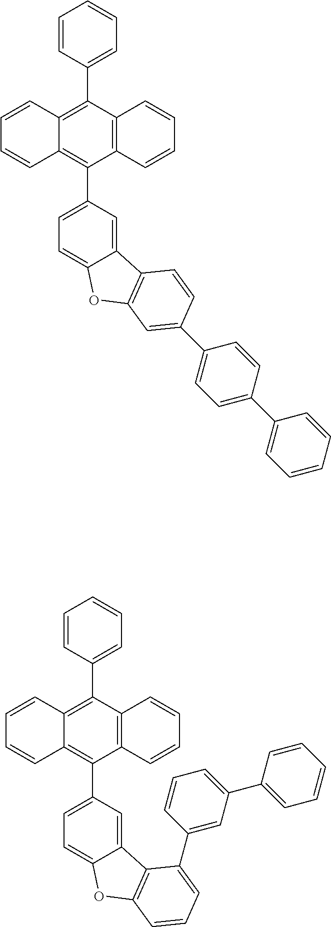 [SMILES: c1ccc(-c2ccc(-c3ccc4c(c3)oc3ccc(-c5c6ccccc6c(-c6ccccc6)c6ccccc56)cc34)cc2)cc1 ; c1ccc(-c2cccc(-c3cccc4oc5ccc(-c6c7ccccc7c(-c7ccccc7)c7ccccc67)cc5c34)c2)cc1]

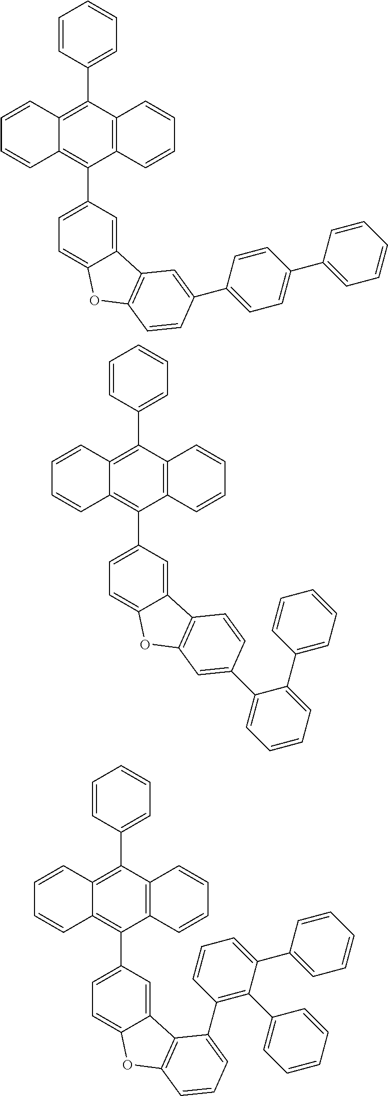

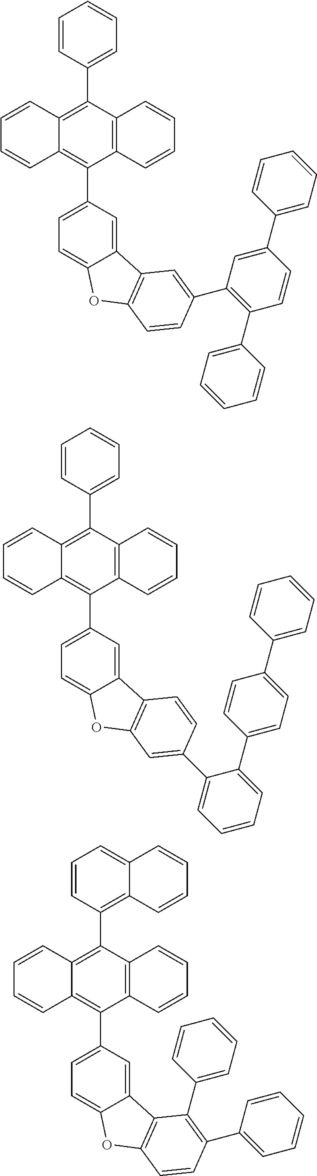

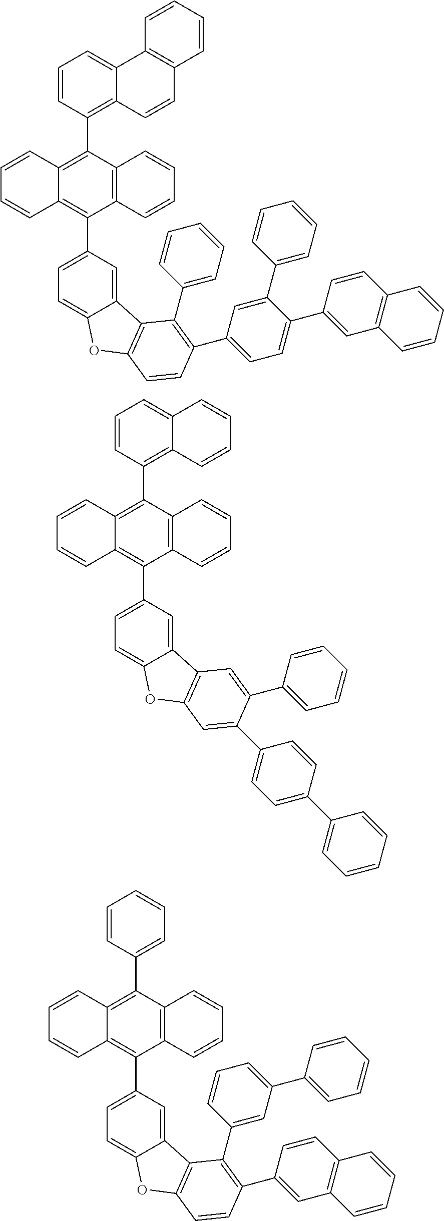

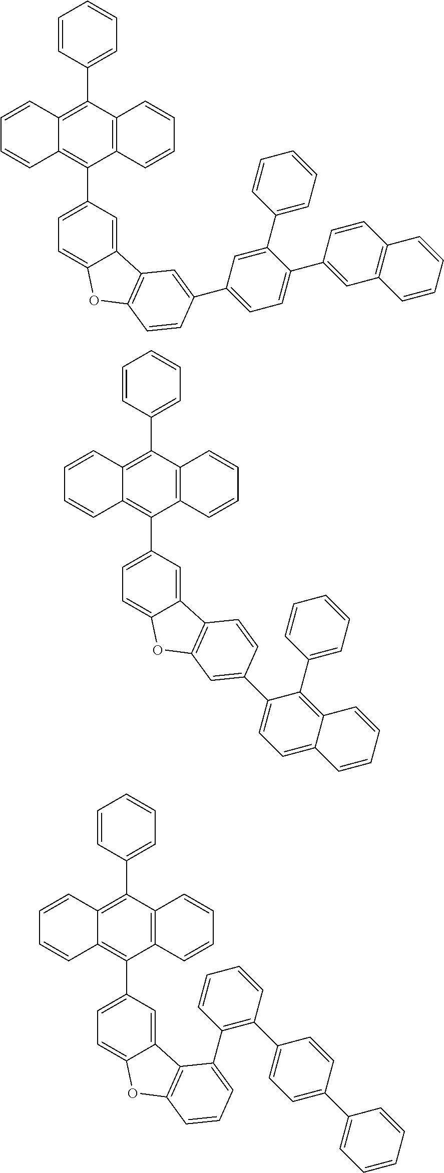

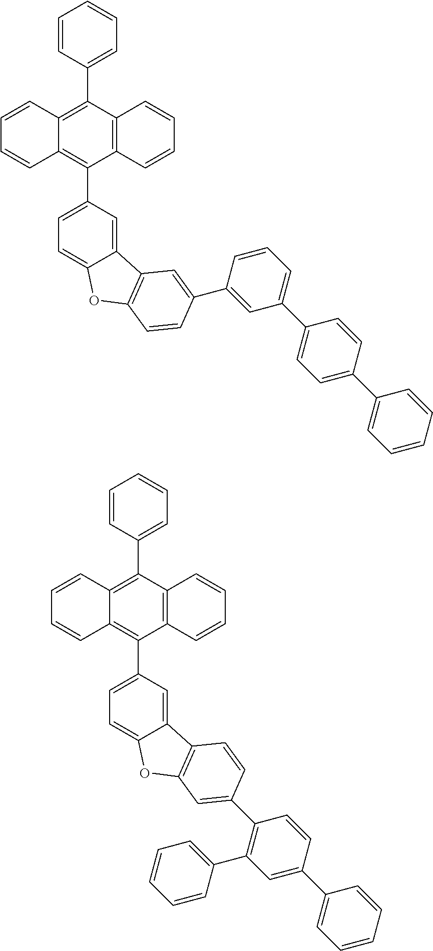 [SMILES: c1ccc(-c2ccc(-c3cccc(-c4ccc5oc6ccc(-c7c8ccccc8c(-c8ccccc8)c8ccccc78)cc6c5c4)c3)cc2)cc1 ; c1ccc(-c2ccc(-c3ccc4c(c3)oc3ccc(-c5c6ccccc6c(-c6ccccc6)c6ccccc56)cc34)c(-c3ccccc3)c2)cc1]

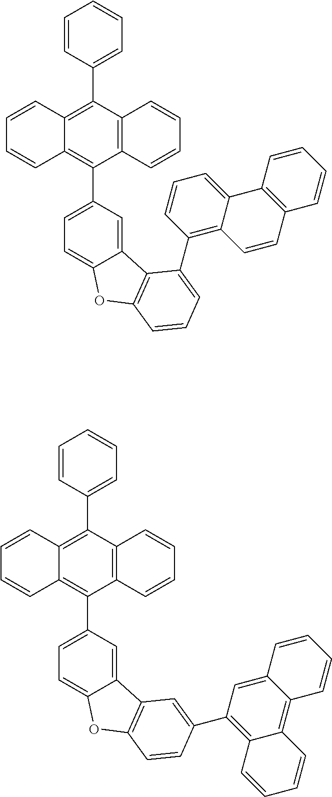 [SMILES: c1ccc(-c2c3ccccc3c(-c3ccc4oc5cccc(-c6cccc7c6ccc6ccccc67)c5c4c3)c3ccccc23)cc1 ; c1ccc(-c2c3ccccc3c(-c3ccc4oc5ccc(-c6cc7ccccc7c7ccccc67)cc5c4c3)c3ccccc23)cc1]

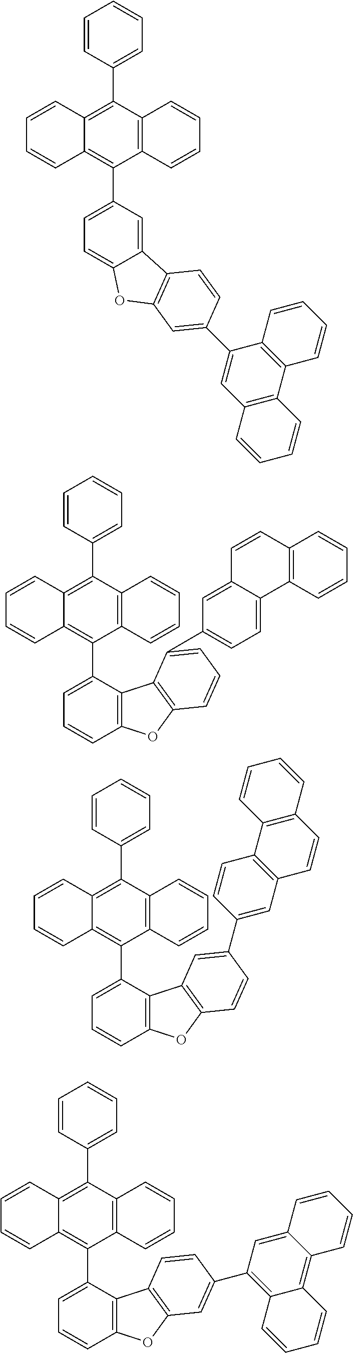

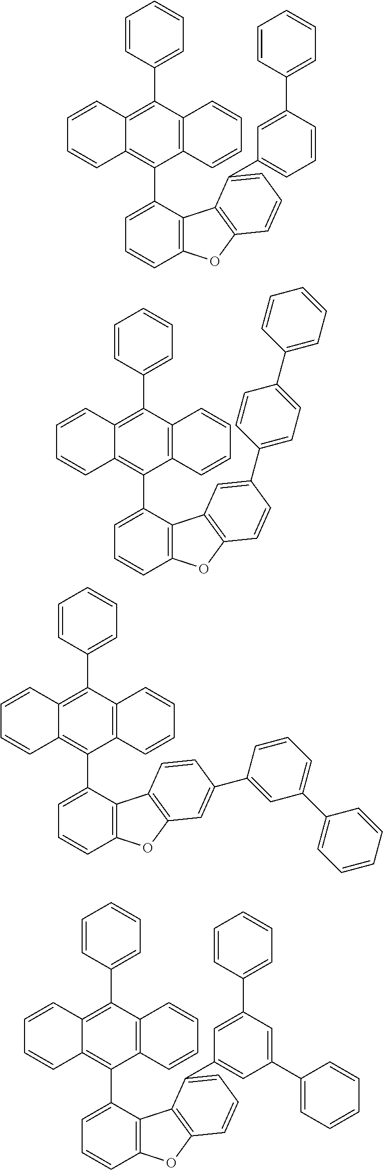

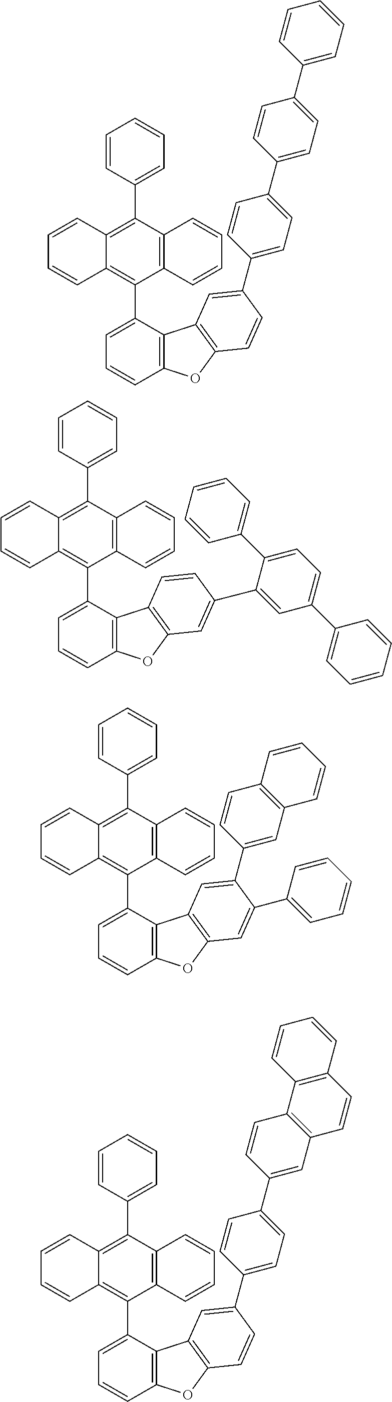

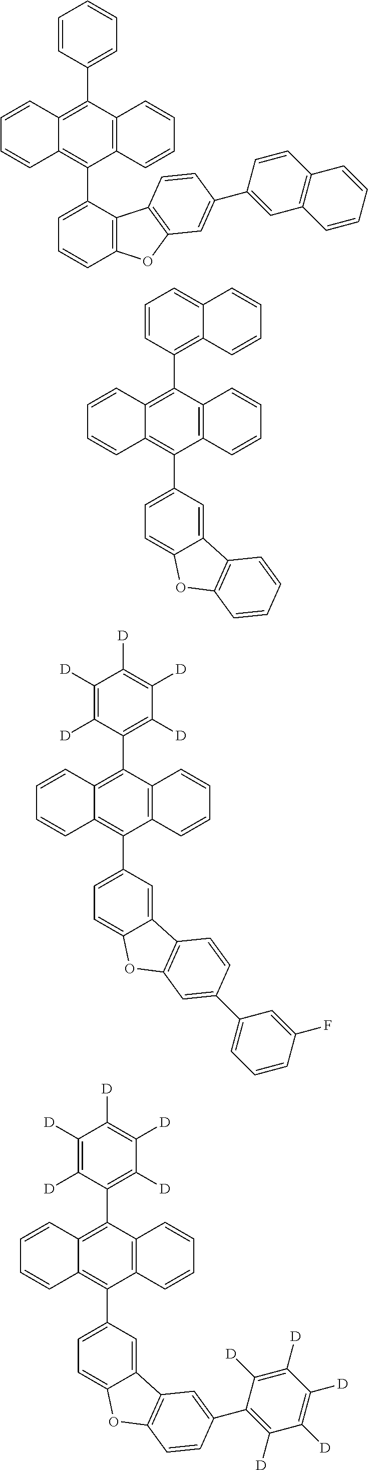

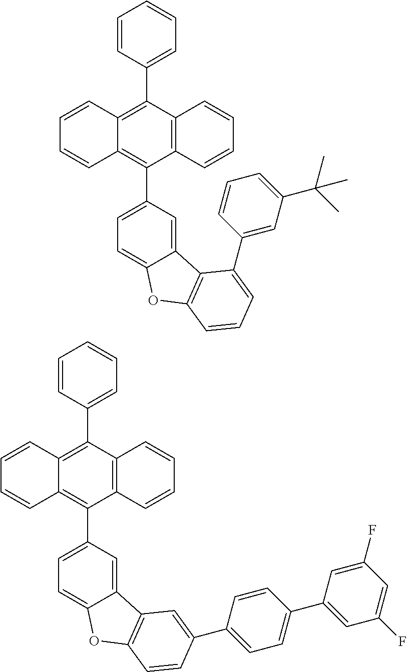 [SMILES: CC(C)(C)c1cccc(-c2cccc3oc4ccc(-c5c6ccccc6c(-c6ccccc6)c6ccccc56)cc4c23)c1 ; Fc1cc(F)cc(-c2ccc(-c3ccc4oc5ccc(-c6c7ccccc7c(-c7ccccc7)c7ccccc67)cc5c4c3)cc2)c1]

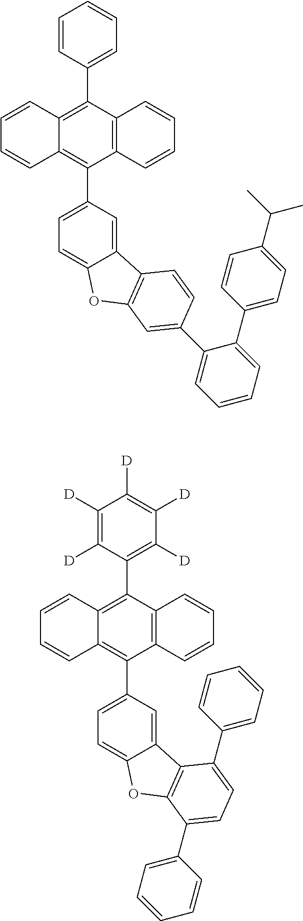 [SMILES: CC(C)c1ccc(-c2ccccc2-c2ccc3c(c2)oc2ccc(-c4c5ccccc5c(-c5ccccc5)c5ccccc45)cc23)cc1 ; [2H]c1c([2H])c([2H])c(-c2c3ccccc3c(-c3ccc4oc5c(-c6ccccc6)ccc(-c6ccccc6)c5c4c3)c3ccccc23)c([2H])c1[2H]]

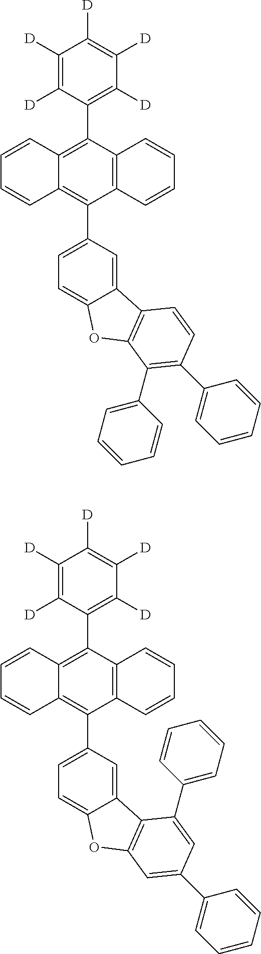 [SMILES: [2H]c1c([2H])c([2H])c(-c2c3ccccc3c(-c3ccc4oc5c(-c6ccccc6)c(-c6ccccc6)ccc5c4c3)c3ccccc23)c([2H])c1[2H] ; [2H]c1c([2H])c([2H])c(-c2c3ccccc3c(-c3ccc4oc5cc(-c6ccccc6)cc(-c6ccccc6)c5c4c3)c3ccccc23)c([2H])c1[2H]]

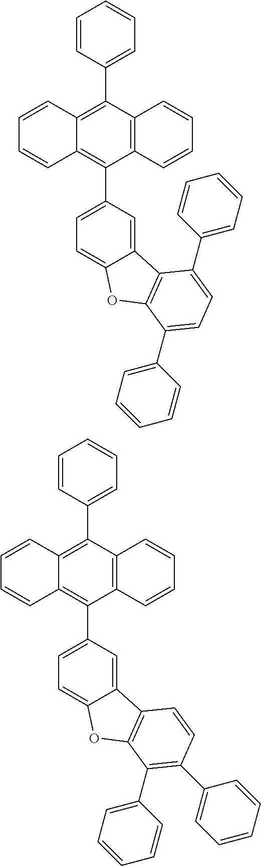

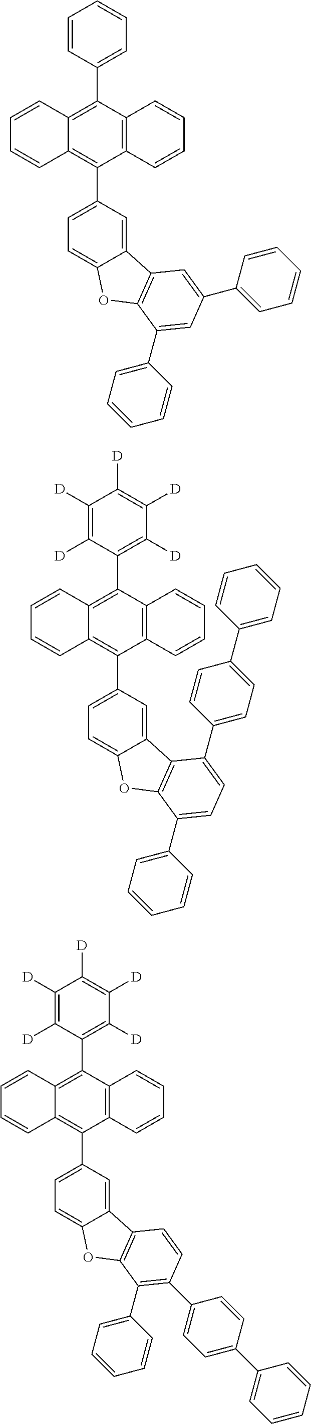

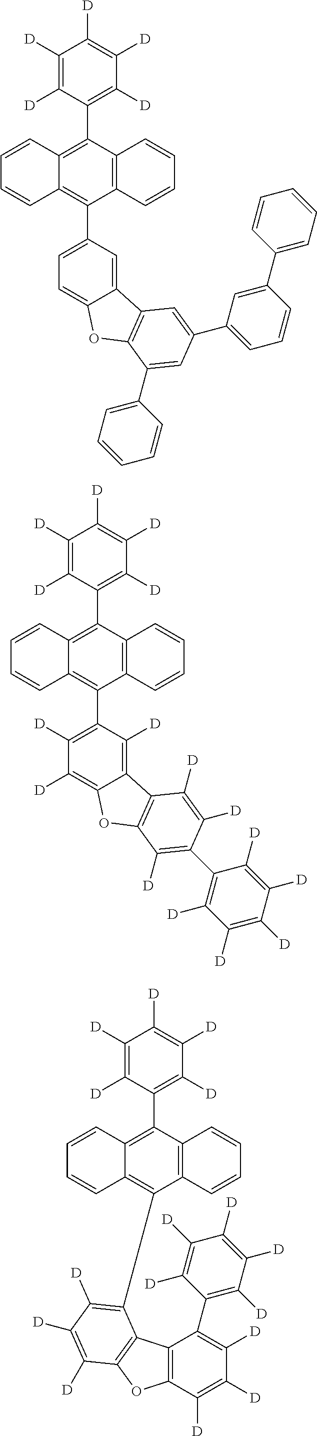

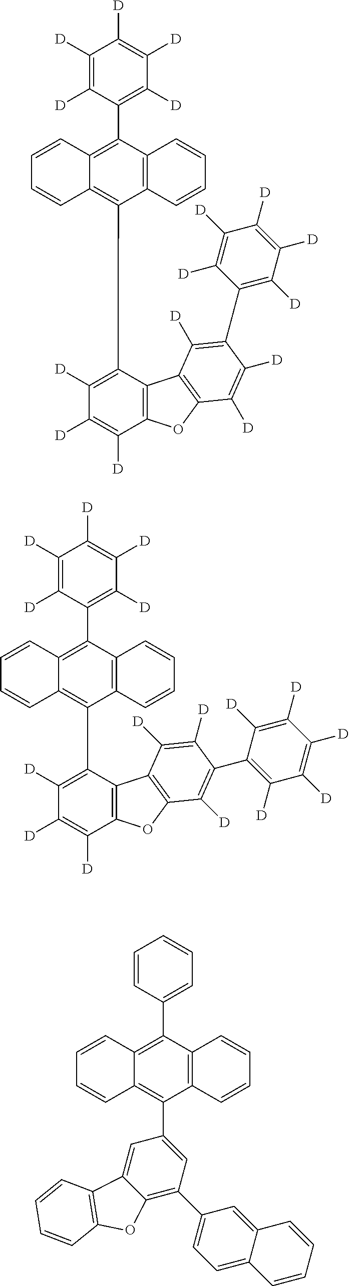 [SMILES: [2H]c1c([2H])c([2H])c(-c2c([2H])c([2H])c3oc4c([2H])c([2H])c([2H])c(-c5c6ccccc6c(-c6c([2H])c([2H])c([2H])c([2H])c6[2H])c6ccccc56)c4c3c2[2H])c([2H])c1[2H] ; [2H]c1c([2H])c([2H])c(-c2c([2H])c([2H])c3c(oc4c([2H])c([2H])c([2H])c(-c5c6ccccc6c(-c6c([2H])c([2H])c([2H])c([2H])c6[2H])c6ccccc56)c43)c2[2H])c([2H])c1[2H] ; c1ccc(-c2c3ccccc3c(-c3cc(-c4ccc5ccccc5c4)c4oc5ccccc5c4c3)c3ccccc23)cc1]

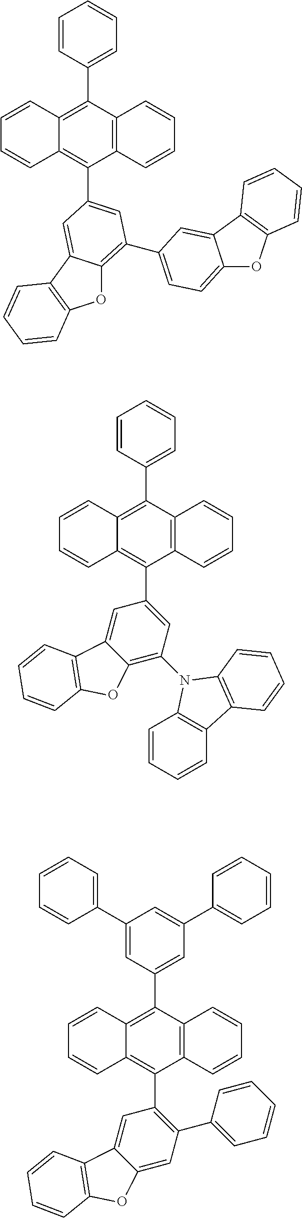 [SMILES: c1ccc(-c2c3ccccc3c(-c3cc(-c4ccc5oc6ccccc6c5c4)c4oc5ccccc5c4c3)c3ccccc23)cc1 ; c1ccc(-c2c3ccccc3c(-c3cc(-n4c5ccccc5c5ccccc54)c4oc5ccccc5c4c3)c3ccccc23)cc1 ; c1ccc(-c2cc(-c3ccccc3)cc(-c3c4ccccc4c(-c4cc5c(cc4-c4ccccc4)oc4ccccc45)c4ccccc34)c2)cc1]

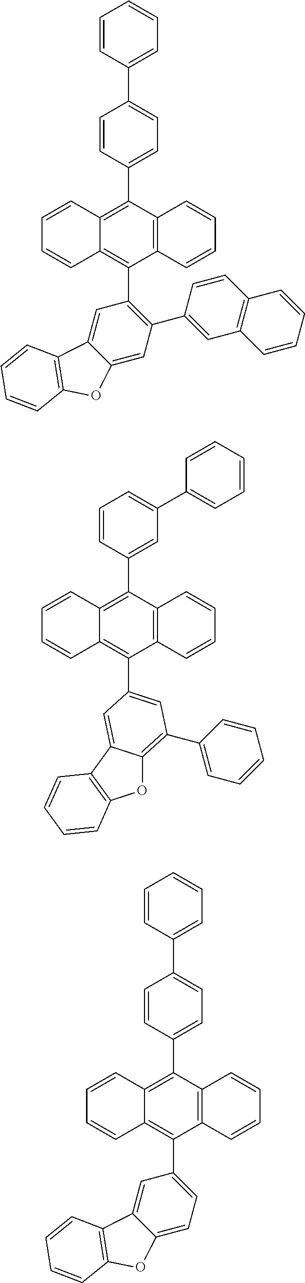 [SMILES: c1ccc(-c2ccc(-c3c4ccccc4c(-c4cc5c(cc4-c4ccc6ccccc6c4)oc4ccccc45)c4ccccc34)cc2)cc1 ; c1ccc(-c2cccc(-c3c4ccccc4c(-c4cc(-c5ccccc5)c5oc6ccccc6c5c4)c4ccccc34)c2)cc1 ; c1ccc(-c2ccc(-c3c4ccccc4c(-c4ccc5oc6ccccc6c5c4)c4ccccc34)cc2)cc1]

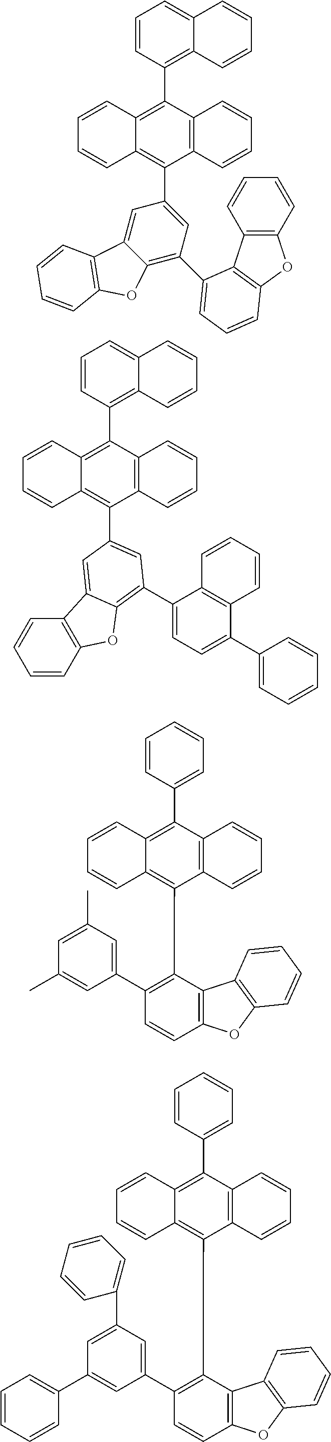

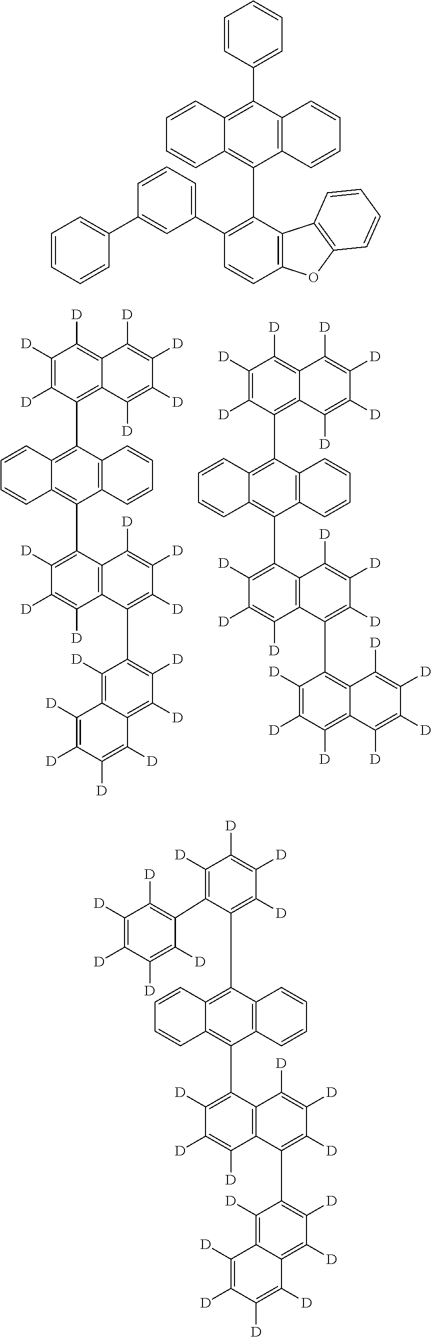

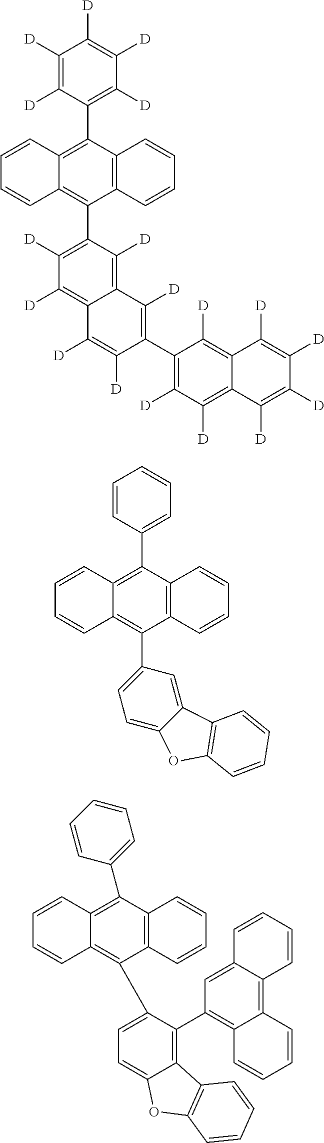 [SMILES: [2H]c1c([2H])c([2H])c(-c2c3ccccc3c(-c3c([2H])c([2H])c4c([2H])c([2H])c(-c5c([2H])c([2H])c6c([2H])c([2H])c([2H])c([2H])c6c5[2H])c([2H])c4c3[2H])c3ccccc23)c([2H])c1[2H] ; c1ccc(-c2c3ccccc3c(-c3ccc4oc5ccccc5c4c3)c3ccccc23)cc1 ; c1ccc(-c2c3ccccc3c(-c3ccc4oc5ccccc5c4c3-c3cc4ccccc4c4ccccc34)c3ccccc23)cc1]

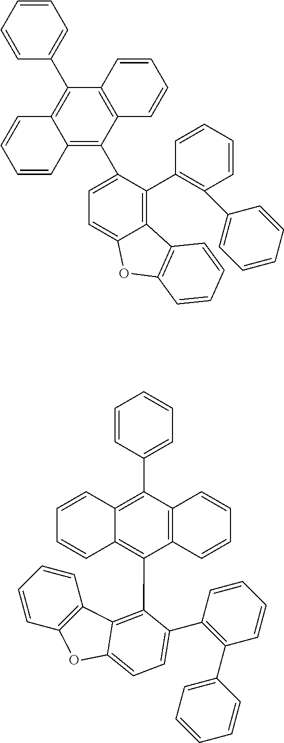 [SMILES: c1ccc(-c2ccccc2-c2c(-c3c4ccccc4c(-c4ccccc4)c4ccccc34)ccc3oc4ccccc4c23)cc1 ; c1ccc(-c2ccccc2-c2ccc3oc4ccccc4c3c2-c2c3ccccc3c(-c3ccccc3)c3ccccc23)cc1]

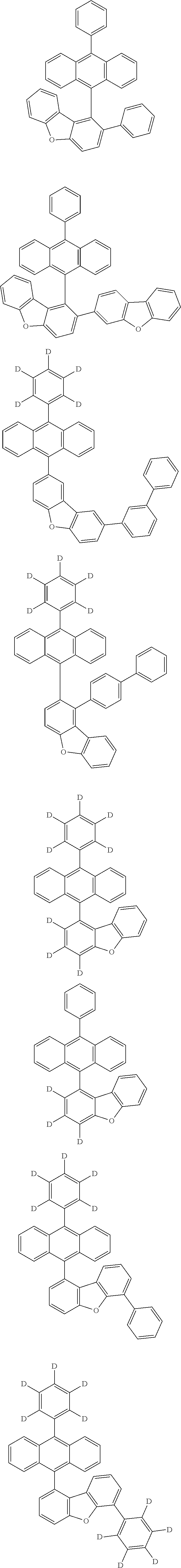

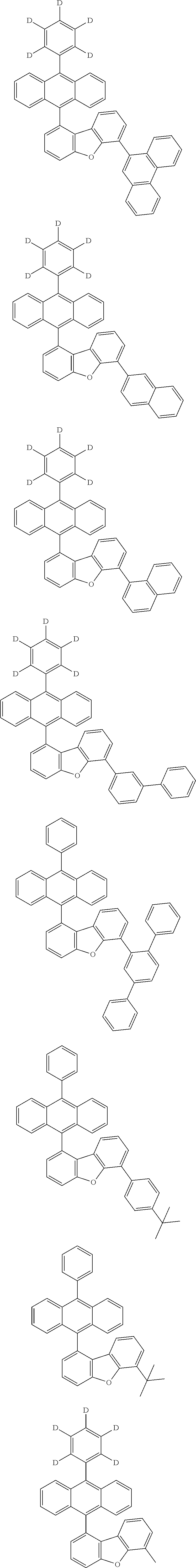

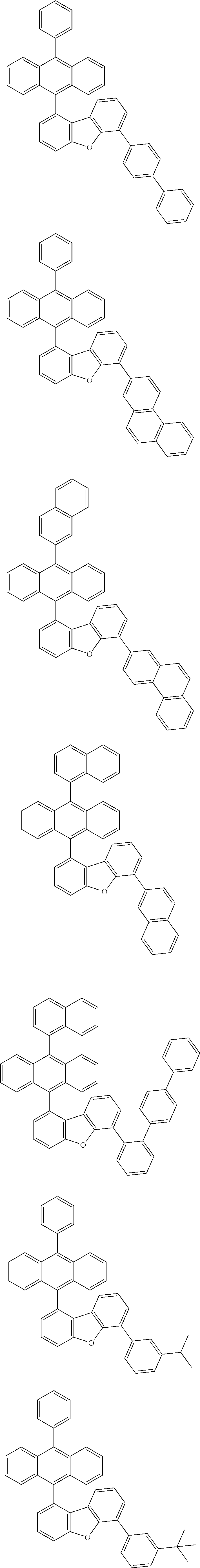

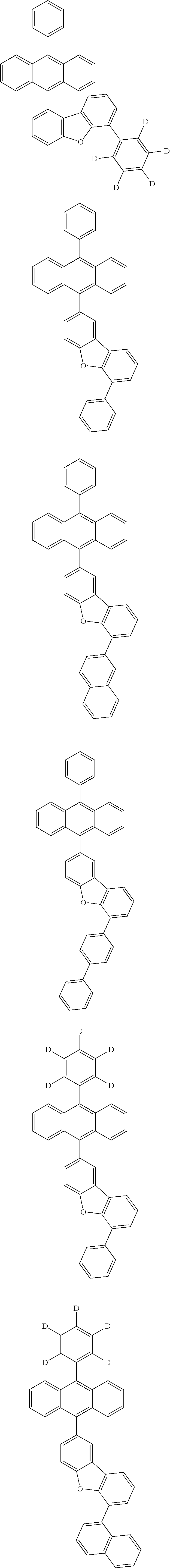

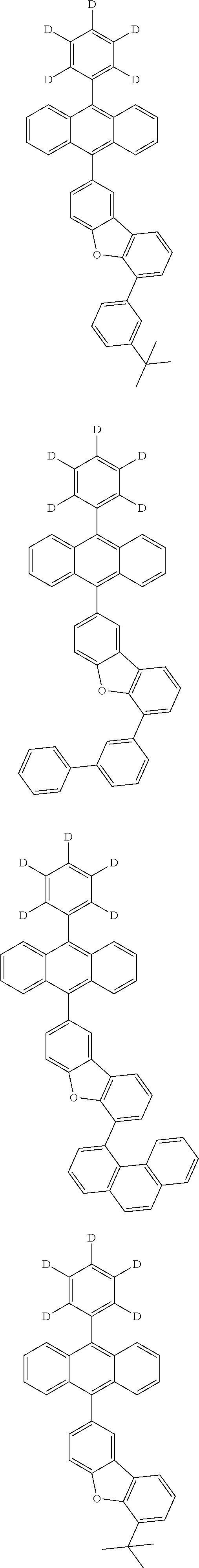 [SMILES: [2H]c1c([2H])c([2H])c(-c2c3ccccc3c(-c3ccc4oc5c(-c6cccc(C(C)(C)C)c6)cccc5c4c3)c3ccccc23)c([2H])c1[2H] ; [2H]c1c([2H])c([2H])c(-c2c3ccccc3c(-c3ccc4oc5c(-c6cccc(-c7ccccc7)c6)cccc5c4c3)c3ccccc23)c([2H])c1[2H] ; [2H]c1c([2H])c([2H])c(-c2c3ccccc3c(-c3ccc4oc5c(-c6cccc7ccc8ccccc8c67)cccc5c4c3)c3ccccc23)c([2H])c1[2H] ; [2H]c1c([2H])c([2H])c(-c2c3ccccc3c(-c3ccc4oc5c(C(C)(C)C)cccc5c4c3)c3ccccc23)c([2H])c1[2H]]

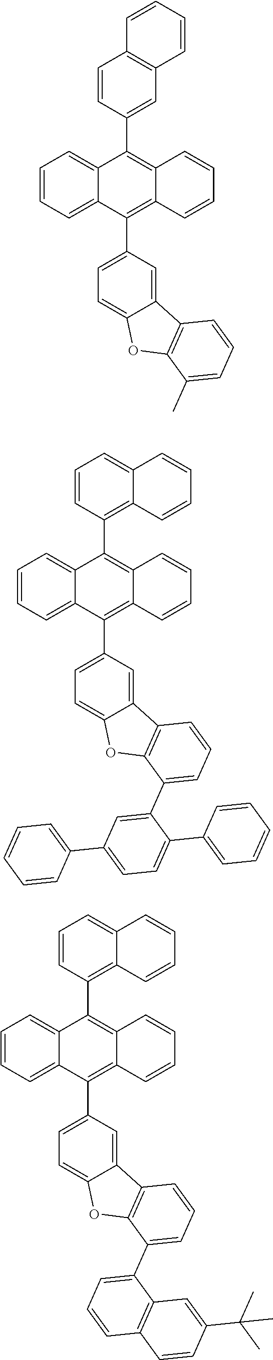

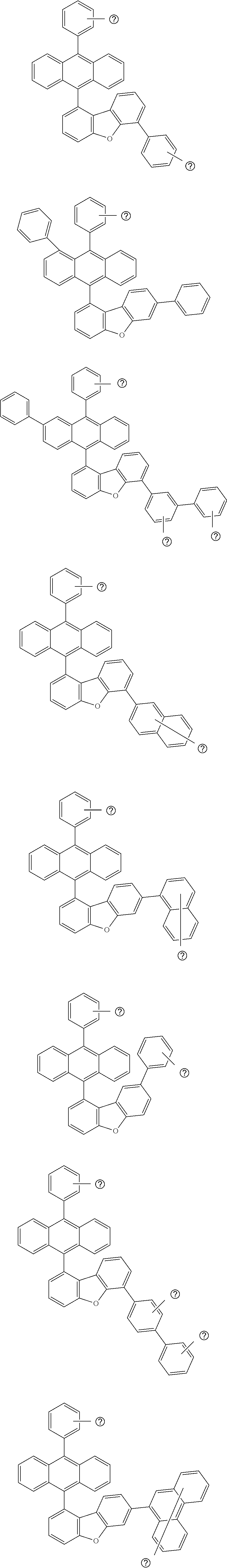

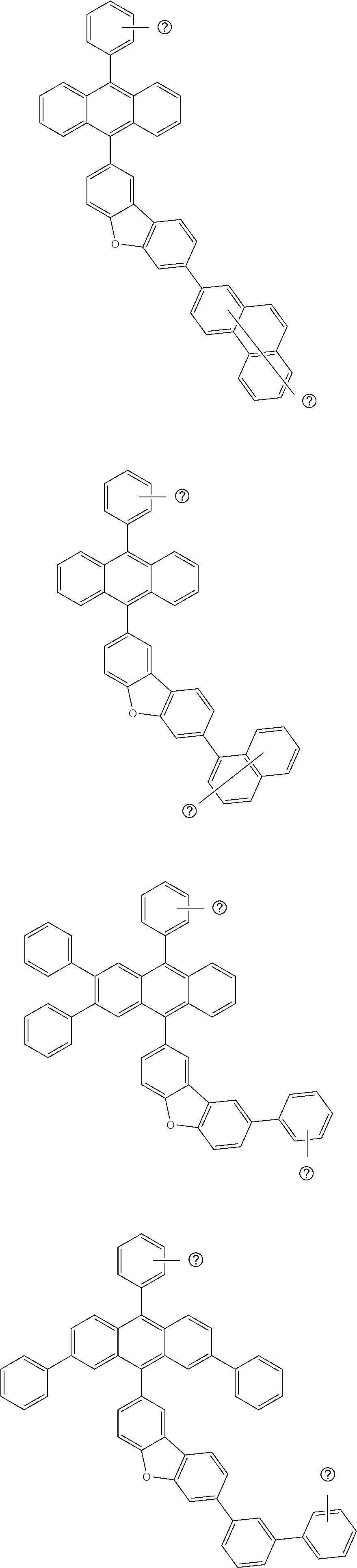

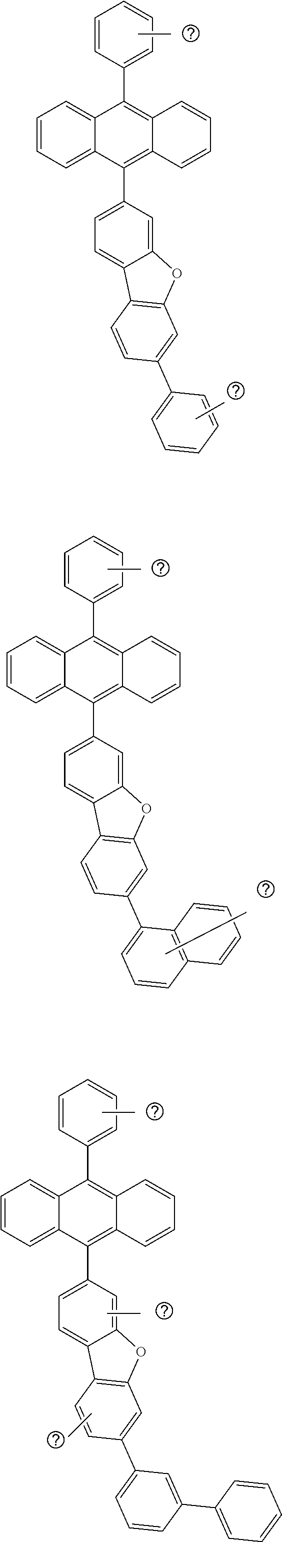

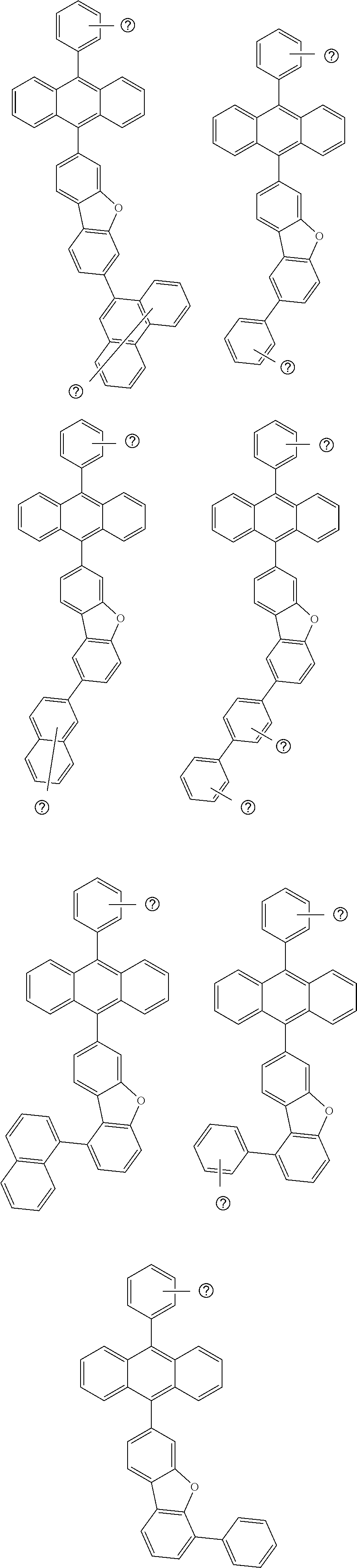

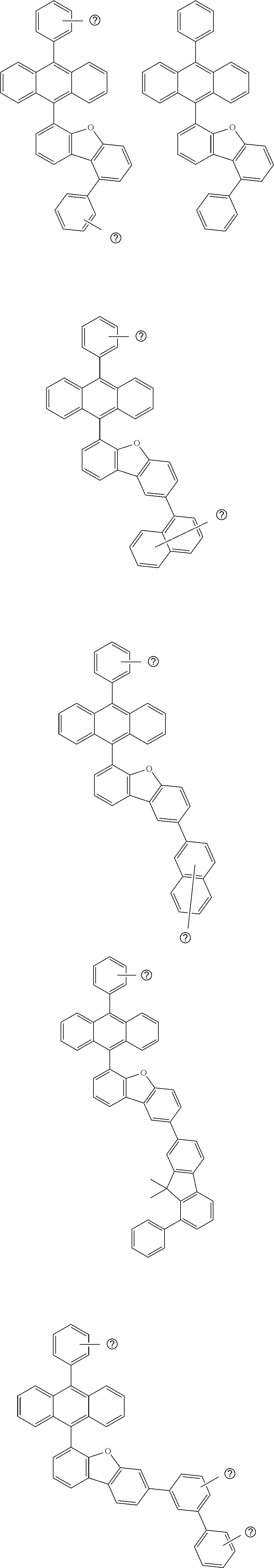

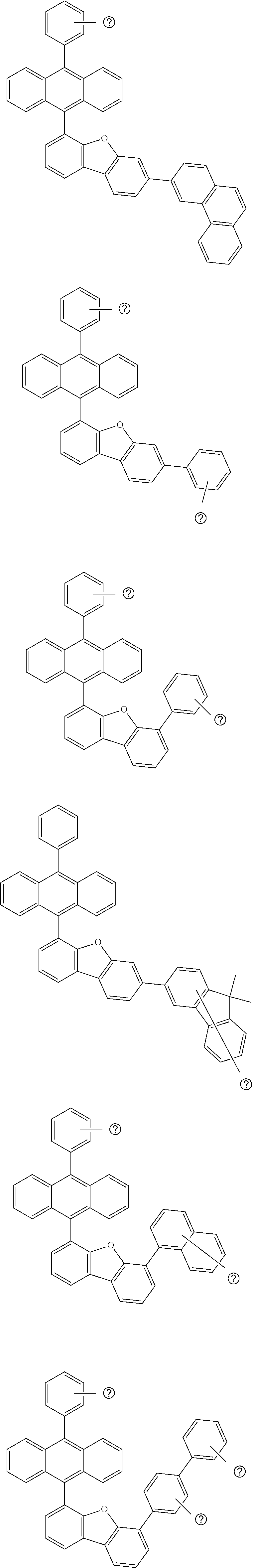

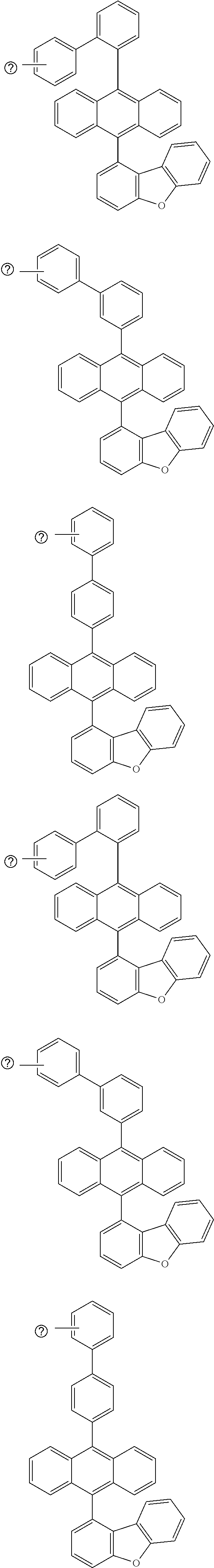

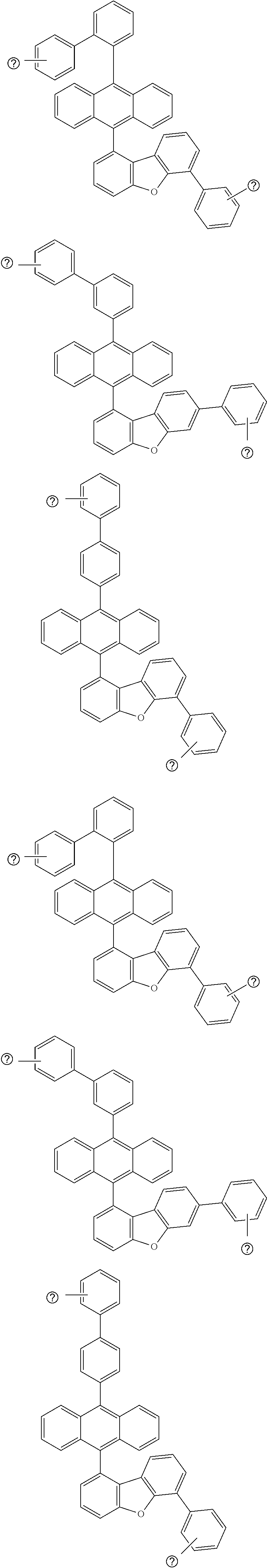

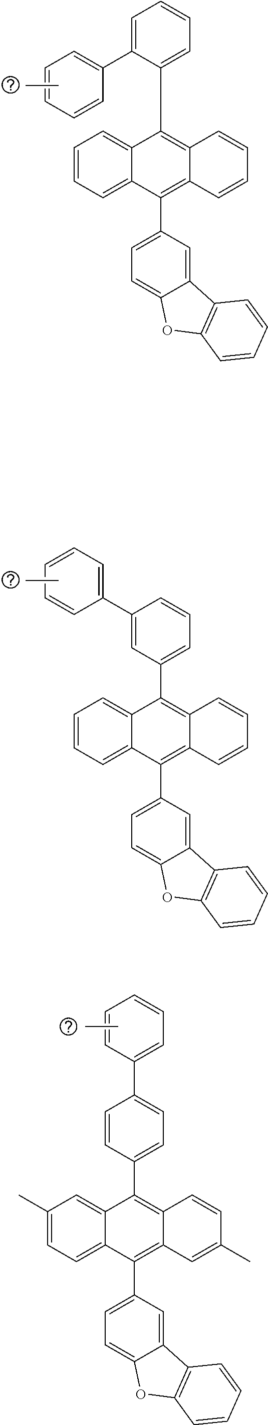

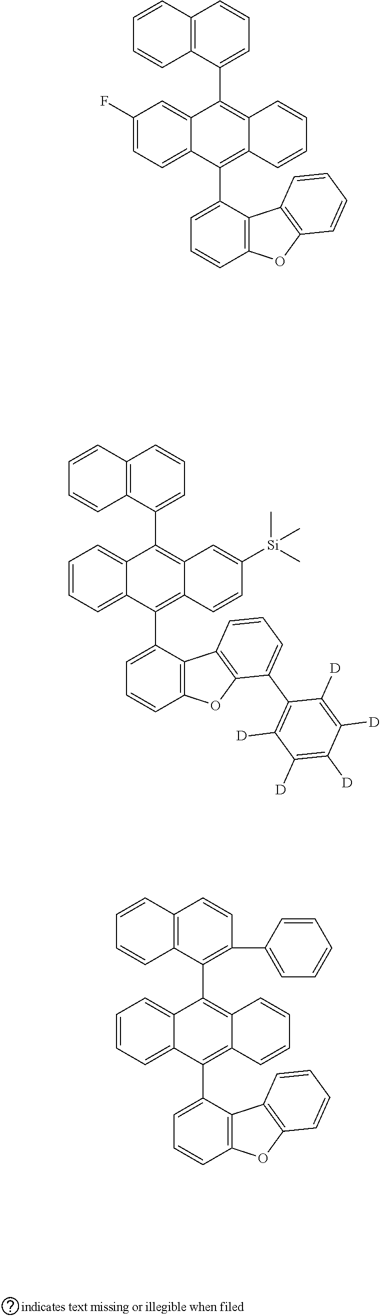 [SMILES: Fc1ccc2c(-c3cccc4oc5ccccc5c34)c3ccccc3c(-c3cccc4ccccc34)c2c1 ; [2H]c1c([2H])c([2H])c(-c2cccc3c2oc2cccc(-c4c5ccccc5c(-c5cccc6ccccc56)c5cc([Si](C)(C)C)ccc45)c23)c([2H])c1[2H] ; c1ccc(-c2ccc3ccccc3c2-c2c3ccccc3c(-c3cccc4oc5ccccc5c34)c3ccccc23)cc1]

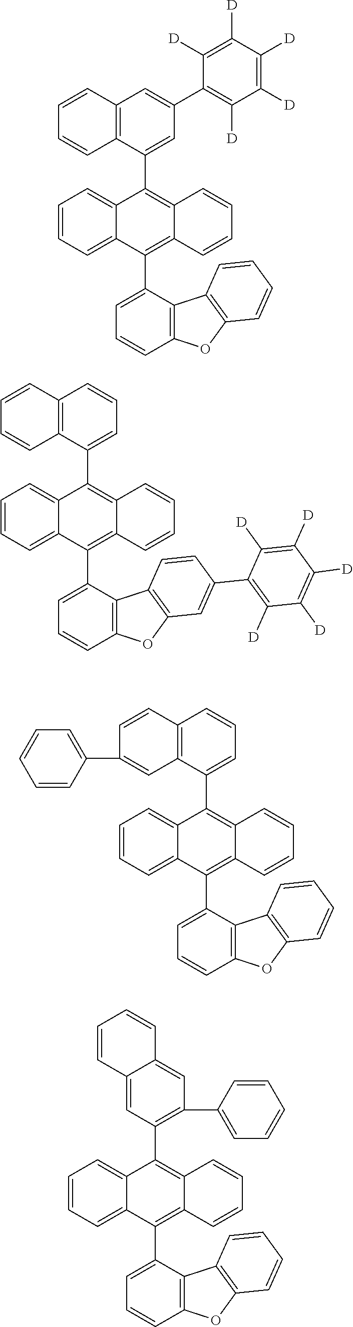 [SMILES: [2H]c1c([2H])c([2H])c(-c2cc(-c3c4ccccc4c(-c4cccc5oc6ccccc6c45)c4ccccc34)c3ccccc3c2)c([2H])c1[2H] ; [2H]c1c([2H])c([2H])c(-c2ccc3c(c2)oc2cccc(-c4c5ccccc5c(-c5cccc6ccccc56)c5ccccc45)c23)c([2H])c1[2H] ; c1ccc(-c2ccc3cccc(-c4c5ccccc5c(-c5cccc6oc7ccccc7c56)c5ccccc45)c3c2)cc1 ; c1ccc(-c2cc3ccccc3cc2-c2c3ccccc3c(-c3cccc4oc5ccccc5c34)c3ccccc23)cc1]

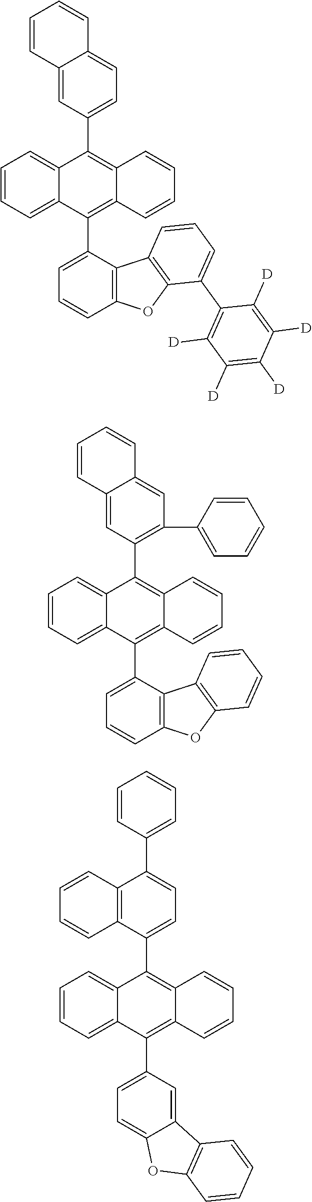

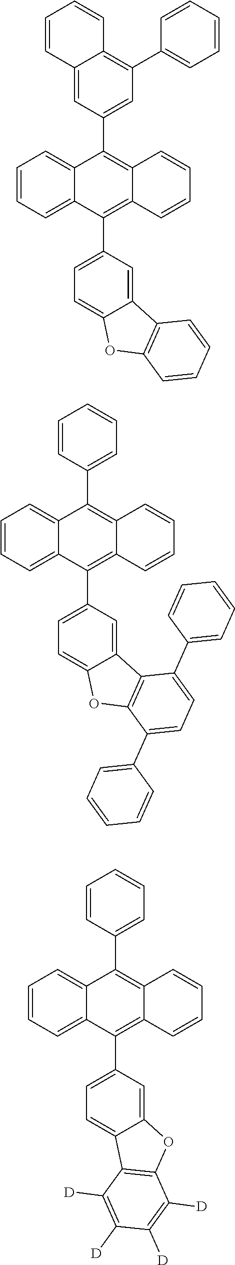

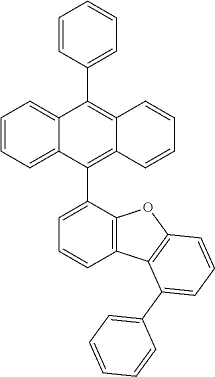 [SMILES: c1ccc(-c2c3ccccc3c(-c3cccc4c3oc3cccc(-c5ccccc5)c34)c3ccccc23)cc1]

The organic layer of the organic electroluminescent device according to the present invention may be formed in a single layer structure, but may be formed in a multilayer structure in which two or more organic layers are stacked. For example, the organic layer may have a structure including a hole injecting layer, a hole transport layer, a hole blocking layer, a light emitting layer, an electron blocking layer, an electron transport layer, an electron injecting layer and the like. However, the structure is not limited thereto, and may also include a smaller or larger number of organic layers, and a preferred organic material layer structure of the organic electroluminescent device according to the present invention will be described in more detail in examples to be described later.

In addition, the organic electroluminescent device according to the present invention may further include various host and dopant materials in addition to the compound (dopant or host) according to the present invention in the light emitting layer as one example, and accordingly, in the light emitting layer, one or more types of compounds different from each other may be mixed or stacked and used as the dopant material as well as the host.

In addition, according to one embodiment of the present invention, the dopant may further include at least one organometallic compound in addition to the compound according to the present invention, which may be mixed or stacked and used.

Accordingly, in the organic electroluminescent device according to one embodiment of the present invention, the light emitting layer may be formed by including a first host, a second host, an organometallic compound and a thermally activated delayed boron-based fluorescent material.

In this case, the organometallic compound functions as a sensitizer, and the thermally activated delayed boron-based fluorescent material functions as a light emitting dopant. The sensitizer compound may receive excitons from the first host and the second host and transfer the excitons to the light emitting dopant.

Accordingly, excitons are transferred from the sensitizer to the light emitting dopant compound through a Dexter energy transfer (DET) or Forster resonance energy transfer (FRET) mechanism, and the exciton energy transferred to the light emitting dopant compound may emit light while being transferred to the ground state. Herein, the excitons of the sensitizer may be transferred from the first host and the second host by the FRET mechanism, or the excitons generated from the host may be transferred by the DET mechanism.

In conclusion, energy is readily transferred between the sensitizer and the light emitting dopant by the FRET or DET mechanism, and triplet-triplet annihilation is suppressed, enabling manufacture of a high-efficiency organic electroluminescent device.

Using the compound of [Formula 1] according to the present invention as a thermally activated delayed boron-based fluorescent material enables Forster energy transfer from the triplet of the phosphorescence sensitizer to the singlet of the thermally activated delayed boron-based fluorescent material, and may improve the lifetime by reducing the number of long-lived triplet excitons involved in the degradation of a device.

In addition, the rate of fluorescence resonance energy transfer from the phosphorescence sensitizer to the fluorescent material increases due to the high molar extinction coefficient, and the emission spectrum is narrowed by the multiple resonance effect, resulting in an increase in the color purity, and as a result, efficiency and lifetime of a device may be improved by such effects.

A more detailed description will be given concerning exemplary embodiments of the organic electroluminescent device according to the present invention.

The organic electroluminescent device of the present invention includes an anode, a hole transport layer, a light emitting layer, an electron transport layer, and a cathode. The organic electroluminescent device of the present invention may optionally further include a hole injecting layer between the anode and the hole transport layer and an electron injecting layer between the electron transport layer and the cathode. If necessary, the organic electroluminescent device of the present invention may further include one or two intermediate layers such as a hole blocking layer or an electron blocking layer. The organic electroluminescent device of the present invention may further include one or more organic layers such as a capping layer that have various functions depending on the desired characteristics of the device.

A specific structure of the organic electroluminescent device according to one embodiment of the present invention, a method for fabricating the device, and materials for the organic layers are as follows.

First, an anode material is coated on a substrate to form an anode. The substrate may be any of those used in general organic electroluminescent devices. The substrate is preferably an organic substrate or a transparent plastic substrate that is excellent in transparency, surface smoothness, ease of handling, and waterproofness. A highly transparent and conductive metal oxide such as indium tin oxide (ITO), indium zinc oxide (IZO), tin oxide (SnO₂) or zinc oxide (ZnO) is used as the anode material.

The hole injecting material is not specially limited so long as it is usually used in the art. Specific examples of such materials include 4,4′,4″-tris(2-naphthylphenyl-phenylamino)triphenylamine (2-TNATA), N,N′-di(1-naphthyl)-N,N′-diphenylbenzidine (NPD), N,N′-diphenyl-N,N′-bis(3-methylphenyl)-1,1′-biphenyl-4,4′-diamine (TPD), N,N′-diphenyl-N,N′-bis(4-(phenyl-m-tolylamino)phenyl)biphenyl-4,4′-diamine (DNTPD) and 1,4,5,8,9,11-hexaazatriphenylenehexacarbonitrile (HAT-CN).

The hole transport material is not specially limited so long as it is commonly used in the art. Examples of such materials include N,N′-bis(3-methylphenyl)-N,N′-diphenyl-(1,1-biphenyl)-4,4′-diamine (TPD) and N,N′-di(naphthalen-1-yl)-N,N′-diphenylbenzidine (α-NPD).

Subsequently, a hole auxiliary layer and a light emitting layer are sequentially stacked on the hole transport layer. A hole blocking layer may be optionally formed on the light emitting layer by vacuum thermal evaporation or spin coating. The hole blocking layer is formed as a thin film and blocks holes from entering a cathode through the organic light emitting layer. This role of the hole blocking layer prevents the lifetime and efficiency of the device from deteriorating. A material having a very low highest occupied molecular orbital (HOMO) energy level is used for the hole blocking layer. The hole blocking material is not particularly limited so long as it can transport electrons and has a higher ionization potential than the light emitting compound. Representative examples of suitable hole blocking materials include BAlq, BCP, and TPBI.

Examples of materials for the hole blocking layer include, but are not limited to, BAlq, BCP, Bphen, TPBI, TAZ, BeBq₂, OXD-7, and Liq.

An electron transport layer is deposited on the hole blocking layer by vacuum thermal evaporation or spin coating, and an electron injecting layer is formed thereon. A cathode metal is deposited on the electron injecting layer by vacuum thermal evaporation to form a cathode, completing the fabrication of the organic electroluminescent device.

For example, lithium (Li), magnesium (Mg), aluminum (Al), aluminum-lithium (Al—Li), calcium (Ca), magnesium-indium (Mg—In) or magnesium-silver (Mg—Ag) may be used as the metal for the formation of the cathode. The organic electroluminescent device may be of top emission type. In this case, a transmissive material such as ITO or IZO may be used to form the cathode.

A material for the electron transport layer functions to stably transport electrons injected from the cathode. The electron transport material may be any of those known in the art and examples thereof include, but are not limited to, quinoline derivatives, particularly tris(8-quinolinolato)aluminum (Alq₃), TAZ, BAlq, beryllium bis(benzoquinolin-10-olate) (Bebq₂), and oxadiazole derivatives such as PBD, BMD, and BND.

Each of the organic layers can be formed by a monomolecular deposition or solution process. According to the monomolecular deposition process, the material for each layer is evaporated into a thin film under heat and vacuum or reduced pressure. According to the solution process, the material for each layer is mixed with a suitable solvent and the mixture is then formed into a thin film by a suitable method such as ink-jet printing, roll-to-roll coating, screen printing, spray coating, dip coating or spin coating.

The organic electroluminescent device of the present invention can be used in a display or lighting system selected from flat panel displays, flexible displays, monochromatic flat panel lighting systems, white flat panel lighting systems, flexible monochromatic lighting systems, flexible white lighting systems, displays for automotives or aircraft, displays for virtual reality, and displays for augmented reality.

The present invention will be more specifically explained with reference to the following synthesis examples and fabrication examples. However, these examples are provided to assist in understanding the invention and are not intended to limit the scope of the present invention.

### Synthesis Example 1: Synthesis of [BM-1]

### Synthesis Example 1-1: Synthesis of A-1

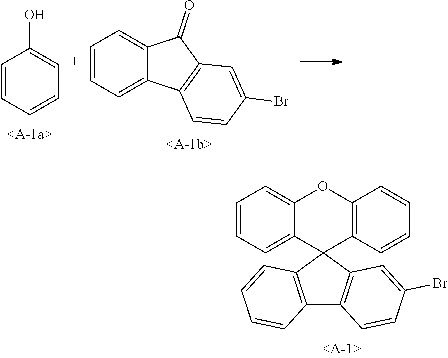 [SMILES: OC1=[C+]C=CC=C1 ; O=C1c2ccccc2-c2ccc(Br)cc21 ; Brc1ccc2c(c1)C1(c3ccccc3Oc3ccccc31)c1ccccc1-2]

In a round bottom flask, a mixture of <A-1b> (10 g), <A-1a> (7.3 g) and excess POCl₃ was stirred under reflux at 120° C. After the reaction was finished, the result was cooled to room temperature, and excess ethanol was introduced thereto, followed by filtering. The filtered solid was dissolved in pyridine, heated, then cooled to room temperature, and then filtered. The result was recrystallized with chloroform and ethyl acetate to obtain <A-1>. (14 g, 87%)

### Synthesis Example 1-2: Synthesis of A-2

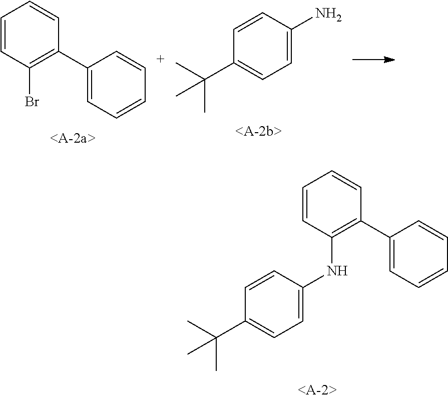

To a round bottom flask, <A-2a> (15 g), <A-2b> (24.6 g), tris(dibenzylideneacetone)dipalladium(0) (1.84 g), bis(diphenylphosphino)-1,1′-binaphthyl (1.25 g), sodium tert-butoxide (19.3 g) and toluene (200 mL) were introduced, and the mixture was stirred under reflux for 3 hours. After cooling the result to room temperature, ethyl acetate and water were introduced thereto. Then, the organic layer was separated, and purified by silica gel chromatography to obtain <A-2>. (25.7 g, 84.8%)

### Synthesis Example 1-3: Synthesis of A-3

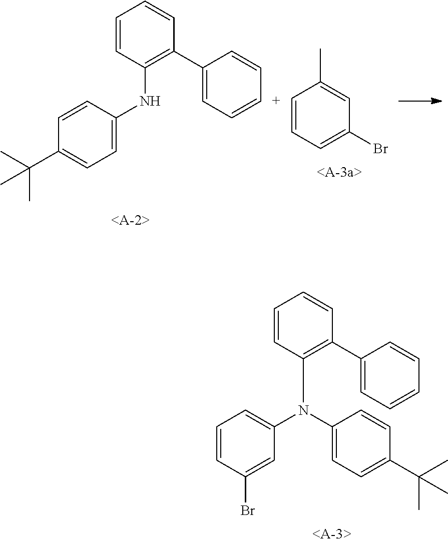

<A-3> was obtained in the same manner as in Synthesis Example 1-2, except that <A-3a> was used instead of <A-2a>, and <A-2> was used instead of <A-2b>. (Yield 46%)

### Synthesis Example 1-4: Synthesis of A-4

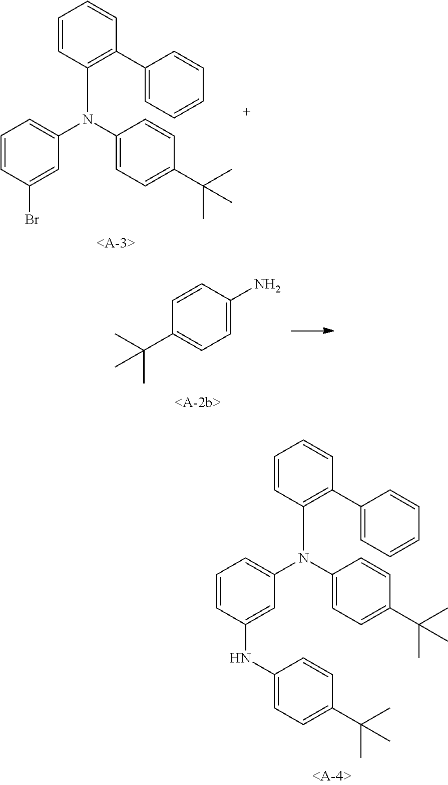 [SMILES: CC(C)(C)c1ccc(N(c2cccc(Br)c2)c2ccccc2-c2ccccc2)cc1 ; CC(C)(C)c1ccc(N)cc1 ; CC(C)(C)c1ccc(Nc2cccc(N(c3ccc(C(C)(C)C)cc3)c3ccccc3-c3ccccc3)c2)cc1]

<A-4> was obtained in the same manner as in Synthesis Example 1-2, except that <A-3> was used instead of <A-2a>. (Yield 79%)

### Synthesis Example 1-5: Synthesis of A-5

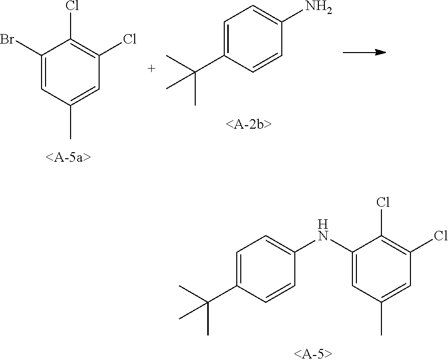

<A-5> was obtained in the same manner as in Synthesis Example 1-2, except that <A-5a> was used instead of <A-2a>. (Yield 76%)

### Synthesis Example 1-6: Synthesis of A-6

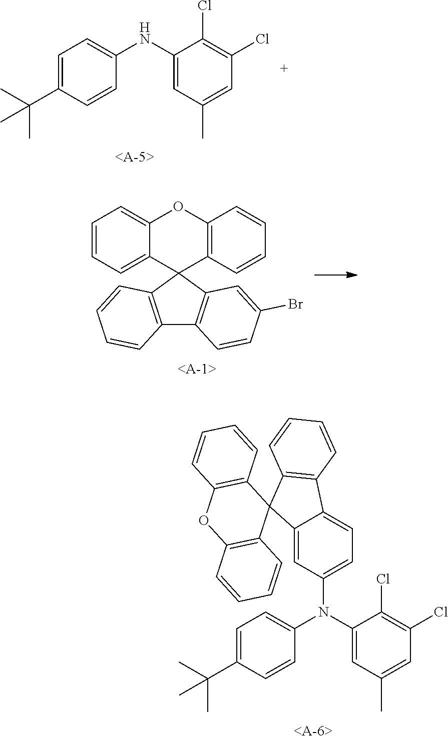 [SMILES: Cc1cc(Cl)c(Cl)c(Nc2ccc(C(C)(C)C)cc2)c1 ; Brc1ccc2c(c1)C1(c3ccccc3Oc3ccccc31)c1ccccc1-2 ; Cc1cc(Cl)c(Cl)c(N(c2ccc(C(C)(C)C)cc2)c2ccc3c(c2)C2(c4ccccc4Oc4ccccc42)c2ccccc2-3)c1]

To a round bottom flask, <A-5> (20 g), <A-1> (29.3 g), bis(tri-tert-butylphosphine)palladium(0) (0.7 g), sodium tert-butoxide (12.5 g) and toluene (250 mL) were introduced, and then the mixture was stirred under reflux for 6 hours. After cooling the result to room temperature, ethyl acetate and water were introduced thereto. Then, the organic layer was separated, and then purified by silica gel chromatography to obtain <A-6>. (25.8 g, 62.3%)

### Synthesis Example 1-7: Synthesis of A-7

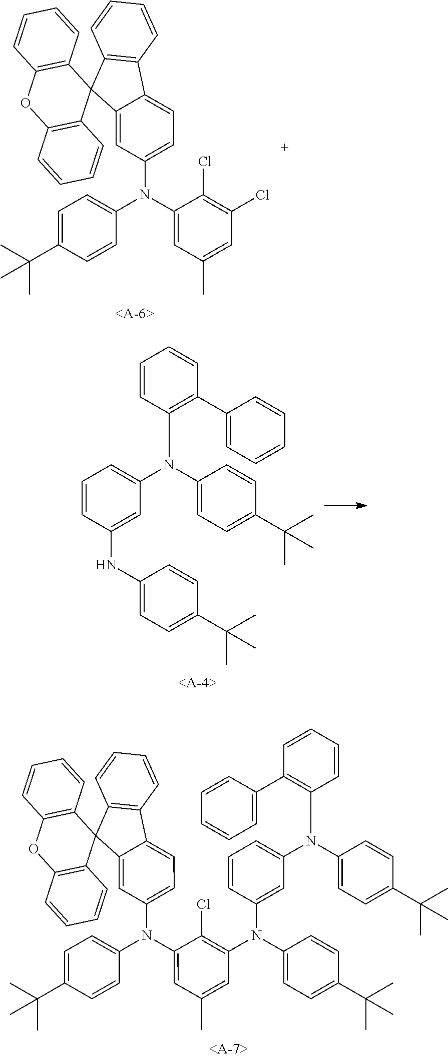 [SMILES: Cc1cc(Cl)c(Cl)c(N(c2ccc(C(C)(C)C)cc2)c2ccc3c(c2)C2(c4ccccc4Oc4ccccc42)c2ccccc2-3)c1 ; CC(C)(C)c1ccc(Nc2cccc(N(c3ccc(C(C)(C)C)cc3)c3ccccc3-c3ccccc3)c2)cc1 ; Cc1cc(N(c2ccc(C(C)(C)C)cc2)c2cccc(N(c3ccc(C(C)(C)C)cc3)c3ccccc3-c3ccccc3)c2)c(Cl)c(N(c2ccc(C(C)(C)C)cc2)c2ccc3c(c2)C2(c4ccccc4Oc4ccccc42)c2ccccc2-3)c1]

<A-7> was obtained in the same manner as in Synthesis Example 1-6, except that <A-4> was used instead of <A-5>, and <A-6> was used instead of <A-1>. (Yield 59.7%)

### Synthesis Example 1-8: Synthesis of [BM-1]

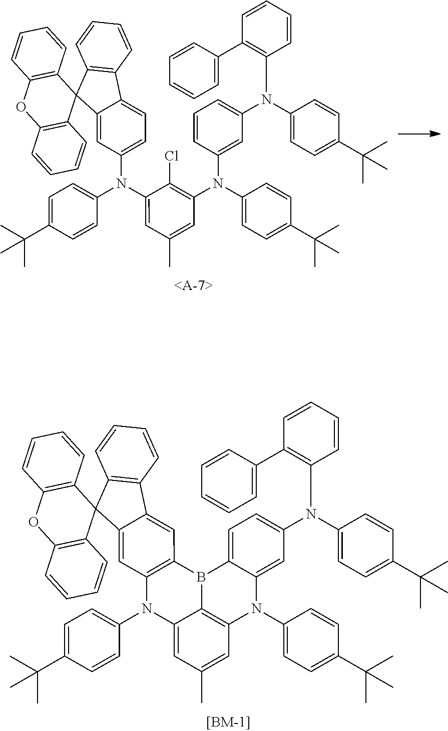

To a round bottom flask, <A-7> (20 g) and tert-butylbenzene (240 mL) were introduced, and then a 1.7 M tert-butyllithium pentane solution (31 mL) was added dropwise thereto at −78° C. After raising the temperature to 60° C., the mixture was stirred for 2 hours, and the pentane was completely removed by blowing nitrogen at 60° C. After lowering the temperature to −78° C., boron tribromide (3 mL) was added dropwise thereto. After raising the temperature to room temperature, the mixture was stirred for 2 hours, and after lowering the temperature to 0° C., N,N-diisopropylethylamine (6 mL) was added dropwise thereto. After raising the temperature to 120° C., the mixture was stirred for 16 hours. After lowering the temperature to room temperature, a 10% aqueous sodium acetate solution and ethyl acetate were introduced thereto. The organic layer was separated, concentrated under reduced pressure, and then purified by silica gel chromatography to obtain [BM-1]. (2.2 g, 11.3%)

MS (MALDI-TOF): m/z 1099.56 [M⁺]

### Synthesis Example 2: Synthesis of [BM-2]

### Synthesis Example 2-1: Synthesis of B-1

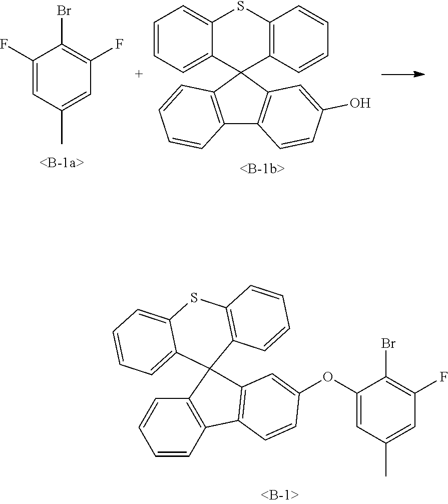

To a round bottom flask, <B-1b> (30 g), <B-1a> (22.2 g), potassium carbonate (34 g) and N,N-dimethylformamide (300 mL) were introduced, and the mixture was refluxed for 24 hours. When the reaction was finished, the reaction solution was cooled to room temperature, and then filtered through celite. The filtrate was concentrated under reduced pressure and then <B-1> was obtained using column chromatography. (33 g, 72.7%)

### Synthesis Example 2-2: Synthesis of B-2

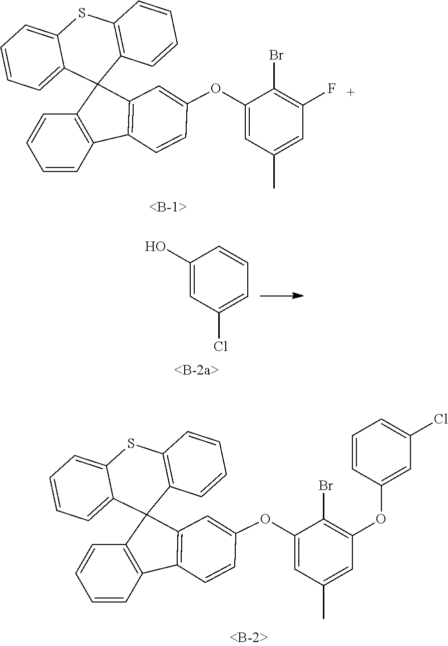 [SMILES: Cc1cc(F)c(Br)c(Oc2ccc3c(c2)C2(c4ccccc4Sc4ccccc42)c2ccccc2-3)c1 ; Oc1cccc(Cl)c1 ; Cc1cc(Oc2cccc(Cl)c2)c(Br)c(Oc2ccc3c(c2)C2(c4ccccc4Sc4ccccc42)c2ccccc2-3)c1]

<B-2> was obtained in the same manner as in Synthesis Example 2-1, except that <B-1> was used instead of <B-1a>, and <B-2a> was used instead of <B-1b>. (Yield 64%)

### Synthesis Example 2-3: Synthesis of B-3

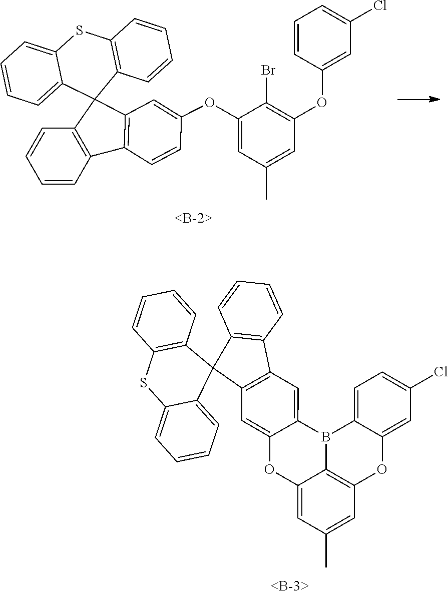 [SMILES: Cc1cc(Oc2cccc(Cl)c2)c(Br)c(Oc2ccc3c(c2)C2(c4ccccc4Sc4ccccc42)c2ccccc2-3)c1 ; Cc1cc2c3c(c1)Oc1cc4c(cc1B3c1ccc(Cl)cc1O2)-c1ccccc1C41c2ccccc2Sc2ccccc21]

To a round bottom flask under the nitrogen atmosphere, <B-2> (30 g) and m-xylene (300 mL) were introduced. The reaction solution was cooled to 0° C., and then stirred for 30 minutes. After that, 1.6 M n-butyllithium (27 mL) was slowly added dropwise thereto, and when the dropwise addition was completed, the temperature of the reaction solution was raised to room temperature, and then the reaction solution was stirred for 1 hour. After 1 hour, the reaction solution was cooled to −30° C., and then boron tribromide (14 g) was added dropwise thereto. After the dropwise addition, the temperature of the reaction solution was raised to room temperature, and then the reaction solution was stirred for 1 hour. Then, the reaction solution was cooled to 0° C. again, then N,N-diisopropylethylamine (22.37 g) was introduced thereto, and the mixture was reacted for 12 hours at 130° C. When the reaction was completed, the reaction solution was cooled to room temperature, and then filtered. The solid was washed with methanol and recrystallized with monochlorobenzene to obtain <B-3>. (7.2 g, 26.9%)

### Synthesis Example 2-4: Synthesis of [BM-2]

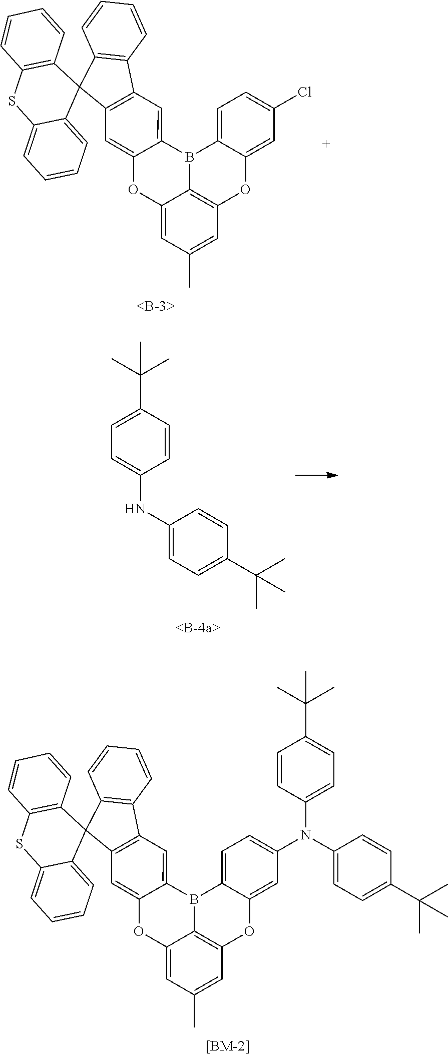 [SMILES: Cc1cc2c3c(c1)Oc1cc4c(cc1B3c1ccc(Cl)cc1O2)-c1ccccc1C41c2ccccc2Sc2ccccc21 ; CC(C)(C)c1ccc(Nc2ccc(C(C)(C)C)cc2)cc1 ; Cc1cc2c3c(c1)Oc1cc4c(cc1B3c1ccc(N(c3ccc(C(C)(C)C)cc3)c3ccc(C(C)(C)C)cc3)cc1O2)-c1ccccc1C41c2ccccc2Sc2ccccc21]

[BM-2] was obtained in the same manner as in Synthesis Example 1-2, except that <B-3> was used instead of <A-2a>, and <B-4a> was used instead of <A-2b>. (Yield 74%)

MS (MALDI-TOF): m/z 833.35 [M⁺]

### Synthesis Example 3: Synthesis of [BM-3]

### Synthesis Example 3-1: Synthesis of C-1

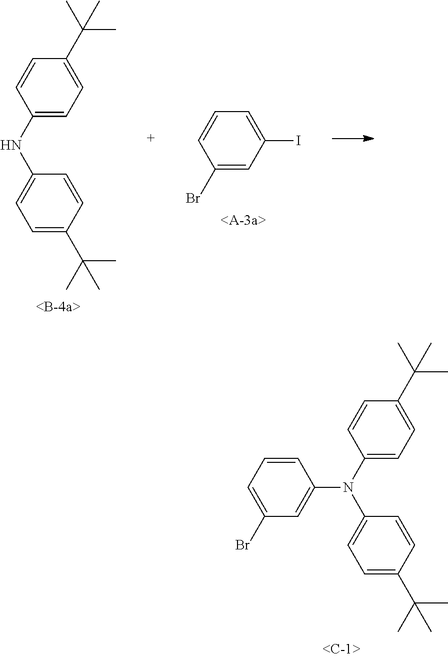 [SMILES: CC(C)(C)c1ccc(Nc2ccc(C(C)(C)C)cc2)cc1 ; Brc1cccc(I)c1 ; CC(C)(C)c1ccc(N(c2ccc(C(C)(C)C)cc2)c2cccc(Br)c2)cc1]

<C-1> was obtained in the same manner as in Synthesis Example 1-2, except that <A-3a> was used instead of <A-2a>, and <B-4a> was used instead of <A-2b>. (Yield 77%)

### Synthesis Example 3-2: Synthesis of C-2

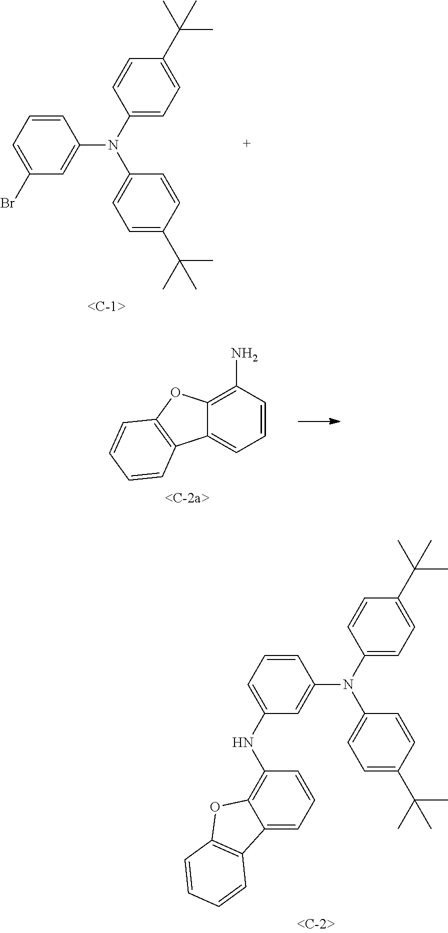 [SMILES: CC(C)(C)c1ccc(N(c2ccc(C(C)(C)C)cc2)c2cccc(Br)c2)cc1 ; Nc1cccc2c1oc1ccccc12 ; CC(C)(C)c1ccc(N(c2ccc(C(C)(C)C)cc2)c2cccc(Nc3cccc4c3oc3ccccc34)c2)cc1]

<C-2> was obtained in the same manner as in Synthesis Example 1-2, except that <C-1> was used instead of <A-2a>, and <C-2a> was used instead of <A-2b>. (Yield 70%)

### Synthesis Example 3-3: Synthesis of C-3

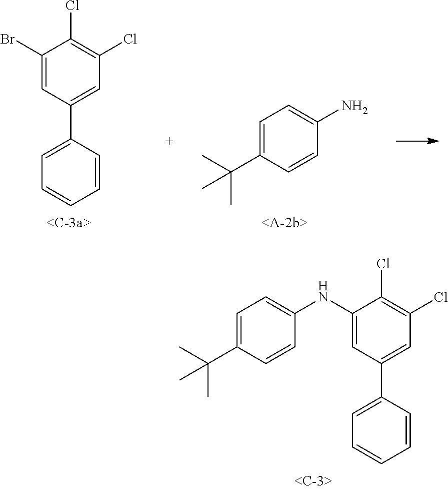 [SMILES: Clc1cc(-c2ccccc2)cc(Br)c1Cl ; CC(C)(C)c1ccc(N)cc1 ; CC(C)(C)c1ccc(Nc2cc(-c3ccccc3)cc(Cl)c2Cl)cc1]

<C-3> was obtained in the same manner as in Synthesis Example 1-2, except that <C-3a> was used instead of <A-2a>. (Yield 74%)

### Synthesis Example 3-4: Synthesis of C-4

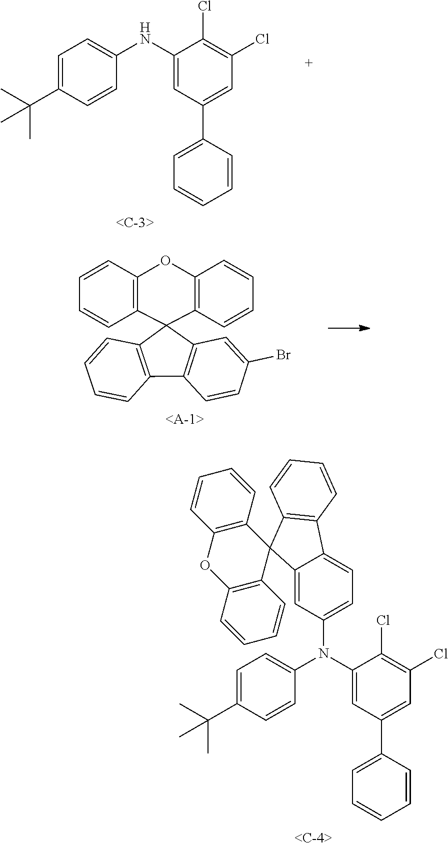 [SMILES: CC(C)(C)c1ccc(Nc2cc(-c3ccccc3)cc(Cl)c2Cl)cc1 ; Brc1ccc2c(c1)C1(c3ccccc3Oc3ccccc31)c1ccccc1-2 ; CC(C)(C)c1ccc(N(c2ccc3c(c2)C2(c4ccccc4Oc4ccccc42)c2ccccc2-3)c2cc(-c3ccccc3)cc(Cl)c2Cl)cc1]

<C-4> was obtained in the same manner as in Synthesis Example 1-6, except that <C-3> was used instead of <A-5>. (Yield 64%)

### Synthesis Example 3-5: Synthesis of C-5

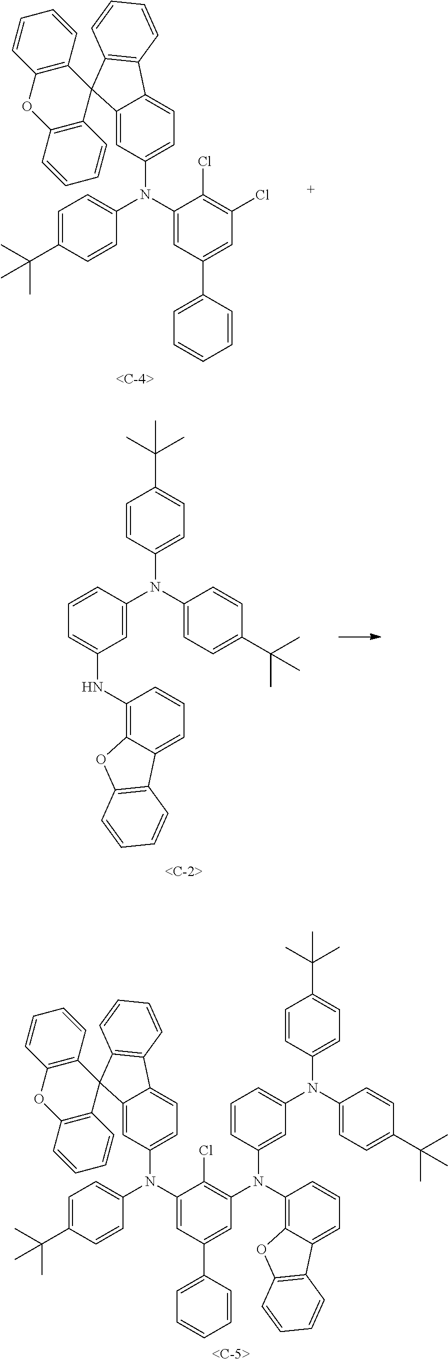 [SMILES: CC(C)(C)c1ccc(N(c2ccc3c(c2)C2(c4ccccc4Oc4ccccc42)c2ccccc2-3)c2cc(-c3ccccc3)cc(Cl)c2Cl)cc1 ; CC(C)(C)c1ccc(N(c2ccc(C(C)(C)C)cc2)c2cccc(Nc3cccc4c3oc3ccccc34)c2)cc1 ; CC(C)(C)c1ccc(N(c2ccc(C(C)(C)C)cc2)c2cccc(N(c3cc(-c4ccccc4)cc(N(c4ccc(C(C)(C)C)cc4)c4ccc5c(c4)C4(c6ccccc6Oc6ccccc64)c4ccccc4-5)c3Cl)c3cccc4c3oc3ccccc34)c2)cc1]

<C-5> was obtained in the same manner as in Synthesis Example 1-6, except that <C-4> was used instead of <A-5>, and <C-2> was used instead of <A-1>. (Yield 58.2%)

### Synthesis Example 3-6: Synthesis of [BM-3]

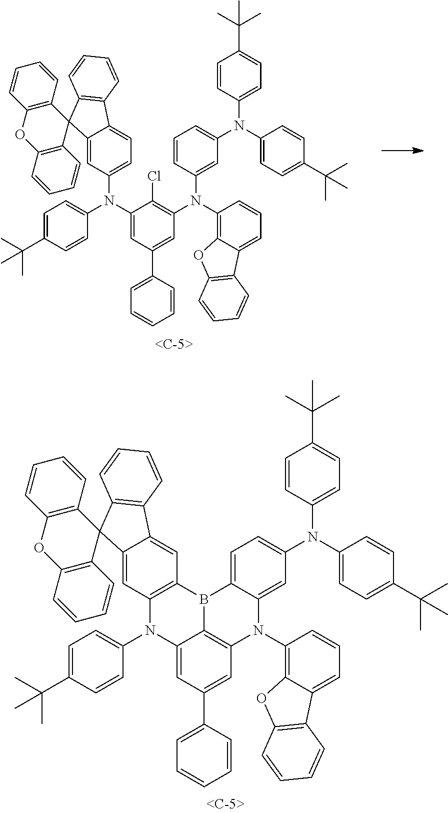

[BM-3] was obtained in the same manner as in Synthesis Example 1-8, except that <C-5> was used instead of <A-7>. (Yield 10.7%)

MS (MALDI-TOF): m/z 1175.56 [M⁺]

### Synthesis Example 4: Synthesis of [BM-4]

### Synthesis Example 4-1: Synthesis of D-1

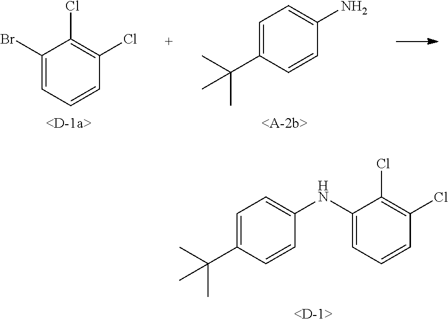 [SMILES: Clc1cccc(Br)c1Cl ; CC(C)(C)c1ccc(N)cc1 ; CC(C)(C)c1ccc(Nc2cccc(Cl)c2Cl)cc1]

<D-1> was obtained in the same manner as in Synthesis Example 1-2, except that <D-1a> was used instead of <A-2a>. (Yield 78%)

### Synthesis Example 4-2: Synthesis of D-2

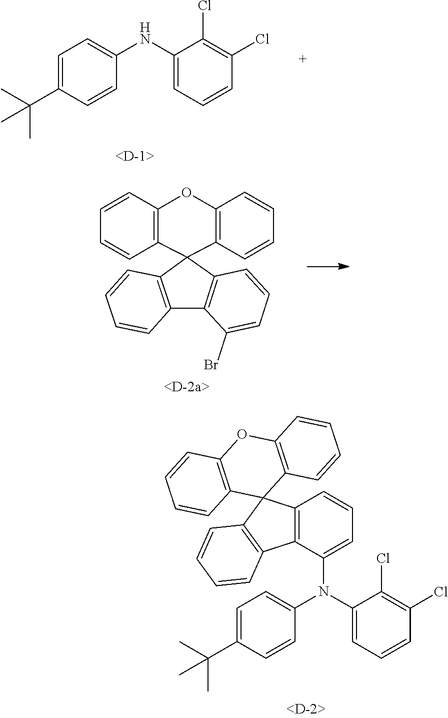 [SMILES: CC(C)(C)c1ccc(Nc2cccc(Cl)c2Cl)cc1 ; Brc1cccc2c1-c1ccccc1C21c2ccccc2Oc2ccccc21 ; CC(C)(C)c1ccc(N(c2cccc(Cl)c2Cl)c2cccc3c2-c2ccccc2C32c3ccccc3Oc3ccccc32)cc1]

<D-2> was obtained in the same manner as in Synthesis Example 1-6, except that <D-1> was used instead of <A-5>, and <D-2a> was used instead of <A-1>. (Yield 65%)

### Synthesis Example 4-3: Synthesis of D-3

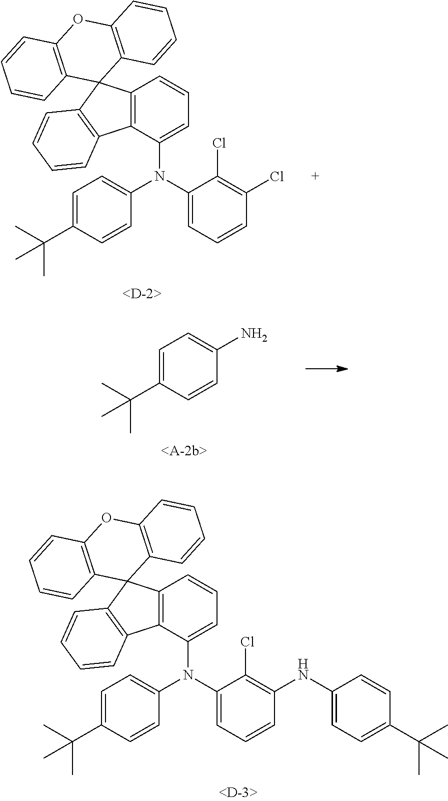 [SMILES: CC(C)(C)c1ccc(N(c2cccc(Cl)c2Cl)c2cccc3c2-c2ccccc2C32c3ccccc3Oc3ccccc32)cc1 ; CC(C)(C)c1ccc(N)cc1 ; CC(C)(C)c1ccc(Nc2cccc(N(c3ccc(C(C)(C)C)cc3)c3cccc4c3-c3ccccc3C43c4ccccc4Oc4ccccc43)c2Cl)cc1]

<D-3> was obtained in the same manner as in Synthesis Example 1-6, except that <A-2b> was used instead of <A-5>, and <D-2> was used instead of <A-1>. (Yield 64.5%)

### Synthesis Example 4-4: Synthesis of D-4

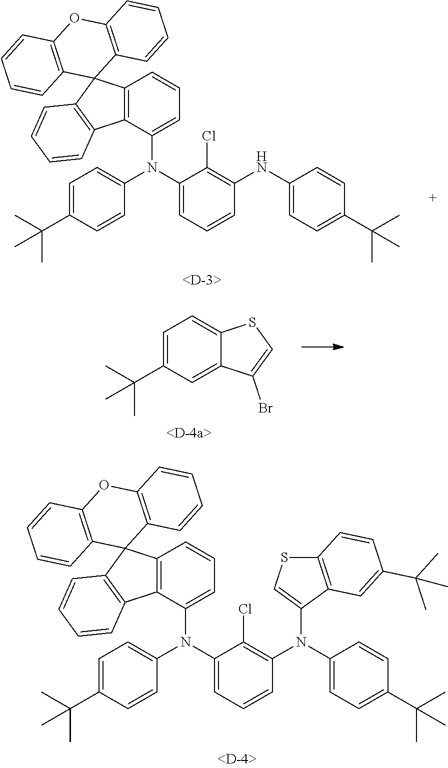

<D-4> was obtained in the same manner as in Synthesis Example 1-2, except that <D-3> was used instead of <A-2b>, and <D-4a> was used instead of <A-2a>. (Yield 77%)

### Synthesis Example 4-5: Synthesis of [BM-4]

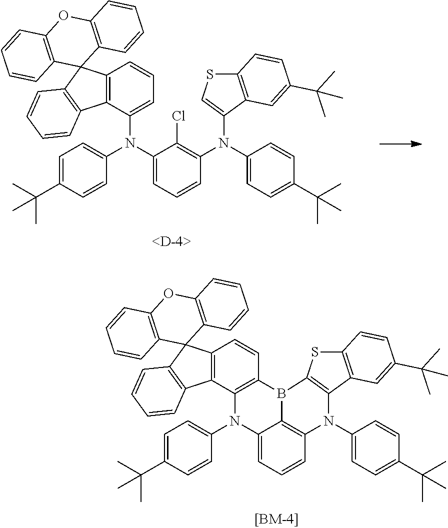 [SMILES: CC(C)(C)c1ccc(N(c2cccc(N(c3ccc(C(C)(C)C)cc3)c3csc4ccc(C(C)(C)C)cc34)c2Cl)c2cccc3c2-c2ccccc2C32c3ccccc3Oc3ccccc32)cc1 ; CC(C)(C)c1ccc(N2c3cccc4c3B(c3ccc5c(c32)-c2ccccc2C52c3ccccc3Oc3ccccc32)c2sc3ccc(C(C)(C)C)cc3c2N4c2ccc(C(C)(C)C)cc2)cc1]

[BM-4] was obtained in the same manner as in Synthesis Example 1-8, except that <D-4> was used instead of <A-7>. (Yield 11.8%)

MS (MALDI-TOF): m/z 898.41 [M⁺]

### Synthesis Example 5: Synthesis of [BM-5]

### Synthesis Example 5-1: Synthesis of E-1

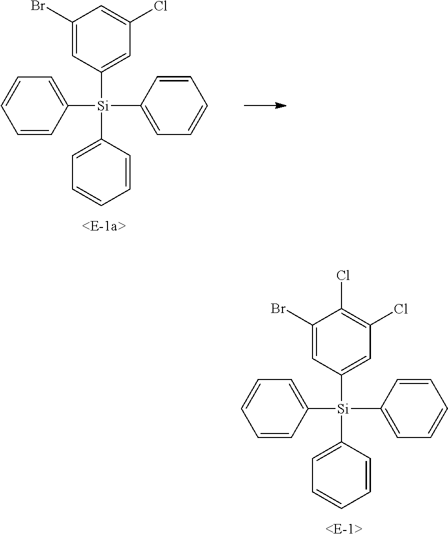 [SMILES: Clc1cc(Br)cc([Si](c2ccccc2)(c2ccccc2)c2ccccc2)c1 ; Clc1cc([Si](c2ccccc2)(c2ccccc2)c2ccccc2)cc(Br)c1Cl]

To a reactor, <E-1a> (50 g) and tetrahydrofuran (50 mL) were introduced, and then a 2 M lithium diisopropylamide solution (140 mL) was added dropwise thereto at −78° C. The mixture was stirred for 3 hours at −78° C., and, after slowly introducing hexachloroethane thereto and raising the temperature to room temperature, the mixture was stirred for 16 hours. Ethyl acetate and water were introduced thereto, and then the organic layer was separated and purified by silica gel chromatography to obtain <E-1>. (42.5 g, 78.9%)

### Synthesis Example 5-2: Synthesis of E-2

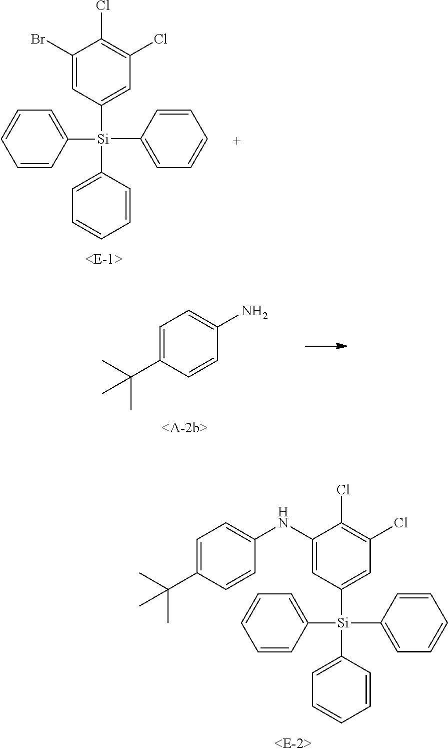 [SMILES: Clc1cc([Si](c2ccccc2)(c2ccccc2)c2ccccc2)cc(Br)c1Cl ; CC(C)(C)c1ccc(N)cc1 ; CC(C)(C)c1ccc(Nc2cc([Si](c3ccccc3)(c3ccccc3)c3ccccc3)cc(Cl)c2Cl)cc1]

<E-2> was obtained in the same manner as in Synthesis Example 1-2, except that <E-1> was used instead of <A-2a>. (Yield 75.7%)

### Synthesis Example 5-3: Synthesis of E-3

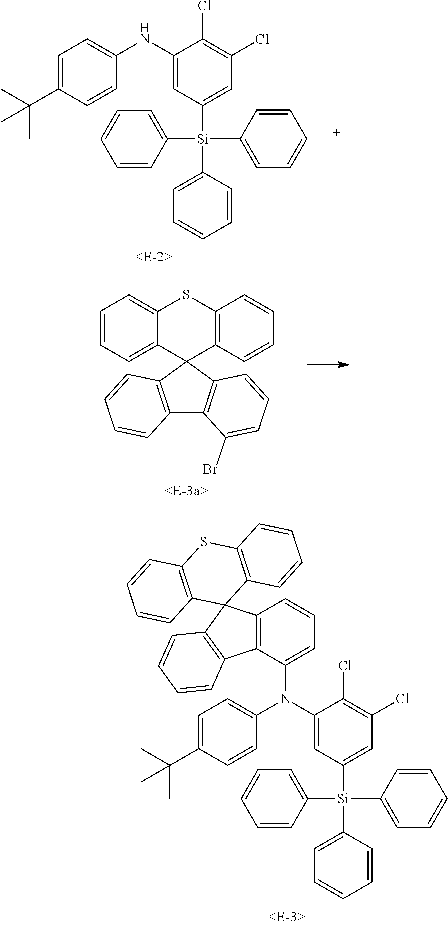 [SMILES: CC(C)(C)c1ccc(Nc2cc([Si](c3ccccc3)(c3ccccc3)c3ccccc3)cc(Cl)c2Cl)cc1 ; Brc1cccc2c1-c1ccccc1C21c2ccccc2Sc2ccccc21 ; CC(C)(C)c1ccc(N(c2cc([Si](c3ccccc3)(c3ccccc3)c3ccccc3)cc(Cl)c2Cl)c2cccc3c2-c2ccccc2C32c3ccccc3Sc3ccccc32)cc1]

<E-3> was obtained in the same manner as in Synthesis Example 1-6, except that <E-2> was used instead of <A-5>, and <E-3a> was used instead of <A-1>. (Yield 64.2%)

### Synthesis Example 5-4: Synthesis of E-4

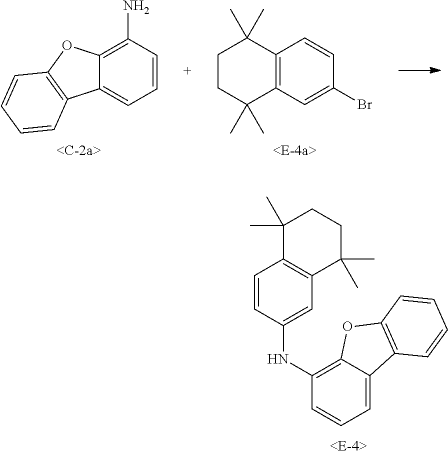 [SMILES: Nc1cccc2c1oc1ccccc12 ; CC1(C)CCC(C)(C)c2cc(Br)ccc21 ; CC1(C)CCC(C)(C)c2cc(Nc3cccc4c3oc3ccccc34)ccc21]

<E-4> was obtained in the same manner as in Synthesis Example 1-2, except that <E-4a> was used instead of <A-2a>, and <C-2a> was used instead of <A-2b>. (Yield 85.7%)

### Synthesis Example 5-5: Synthesis of E-5

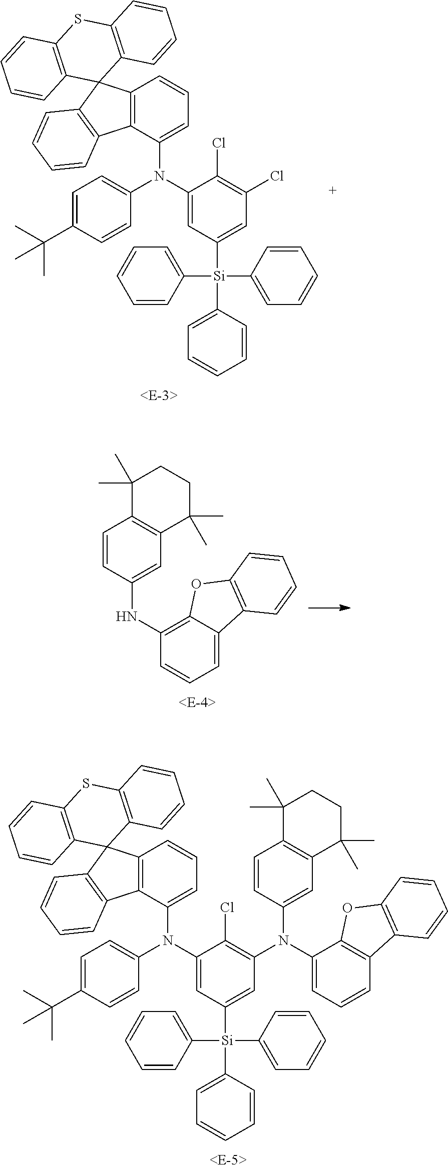 [SMILES: CC(C)(C)c1ccc(N(c2cc([Si](c3ccccc3)(c3ccccc3)c3ccccc3)cc(Cl)c2Cl)c2cccc3c2-c2ccccc2C32c3ccccc3Sc3ccccc32)cc1 ; CC1(C)CCC(C)(C)c2cc(Nc3cccc4c3oc3ccccc34)ccc21 ; CC(C)(C)c1ccc(N(c2cc([Si](c3ccccc3)(c3ccccc3)c3ccccc3)cc(N(c3ccc4c(c3)C(C)(C)CCC4(C)C)c3cccc4c3oc3ccccc34)c2Cl)c2cccc3c2-c2ccccc2C32c3ccccc3Sc3ccccc32)cc1]

<E-5> was obtained in the same manner as in Synthesis Example 1-6, except that <E-4> was used instead of <A-5>, and <E-3> was used instead of <A-1>. (Yield 61.4%)

### Synthesis Example 5-6: Synthesis of [BM-5]

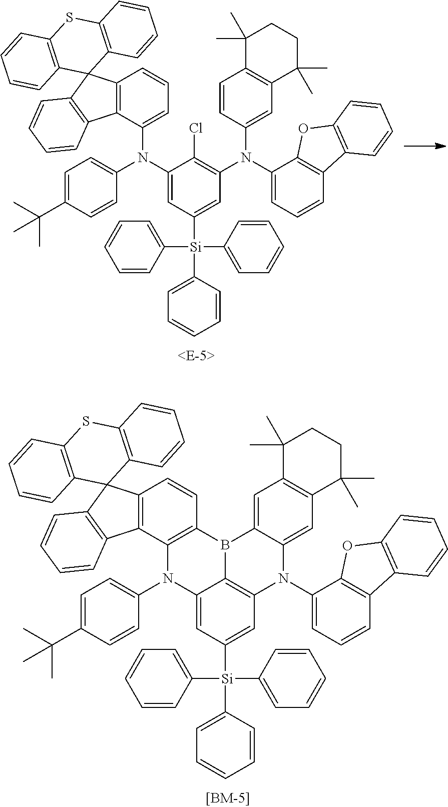 [SMILES: CC(C)(C)c1ccc(N(c2cc([Si](c3ccccc3)(c3ccccc3)c3ccccc3)cc(N(c3ccc4c(c3)C(C)(C)CCC4(C)C)c3cccc4c3oc3ccccc34)c2Cl)c2cccc3c2-c2ccccc2C32c3ccccc3Sc3ccccc32)cc1 ; CC(C)(C)c1ccc(N2c3cc([Si](c4ccccc4)(c4ccccc4)c4ccccc4)cc4c3B(c3cc5c(cc3N4c3cccc4c3oc3ccccc34)C(C)(C)CCC5(C)C)c3ccc4c(c32)-c2ccccc2C42c3ccccc3Sc3ccccc32)cc1]

[BM-5] was obtained in the same manner as in Synthesis Example 1-8, except that <E-5> was used instead of <A-7>. (Yield 10.4%)

MS (MALDI-TOF): m/z 1204.50 [M⁺]

### Synthesis Example 6: Synthesis of [BM-6]

### Synthesis Example 6-1: Synthesis of F-1

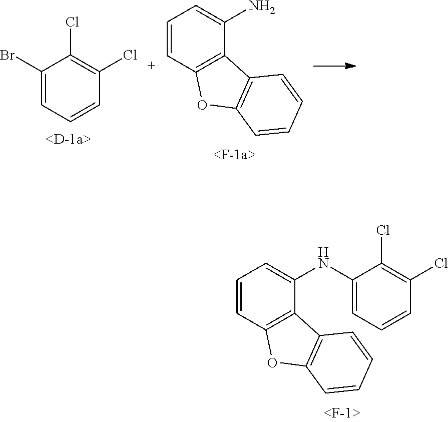

<F-1> was obtained in the same manner as in Synthesis Example 1-2, except that <D-1a> was used instead of <A-2a>, and <F-1a> was used instead of <A-2b>. (Yield 80%)

### Synthesis Example 6-2: Synthesis of F-2

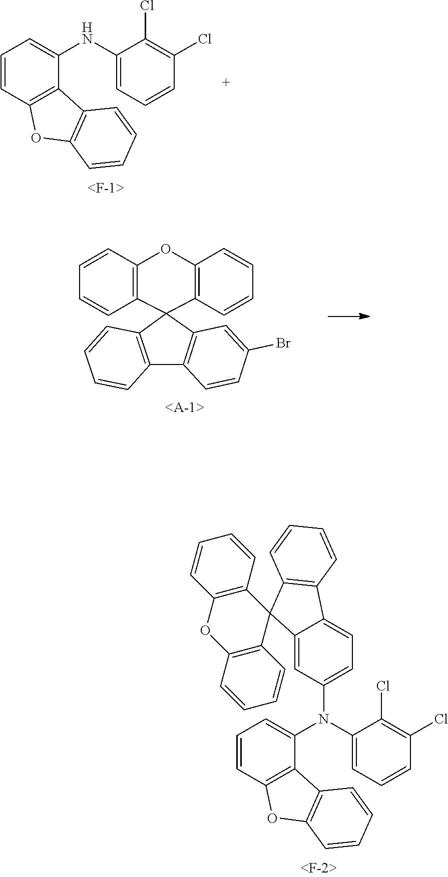 [SMILES: Clc1cccc(Nc2cccc3oc4ccccc4c23)c1Cl ; Brc1ccc2c(c1)C1(c3ccccc3Oc3ccccc31)c1ccccc1-2 ; Clc1cccc(N(c2ccc3c(c2)C2(c4ccccc4Oc4ccccc42)c2ccccc2-3)c2cccc3oc4ccccc4c23)c1Cl]

<F-2> was obtained in the same manner as in Synthesis Example 1-6, except that <F-1> was used instead of <A-5>. (Yield 67%)

### Synthesis Example 6-3: Synthesis of F-3

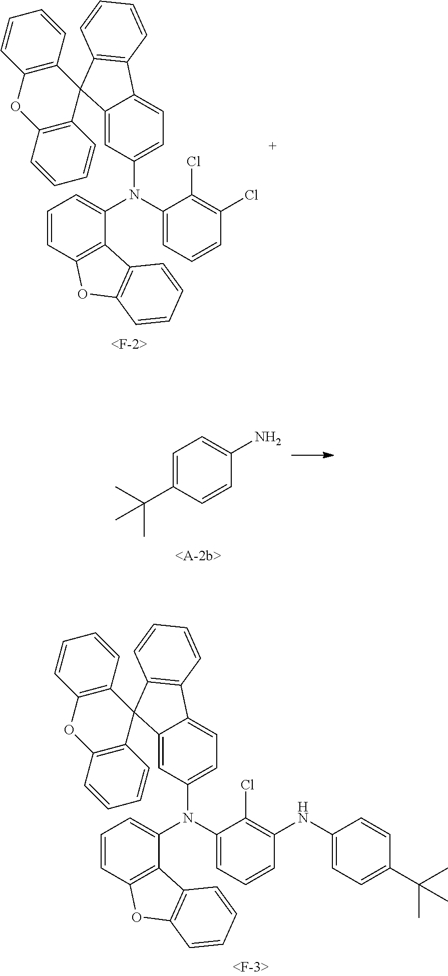 [SMILES: Clc1cccc(N(c2ccc3c(c2)C2(c4ccccc4Oc4ccccc42)c2ccccc2-3)c2cccc3oc4ccccc4c23)c1Cl ; CC(C)(C)c1ccc(N)cc1 ; CC(C)(C)c1ccc(Nc2cccc(N(c3ccc4c(c3)C3(c5ccccc5Oc5ccccc53)c3ccccc3-4)c3cccc4oc5ccccc5c34)c2Cl)cc1]

<F-3> was obtained in the same manner as in Synthesis Example 1-6, except that <A-2b> was used instead of <A-5>, and <F-2> was used instead of <A-1>. (Yield 63.7%)

### Synthesis Example 6-4: Synthesis of F-4

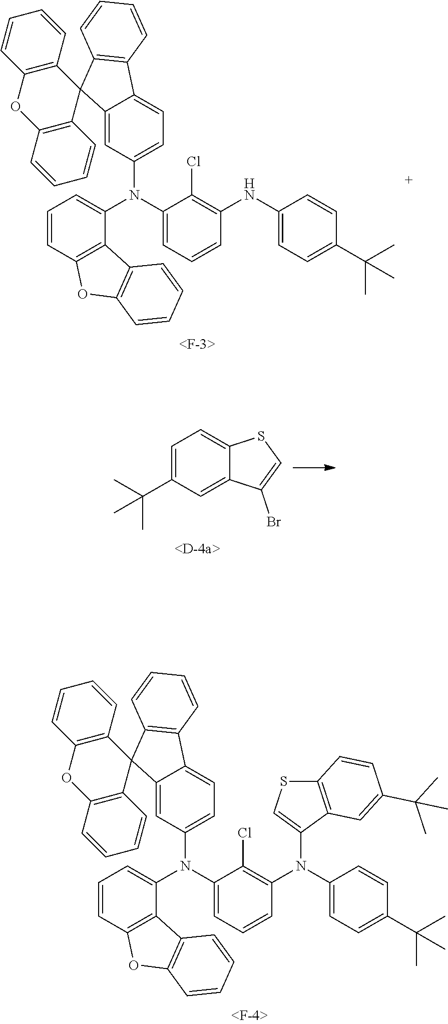

<F-4> was obtained in the same manner as in Synthesis Example 1-2, except that <F-3> was used instead of <A-2b>, and <D-4a> was used instead of <A-2a>. (Yield 74.7%)

### Synthesis Example 6-5: Synthesis of [BM-6]

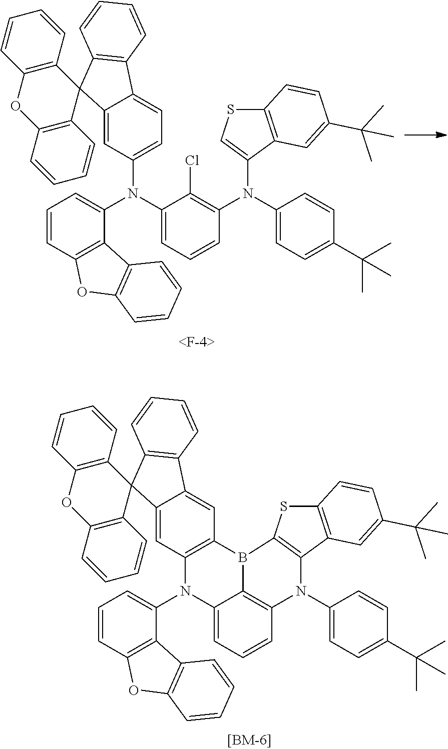 [SMILES: CC(C)(C)c1ccc(N(c2cccc(N(c3ccc4c(c3)C3(c5ccccc5Oc5ccccc53)c3ccccc3-4)c3cccc4oc5ccccc5c34)c2Cl)c2csc3ccc(C(C)(C)C)cc23)cc1 ; CC(C)(C)c1ccc(N2c3cccc4c3B(c3cc5c(cc3N4c3cccc4oc6ccccc6c34)C3(c4ccccc4Oc4ccccc43)c3ccccc3-5)c3sc4ccc(C(C)(C)C)cc4c32)cc1]

[BM-6] was obtained in the same manner as in Synthesis Example 1-8, except that <F-4> was used instead of <A-7>. (Yield 11.4%)

MS (MALDI-TOF): m/z 932.36 [M⁺]

### Synthesis Example 7: Synthesis of [BM-7]

### Synthesis Example 7-1: Synthesis of G-1

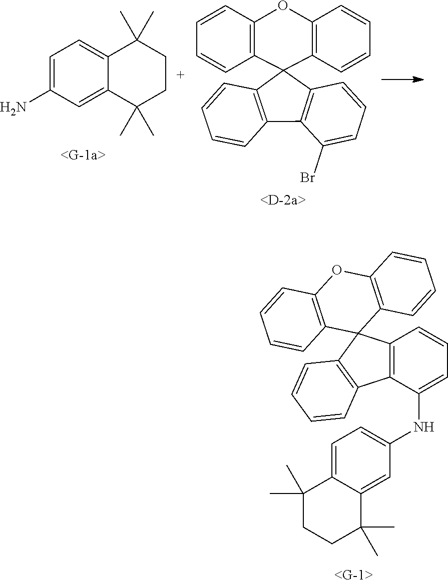

<G-1> was obtained in the same manner as in Synthesis Example 1-2, except that <D-2a> was used instead of <A-2a>, and <G-1a> was used instead of <A-2b>. (Yield 85.2%)

### Synthesis Example 7-2: Synthesis of G-2

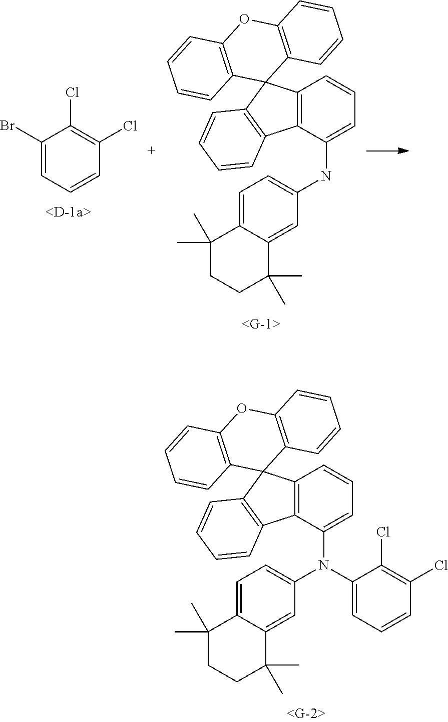 [SMILES: Clc1cccc(Br)c1Cl ; CC1(C)CCC(C)(C)c2cc(Nc3cccc4c3-c3ccccc3C43c4ccccc4Oc4ccccc43)ccc21 ; CC1(C)CCC(C)(C)c2cc(N(c3cccc(Cl)c3Cl)c3cccc4c3-c3ccccc3C43c4ccccc4Oc4ccccc43)ccc21]

<G-2> was obtained in the same manner as in Synthesis Example 1-2, except that <D-1a> was used instead of <A-2a>, and <G-1> was used instead of <A-2b>. (Yield 72.5%)

### Synthesis Example 7-3: Synthesis of G-3

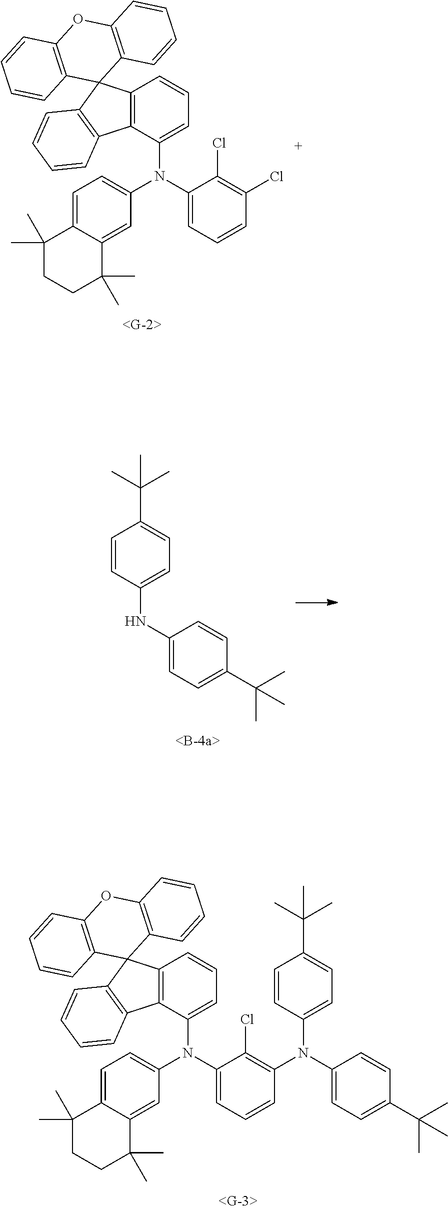 [SMILES: CC1(C)CCC(C)(C)c2cc(N(c3cccc(Cl)c3Cl)c3cccc4c3-c3ccccc3C43c4ccccc4Oc4ccccc43)ccc21 ; CC(C)(C)c1ccc(Nc2ccc(C(C)(C)C)cc2)cc1 ; CC(C)(C)c1ccc(N(c2ccc(C(C)(C)C)cc2)c2cccc(N(c3ccc4c(c3)C(C)(C)CCC4(C)C)c3cccc4c3-c3ccccc3C43c4ccccc4Oc4ccccc43)c2Cl)cc1]

<G-3> was obtained in the same manner as in Synthesis Example 1-6, except that <B-4> was used instead of <A-5>, and <G-2> was used instead of <A-1>. (Yield 63.2%)

### Synthesis Example 7-4: Synthesis of [BM-7]

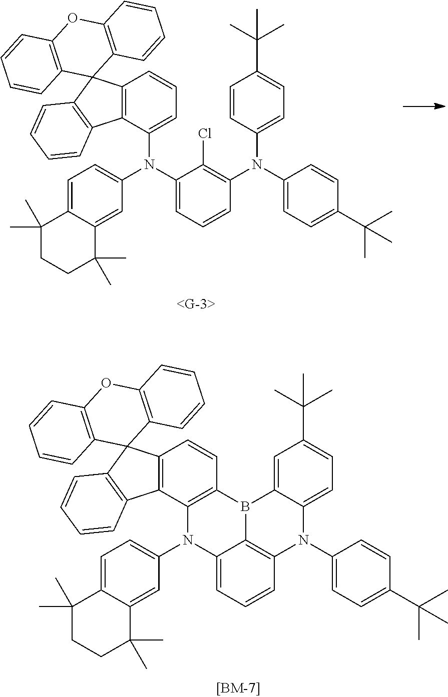 [SMILES: CC(C)(C)c1ccc(N(c2ccc(C(C)(C)C)cc2)c2cccc(N(c3ccc4c(c3)C(C)(C)CCC4(C)C)c3cccc4c3-c3ccccc3C43c4ccccc4Oc4ccccc43)c2Cl)cc1 ; CC(C)(C)c1ccc(N2c3ccc(C(C)(C)C)cc3B3c4ccc5c(c4N(c4ccc6c(c4)C(C)(C)CCC6(C)C)c4cccc2c43)-c2ccccc2C52c3ccccc3Oc3ccccc32)cc1]

[BM-7] was obtained in the same manner as in Synthesis Example 1-8, except that <G-3> was used instead of <A-7>. (Yield 12.3%)

MS (MALDI-TOF): m/z 896.49 [M⁺]

### Synthesis Example 8: Synthesis of [BM-8]

### Synthesis Example 8-1: Synthesis of H-1

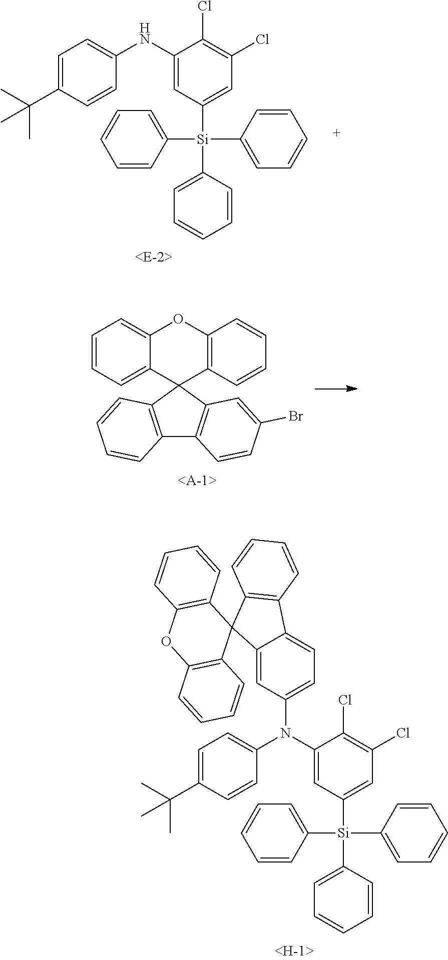 [SMILES: CC(C)(C)c1ccc(Nc2cc([Si](c3ccccc3)(c3ccccc3)c3ccccc3)cc(Cl)c2Cl)cc1 ; Brc1ccc2c(c1)C1(c3ccccc3Oc3ccccc31)c1ccccc1-2 ; CC(C)(C)c1ccc(N(c2ccc3c(c2)C2(c4ccccc4Oc4ccccc42)c2ccccc2-3)c2cc([Si](c3ccccc3)(c3ccccc3)c3ccccc3)cc(Cl)c2Cl)cc1]

<H-1> was obtained in the same manner as in Synthesis Example 1-6, except that <E-2> was used instead of <A-5>. (Yield 63%)

### Synthesis Example 8-2: Synthesis of H-2

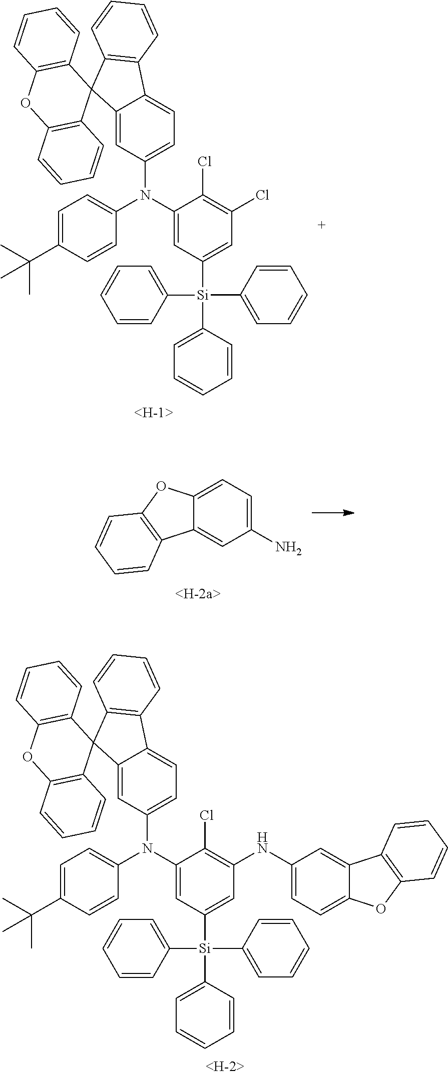 [SMILES: CC(C)(C)c1ccc(N(c2ccc3c(c2)C2(c4ccccc4Oc4ccccc42)c2ccccc2-3)c2cc([Si](c3ccccc3)(c3ccccc3)c3ccccc3)cc(Cl)c2Cl)cc1 ; Nc1ccc2oc3ccccc3c2c1 ; CC(C)(C)c1ccc(N(c2ccc3c(c2)C2(c4ccccc4Oc4ccccc42)c2ccccc2-3)c2cc([Si](c3ccccc3)(c3ccccc3)c3ccccc3)cc(Nc3ccc4oc5ccccc5c4c3)c2Cl)cc1]

<H-2> was obtained in the same manner as in Synthesis Example 1-6, except that <H-2a> was used instead of <A-5>, and <H-1> was used instead of <A-1>. (Yield 62%)

### Synthesis Example 8-3: Synthesis of H-3

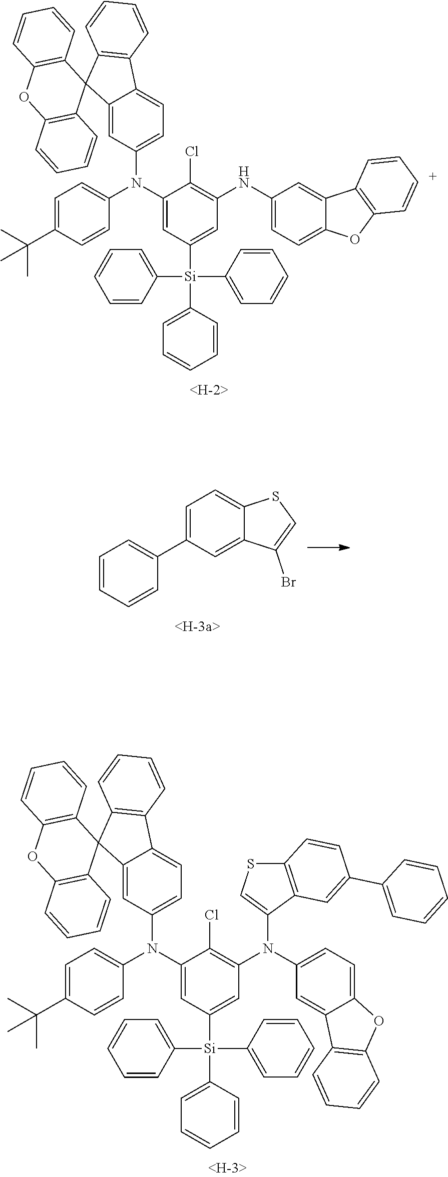 [SMILES: CC(C)(C)c1ccc(N(c2ccc3c(c2)C2(c4ccccc4Oc4ccccc42)c2ccccc2-3)c2cc([Si](c3ccccc3)(c3ccccc3)c3ccccc3)cc(Nc3ccc4oc5c(c4c3)C=C[C+]=C5)c2Cl)cc1 ; Brc1csc2ccc(-c3ccccc3)cc12 ; CC(C)(C)c1ccc(N(c2ccc3c(c2)C2(c4ccccc4Oc4ccccc42)c2ccccc2-3)c2cc([Si](c3ccccc3)(c3ccccc3)c3ccccc3)cc(N(c3ccc4oc5ccccc5c4c3)c3csc4ccc(-c5ccccc5)cc34)c2Cl)cc1]

<H-3> was obtained in the same manner as in Synthesis Example 1-2, except that <H-3a> was used instead of <A-2a>, and <H-2> was used instead of <A-2b>. (Yield 82%)

### Synthesis Example 8-4: Synthesis of [BM-8]

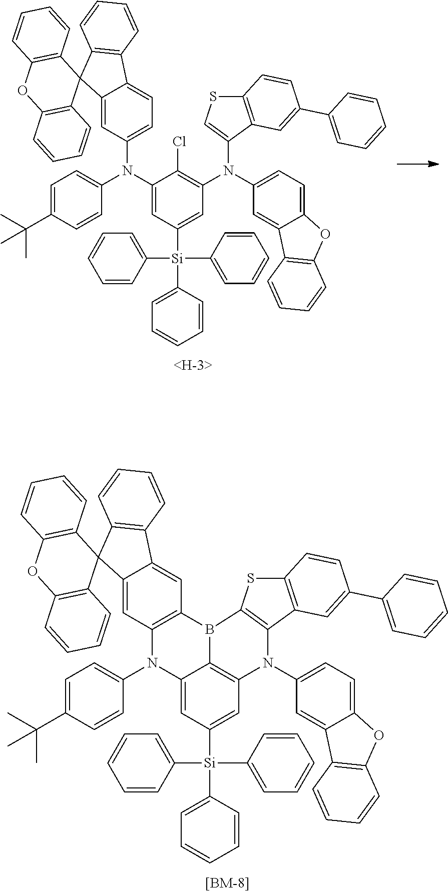 [SMILES: CC(C)(C)c1ccc(N(c2ccc3c(c2)C2(c4ccccc4Oc4ccccc42)c2ccccc2-3)c2cc([Si](c3ccccc3)(c3ccccc3)c3ccccc3)cc(N(c3ccc4oc5ccccc5c4c3)c3csc4ccc(-c5ccccc5)cc34)c2Cl)cc1 ; CC(C)(C)c1ccc(N2c3cc4c(cc3B3c5sc6ccc(-c7ccccc7)cc6c5N(c5ccc6oc7ccccc7c6c5)c5cc([Si](c6ccccc6)(c6ccccc6)c6ccccc6)cc2c53)-c2ccccc2C42c3ccccc3Oc3ccccc32)cc1]

[BM-8] was obtained in the same manner as in Synthesis Example 1-8, except that <H-3> was used instead of <A-7>. (Yield 11.5%)

MS (MALDI-TOF): m/z 1210.42 [M⁺]

### Examples 1 to 8: Manufacture of Organic Electroluminescent Device

An ITO glass was patterned to have a light emitting area of 2 mm×2 mm, and then cleaned. The ITO glass was installed in a vacuum chamber, and after setting the base pressure at 1×10⁻⁷ torr, an electron acceptor of the following structural formula [Acceptor-1] and [Formula F] were deposited (100 Å) on the ITO glass as a hole injecting layer so that the deposition ratio of [Acceptor-1]:[Formula F] was 2:98. [Formula F] was deposited (550 Å) as a hole transport layer, and subsequently, [Formula G] was deposited (50 Å) as an electron blocking layer. As a light emitting layer, a host [BH-1] described below and the compound of the present invention (2 wt %) were mixed and deposited (200 Å). After that, [Formula H] was deposited (50 Å) as a hole blocking layer, [Formula E-1] and [Formula E-2] were deposited (250 Å) in a ratio of 1:1 as an electron transport layer, [Formula E-2] was deposited (10 Å) as an electron injecting layer, and Al was deposited (1000 Å) in this order to manufacture an organic electroluminescent device. Luminous characteristics of the organic electroluminescent device were measured at 0.4 mA.

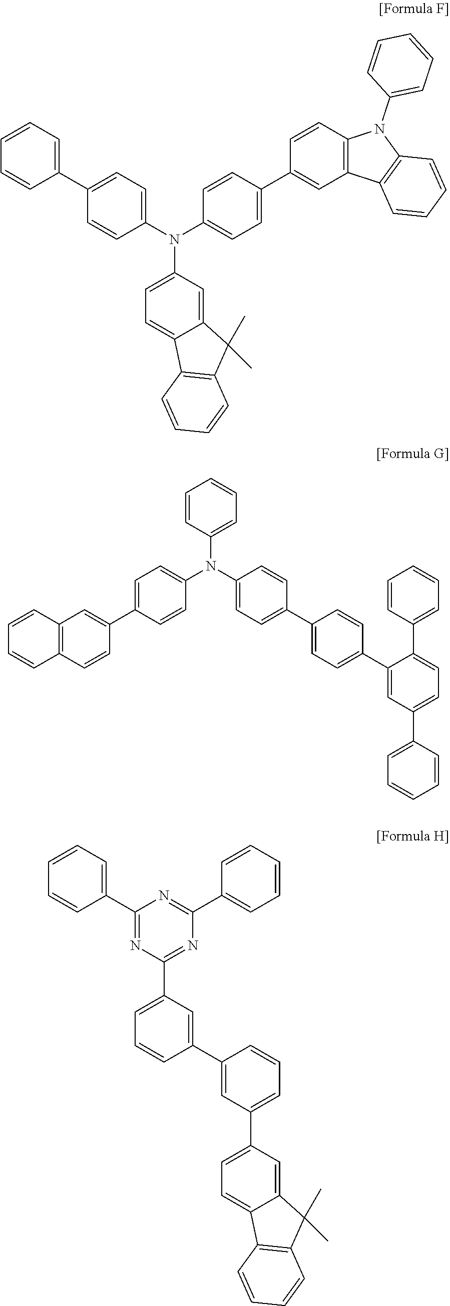

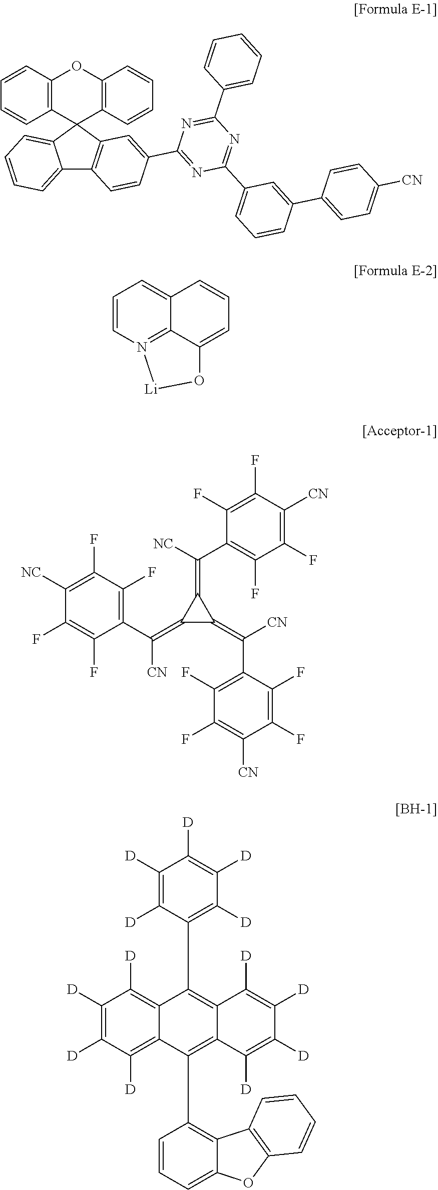

### Comparative Examples 1 and 2

Organic electroluminescent devices were manufactured in the same manner as in Examples, except that [RD-1] and [RD-2] were used instead of the compound used in Examples, and luminous characteristics of the organic electroluminescent devices were measured at 0.4 mA. The structures of [RD-1] and [RD-2] are as follows.

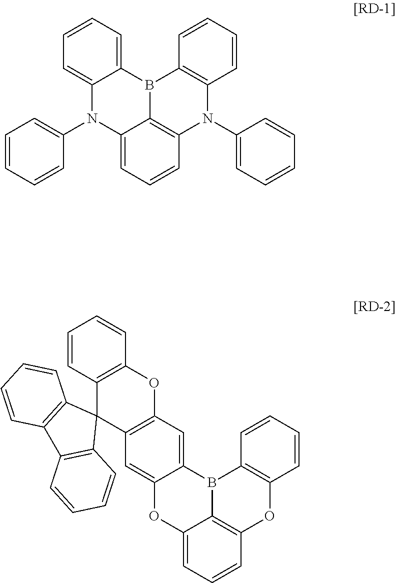 [SMILES: c1ccc(N2c3ccccc3B3c4ccccc4N(c4ccccc4)c4cccc2c43)cc1 ; c1ccc2c(c1)Oc1cccc3c1B2c1cc2c(cc1O3)C1(c3ccccc3O2)c2ccccc2-c2ccccc21]

For each of the organic electroluminescent devices manufactured according to Examples 1 to 8 and Comparative Examples 1 and 2, external quantum efficiency and lifetime were measured, and the results are shown in the following [Table 1].

TABLE 1

| | | External Quantum Efficiency | Lifetime |
|---|---|---|---|
| Category | Dopant | (EQE, %) | (T97, hr) |
| Example 1 | BM-1 | 9.0 | 135 |
| Example 2 | BM-2 | 7.8 | 95 |
| Example 3 | BM-3 | 9.5 | 155 |
| Example 4 | BM-4 | 9.1 | 150 |
| Example 5 | BM-5 | 9.4 | 165 |
| Example 6 | BM-6 | 9.2 | 138 |
| Example 7 | BM-7 | 8.8 | 125 |
| Example 8 | BM-8 | 9.6 | 118 |
| Comparative | RD-1 | 7.2 | 65 |
| Example 1 | | | |
| Comparative | RD-2 | 6.5 | 35 |
| Example 2 | | | |

As shown in [Table 1], the device employing the compound according to the present invention as a dopant compound of a light emitting layer in the organic electroluminescent device may be embodied as a high-efficiency and long-lifetime organic electroluminescent device with excellent quantum efficiency and lifetime properties compared to the devices (Comparative Examples 1 and 2) employing compounds having structures in contrast to the characteristic structures of the compound according to the present invention.

1. A polycyclic compound represented by the following [Formula 1]: 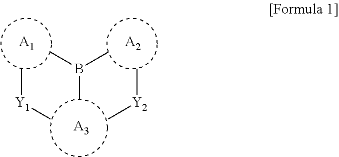
wherein, in [Formula 1],
Y₁ and Y₂ are the same as or different from each other, and each independently any one selected from O, S, NR₁, CR₂R₃, SiR₄R₅ and GeR₆R₇;
A₁ to A₃ are the same as or different from each other, and each independently any one selected from substituted or unsubstituted C₆-C₃₀ aromatic hydrocarbon rings, substituted or unsubstituted C₃-C₃₀ aliphatic hydrocarbon rings, substituted or unsubstituted C₂-C₃₀ aromatic heterocyclic rings, substituted or unsubstituted C₂-C₃₀ aliphatic heterocyclic rings, and substituted or unsubstituted cyclic groups in which a C₃-C₂₄ aliphatic ring and a C₅-C₂₄ aromatic ring are fused together;
at least one of A₁ to A₃ is fused with the following [Structural Formula 1] to form a ring; 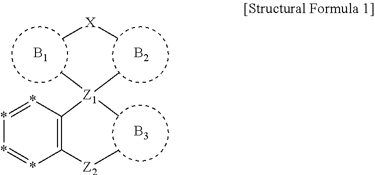
when A₁ is [Structural Formula 1], two adjacent ‘*’s are linked to B and Y₁ in [Formula 1] to form a ring;
when A₂ is [Structural Formula 1], two adjacent ‘*’s are linked to B and Y₂ in [Formula 1] to form a ring;
when A₃ is [Structural Formula 1], three adjacent ‘*’s are linked to B, Y₁ and Y₂ in [Formula 1] to form a ring;
the remaining ‘*’s not participating in the ring formation are each independently CR;
B₁ to B₃ are the same as or different from each other, and each independently any one selected from substituted or unsubstituted C₆-C₃₀ aromatic hydrocarbon rings, substituted or unsubstituted C₃-C₃₀ aliphatic hydrocarbon rings, substituted or unsubstituted C₂-C₃₀ aromatic heterocyclic rings, substituted or unsubstituted C₂-C₃₀ aliphatic heterocyclic rings, and substituted or unsubstituted cyclic groups in which a C₃-C₂₄ aliphatic ring and a C₅-C₂₄ aromatic ring are fused together;
Z₁ is C or Si;
Z₂ is a single bond, or O or S;
X is any one selected from O, S, NR₈, CR₉R₁₀, SiR₁₁R₁₂ and GeR₁₃R₁₄;
R and R₁ to R₁₄ are the same as or different from each other, and each independently any one selected from hydrogen, deuterium, substituted or unsubstituted C₁-C₃₀ alkyl, substituted or unsubstituted C₂-C₃₀ alkynyl, substituted or unsubstituted C₂-C₃₀ alkenyl, substituted or unsubstituted C₆-C₅₀ aryl, substituted or unsubstituted C₃-C₅₀ cycloalkyl, substituted or unsubstituted C₂-C₅₀ heterocycloalkyl, substituted or unsubstituted C₂-C₅₀ heteroaryl, substituted or unsubstituted cyclic groups in which a C₃-C₃₀ aliphatic ring and a C₅-C₃₀ aromatic ring are fused together, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted amine, substituted or unsubstituted silyl, substituted or unsubstituted germanium, nitro, cyano and halogen;
R₁ to R₇ are each optionally linked to the rings A₁ to A₃ to further form an alicyclic or aromatic monocyclic or polycyclic ring;
R₂ and R₃, R₄ and R₅, R₆ and R₇, R₉ and R₁₀, R₁₁ and R₁₂, and R₁₃ and R₁₄ are optionally linked to each other to further form an alicyclic or aromatic monocyclic or polycyclic ring; and
the term ‘substituted’ in the ‘substituted or unsubstituted’ in [Formula 1] and [Structural Formula 1] means being substituted with one or more substituents selected from the group consisting of deuterium, C₁-C₂₄ alkyl, C₁-C₂₄ haloalkyl, C₂-C₂₄ alkenyl, C₂-C₂₄ alkynyl, C₃-C₃₀ cycloalkyl, C₁-C₂₄ heteroalkyl, C₆-C₃₀ aryl, C₇-C₃₀ arylalkyl, C₇-C₃₀ alkylaryl, C₂-C₃₀ heteroaryl, C₂-C₃₀ heteroarylalkyl, cyclic groups in which a C₃-C₂₄ aliphatic ring and a C₅-C₂₄ aromatic ring are fused together, C₁-C₂₄ alkoxy, C₁-C₃₀ amine, C₁-C₃₀ silyl, C₁-C₃₀ germanium, C₆-C₂₄ aryloxy, C₆-C₂₄ arylthionyl, cyano, halogen, hydroxyl and nitro, and when there are two or more substituents, they are the same as or different from each other, and one or more hydrogen atoms in each of the substituents are optionally substituted with deuterium atoms.

2. The polycyclic compound according to claim 1, wherein Y₁ and Y₂ are the same as or different from each other, and each independently any one selected from NR₁, O and S.

3. The polycyclic compound according to claim 1, wherein [Formula 1] is any one represented by the following [Formula A-1] to [Formula A-6]: 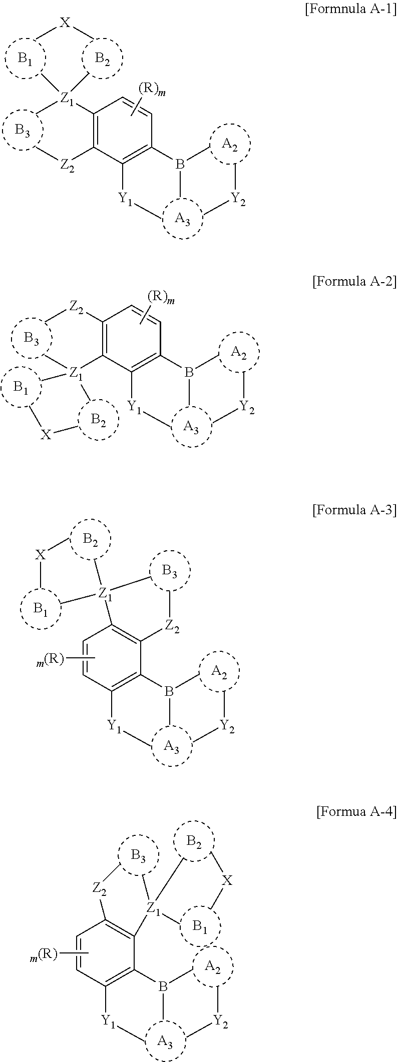 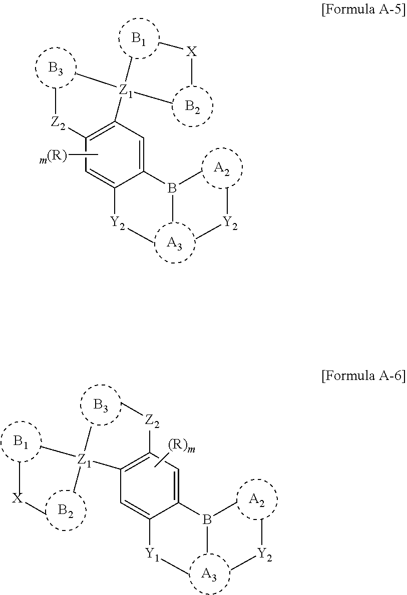
in [Formula A-1] to [Formula A-6],
Y₁ and Y₂ are the same as or different from each other, and each independently any one selected from O, S, NR₁, CR₂R₃, SiR₄R₅ and GeR₆R₇;
A₂ and A₃ are the same as or different from each other, and each independently any one selected from substituted or unsubstituted C₆-C₃₀ aromatic hydrocarbon rings, substituted or unsubstituted C₃-C₃₀ aliphatic hydrocarbon rings, substituted or unsubstituted C₂-C₃₀ aromatic heterocyclic rings, substituted or unsubstituted C₂-C₃₀ aliphatic heterocyclic rings, and substituted or unsubstituted cyclic groups in which a C₃-C₂₄ aliphatic ring and a C₅-C₂₄ aromatic ring are fused together;
B₁ to B₃ are the same as or different from each other, and each independently any one selected from substituted or unsubstituted C₆-C₃₀ aromatic hydrocarbon rings, substituted or unsubstituted C₃-C₃₀ aliphatic hydrocarbon rings, substituted or unsubstituted C₂-C₃₀ aromatic heterocyclic rings, substituted or unsubstituted C₂-C₃₀ aliphatic heterocyclic rings, and substituted or unsubstituted cyclic groups in which a C₃-C₂₄ aliphatic ring and a C₅-C₂₄ aromatic ring are fused together;
Z₁ is C or Si;
Z₂ is a single bond, or O or S;
X is any one selected from O, S, NR₈, CR₉R₁₀, SiR₁₁R₁₂ and GeR₁₃R₁₄;
R and R₁ to R₁₄ are the same as or different from each other, and each independently any one selected from hydrogen, deuterium, substituted or unsubstituted C₁-C₃₀ alkyl, substituted or unsubstituted C₂-C₃₀ alkynyl, substituted or unsubstituted C₂-C₃₀ alkenyl, substituted or unsubstituted C₆-C₅₀ aryl, substituted or unsubstituted C₃-C₅₀ cycloalkyl, substituted or unsubstituted C₂-C₅₀ heterocycloalkyl, substituted or unsubstituted C₂-C₅₀ heteroaryl, substituted or unsubstituted cyclic groups in which a C₃-C₃₀ aliphatic ring and a C₅-C₃₀ aromatic ring are fused together, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted amine, substituted or unsubstituted silyl, substituted or unsubstituted germanium, nitro, cyano and halogen;
m is an integer of 2, and Rs are the same as or different from each other;
R₁ to R₇ are each optionally linked to the rings A₂ and A₃ to further form an alicyclic or aromatic monocyclic or polycyclic ring;
R₂ and R₃, R₄ and R₅, R₆ and R₇, R₉ and R₁₀, R₁₁ and R₁₂, and R₁₃ and R₁₄ are optionally linked to each other to further form an alicyclic or aromatic monocyclic or polycyclic ring; and
the term ‘substituted’ in the ‘substituted or unsubstituted’ in [Formula A-1] to [Formula A-6] has the same definition as in [Formula 1] in claim 1.

4. The polycyclic compound according to claim 1, wherein [Formula 1] is any one represented by the following [Formula B-1] to [Formula B-12]: 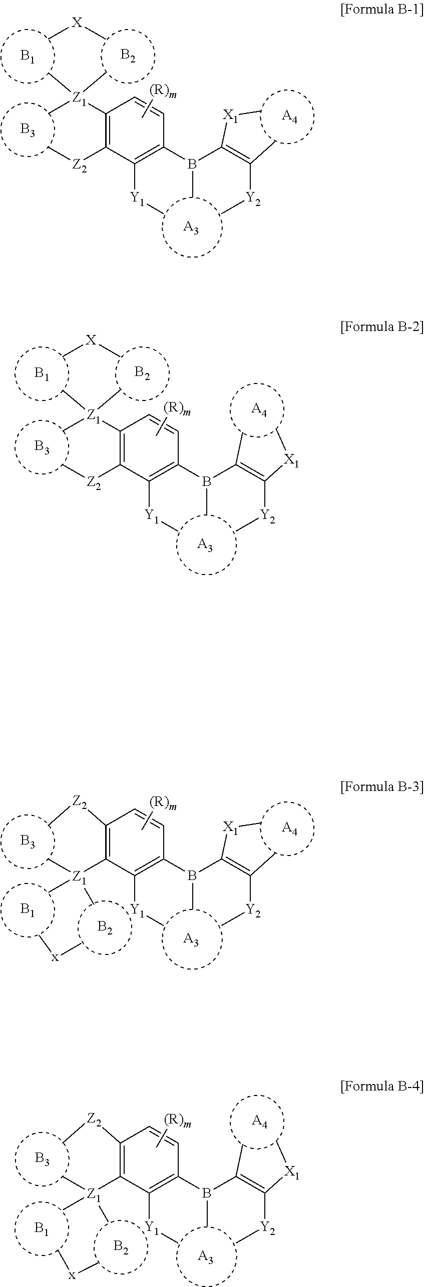 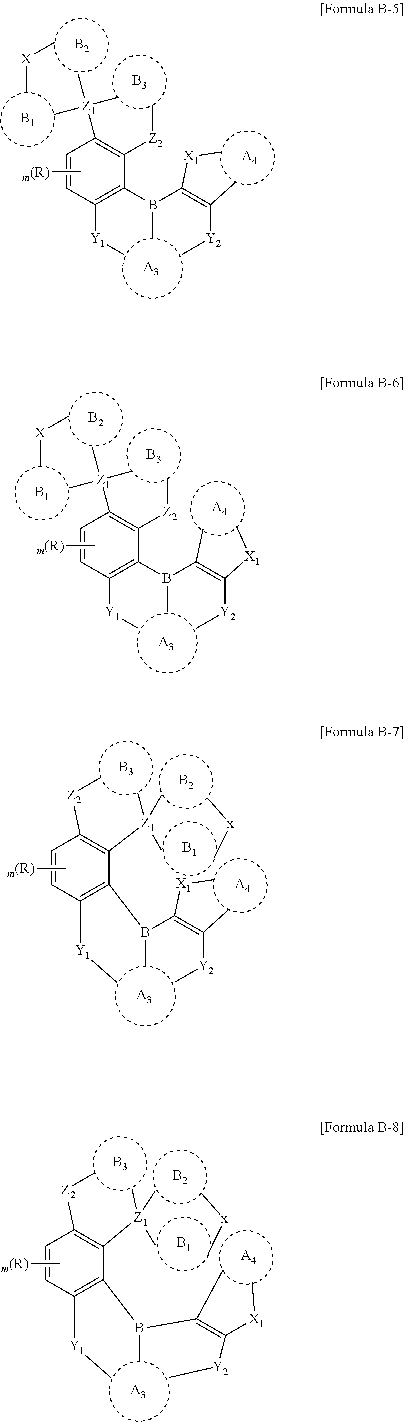 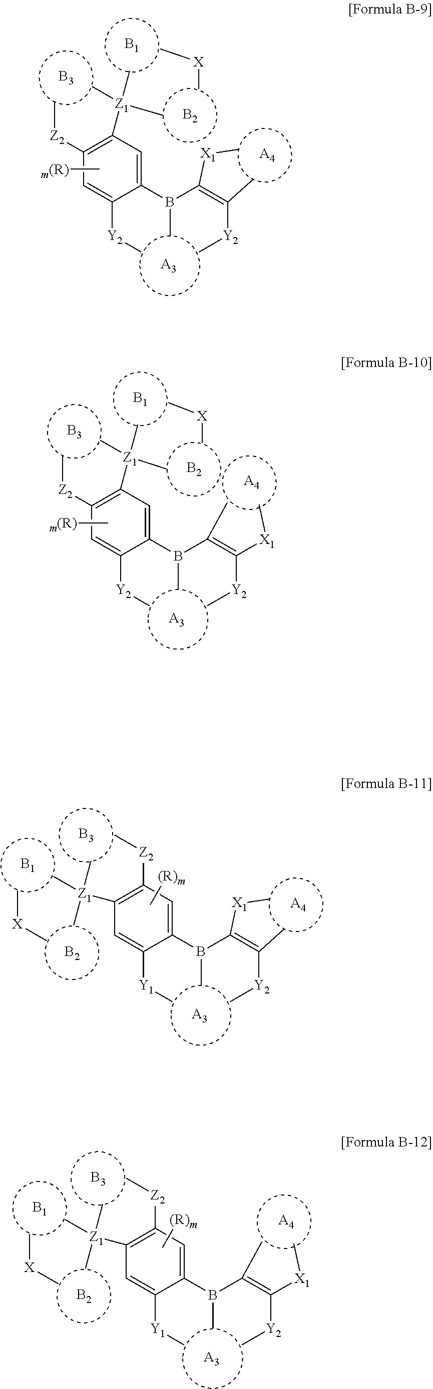
in [Formula B-1] to [Formula B-12],
Y₁ and Y₂ are the same as or different from each other, and each independently any one selected from O, S, NR₁, CR₂R₃, SiR₄R₅ and GeR₆R₇;
X₁ is O or S;
A₃ and A₄ are the same as or different from each other, and each independently any one selected from substituted or unsubstituted C₆-C₃₀ aromatic hydrocarbon rings, substituted or unsubstituted C₃-C₃₀ aliphatic hydrocarbon rings, substituted or unsubstituted C₂-C₃₀ aromatic heterocyclic rings, substituted or unsubstituted C₂-C₃₀ aliphatic heterocyclic rings, and substituted or unsubstituted cyclic groups in which a C₃-C₂₄ aliphatic ring and a C₅-C₂₄ aromatic ring are fused together,
B₁ to B₃ are the same as or different from each other, and each independently any one selected from substituted or unsubstituted C₆-C₃₀ aromatic hydrocarbon rings, substituted or unsubstituted C₃-C₃₀ aliphatic hydrocarbon rings, substituted or unsubstituted C₂-C₃₀ aromatic heterocyclic rings, substituted or unsubstituted C₂-C₃₀ aliphatic heterocyclic rings, and substituted or unsubstituted cyclic groups in which a C₃-C₂₄ aliphatic ring and a C₅-C₂₄ aromatic ring are fused together;
Z₁ is C or Si;
Z₂ is a single bond, or O or S;
X is any one selected from O, S, NR₈, CR₉R₁₀, SiR₁₁R₁₂ and GeR₁₃R₁₄;
R and R₁ to R₁₄ are the same as or different from each other, and each independently any one selected from hydrogen, deuterium, substituted or unsubstituted C₁-C₃₀ alkyl, substituted or unsubstituted C₂-C₃₀ alkynyl, substituted or unsubstituted C₂-C₃₀ alkenyl, substituted or unsubstituted C₆-C₅₀ aryl, substituted or unsubstituted C₃-C₅₀ cycloalkyl, substituted or unsubstituted C₂-C₅₀ heterocycloalkyl, substituted or unsubstituted C₂-C₅₀ heteroaryl, substituted or unsubstituted cyclic groups in which a C₃-C₃₀ aliphatic ring and a C₅-C₃₀ aromatic ring are fused together, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted amine, substituted or unsubstituted silyl, substituted or unsubstituted germanium, nitro, cyano and halogen;
m is an integer of 2, and Rs are the same as or different from each other;
R₁ to R₇ are each optionally linked to the rings A₃ and A₄ to further form an alicyclic or aromatic monocyclic or polycyclic ring;
R₂ and R₃, R₄ and R₅, R₆ and R₇, R₉ and R₁₀, R₁₁ and R₁₂, and R₁₃ and R₁₄ are optionally linked to each other to further form an alicyclic or aromatic monocyclic or polycyclic ring; and
the term ‘substituted’ in the ‘substituted or unsubstituted’ in [Formula B-1] to [Formula B-12] has the same definition as in [Formula 1] in claim 1.

5. The polycyclic compound according to claim 3, wherein A₂ and A₃ except A₁ are the same as or different from each other, and each independently any one selected from substituted or unsubstituted C₆-C₂₀ aromatic hydrocarbon rings, substituted or unsubstituted C₂-C₂₀ aromatic heterocyclic rings, and substituted or unsubstituted cyclic groups in which a C₃-C₁₄ aliphatic ring and a C₅-C₁₄ aromatic ring are fused together.

6. The polycyclic compound according to claim 1, wherein X in [Structural Formula 1] is any one selected from NR₈, O and S.

7. The polycyclic compound according to claim 1, wherein Z₁ is C, and at the same time, Z₂ is a single bond.

8. The polycyclic compound according to claim 1, wherein R of the remaining ‘*’s not participating in the ring formation in [Structural Formula 1] is hydrogen or deuterium.

9. The polycyclic compound according to claim 1, wherein B₁ to B₃ in [Structural Formula 1] are the same as or different from each other, and each independently any one selected from substituted or unsubstituted C₆-C₂₀ aromatic hydrocarbon rings, substituted or unsubstituted C₂-C₂₀ aromatic heterocyclic rings, and substituted or unsubstituted cyclic groups in which a C₃-C₁₄ aliphatic ring and a C₅-C₁₄ aromatic ring are fused together.

10. The polycyclic compound according to claim 1, wherein [Formula 1] is any one selected from compounds represented by the following formulae:

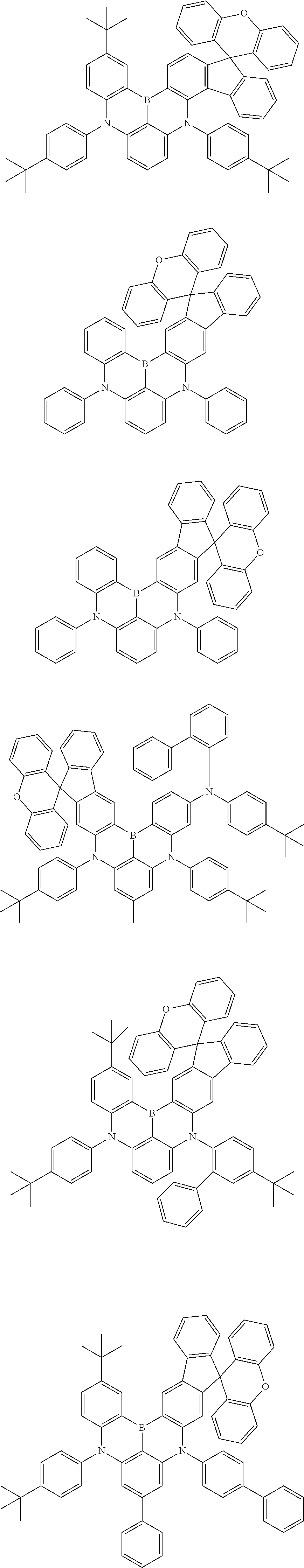

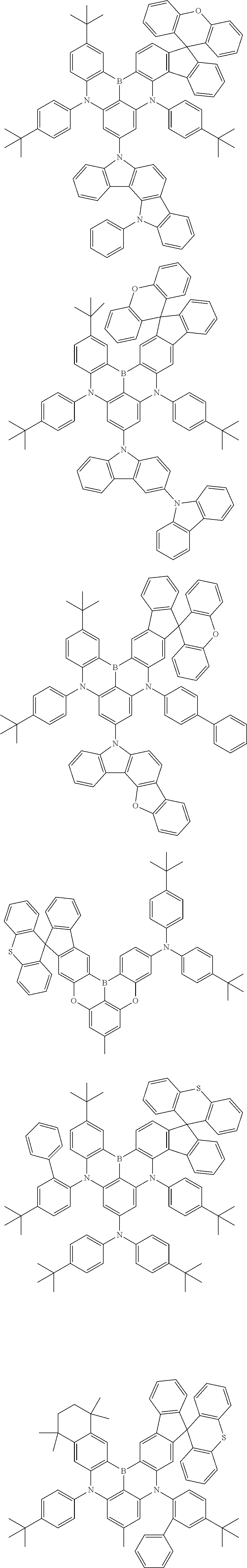

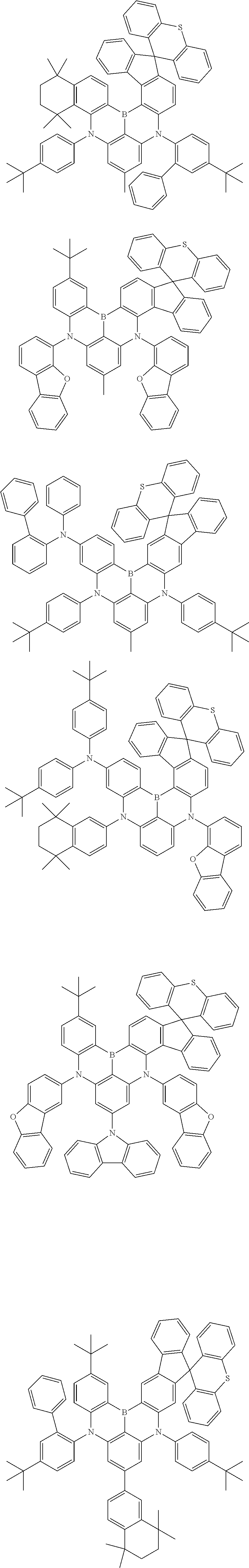

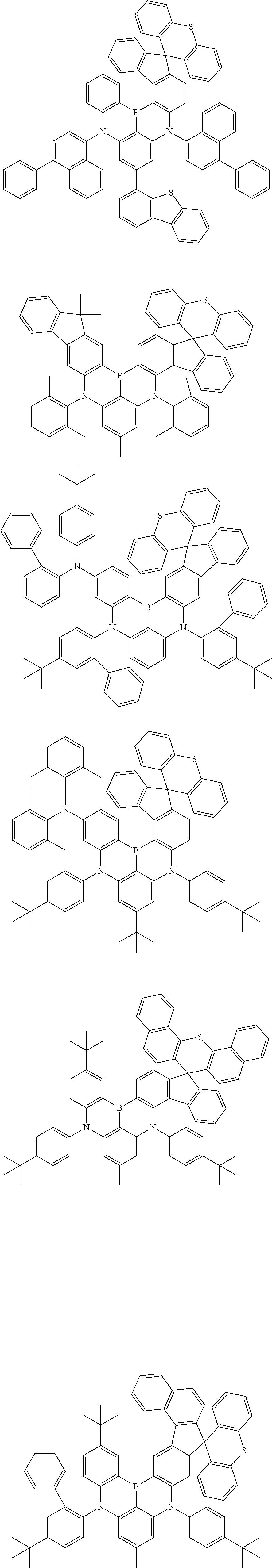

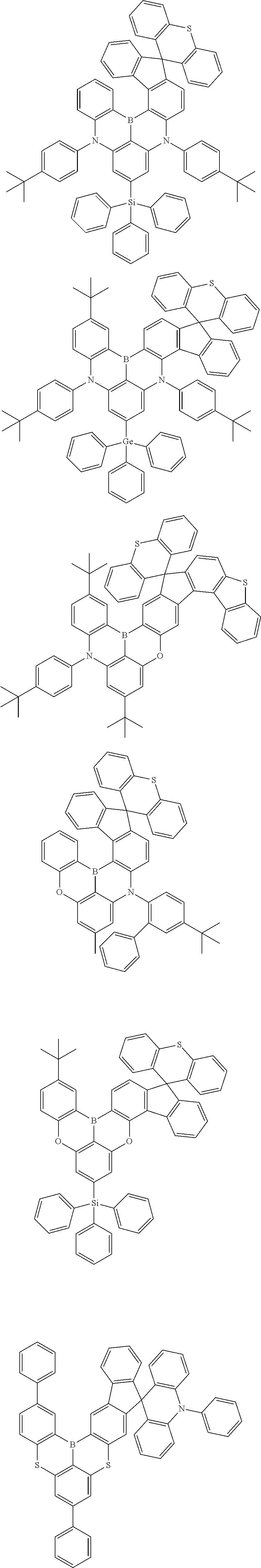

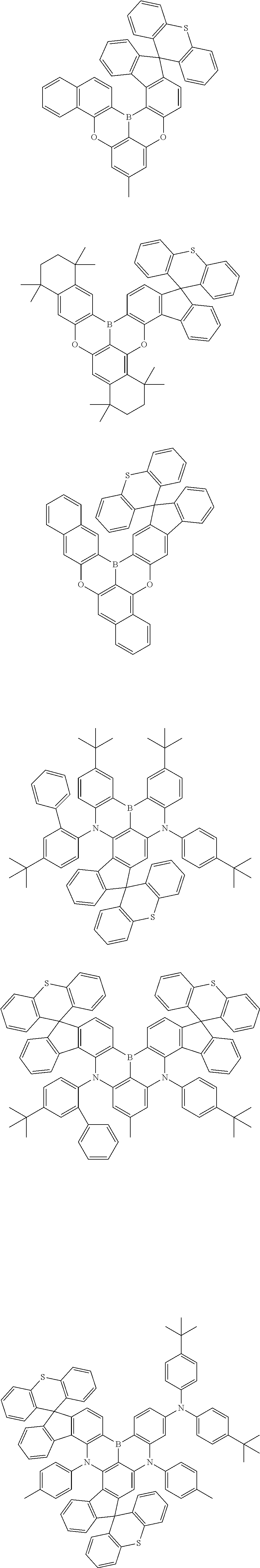

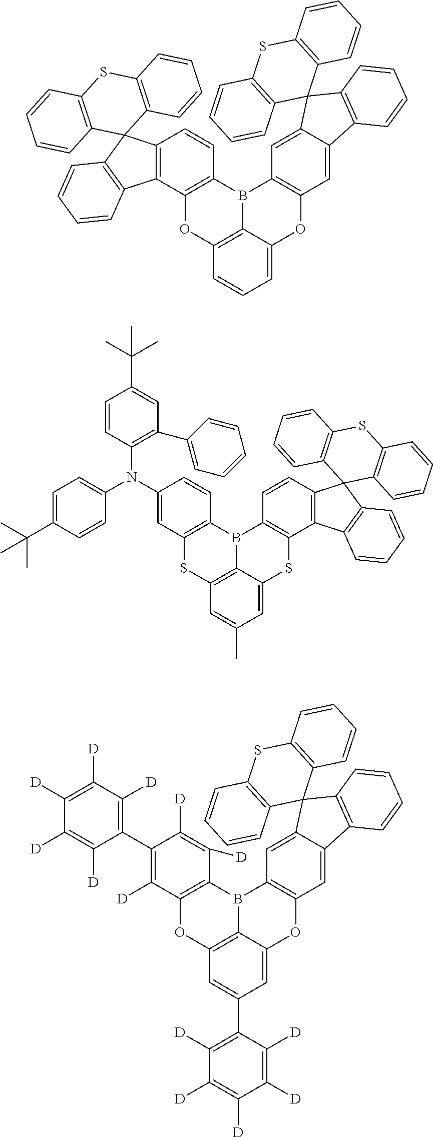 [SMILES: c1cc2c3c(c1)Oc1c(ccc4c1-c1ccccc1C41c4ccccc4Sc4ccccc41)B3c1cc3c(cc1O2)-c1ccccc1C31c2ccccc2Sc2ccccc21 ; Cc1cc2c3c(c1)Sc1c(ccc4c1-c1ccccc1C41c4ccccc4Sc4ccccc41)B3c1ccc(N(c3ccc(C(C)(C)C)cc3)c3ccc(C(C)(C)C)cc3-c3ccccc3)cc1S2 ; [2H]c1c([2H])c([2H])c(-c2cc3c4c(c2)Oc2c([2H])c(-c5c([2H])c([2H])c([2H])c([2H])c5[2H])c([2H])c([2H])c2B4c2cc4c(cc2O3)-c2ccccc2C42c3ccccc3Sc3ccccc32)c([2H])c1[2H]]

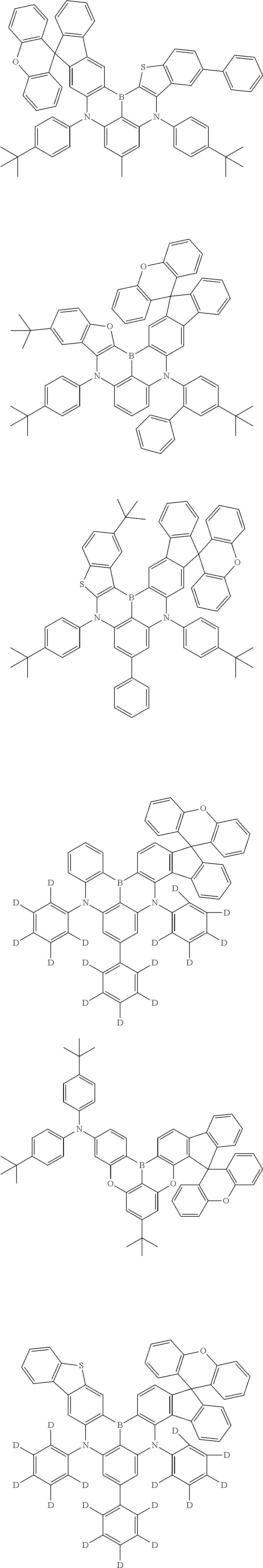

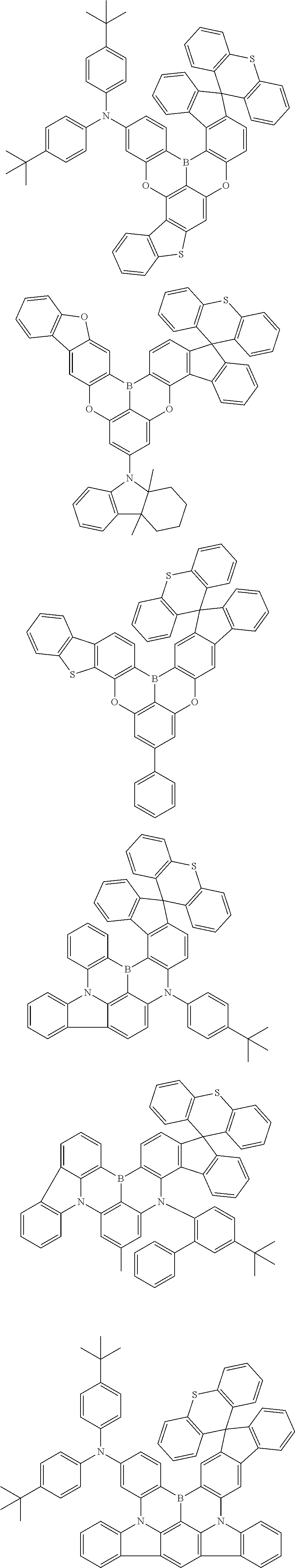

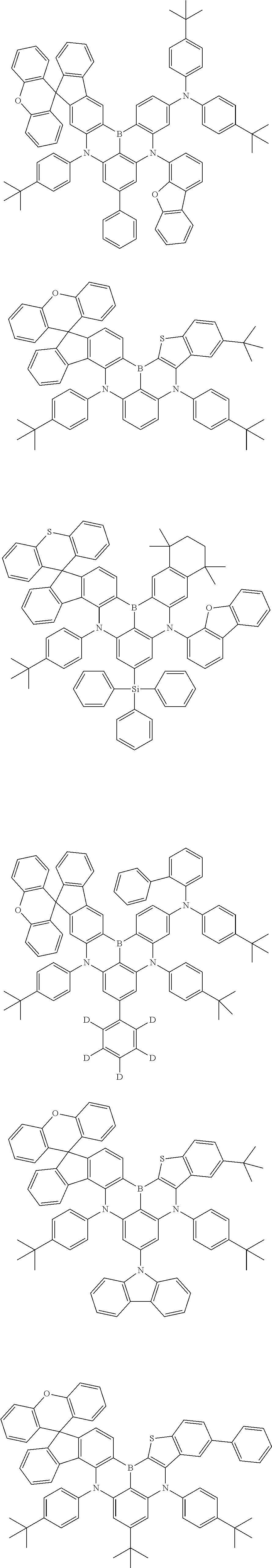

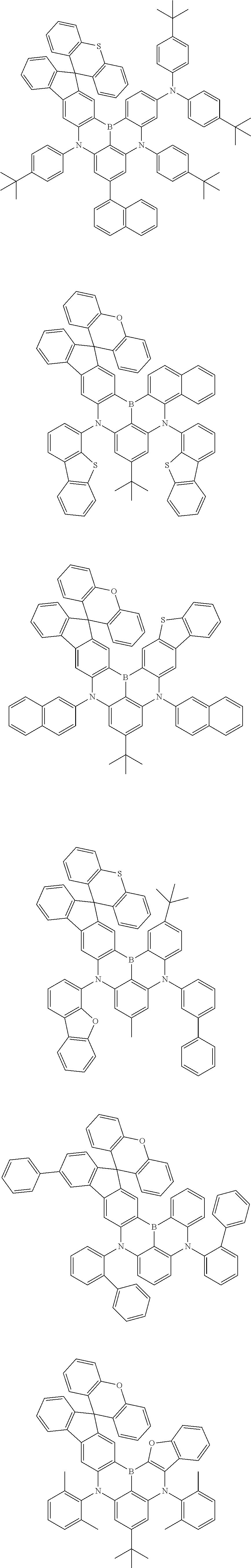

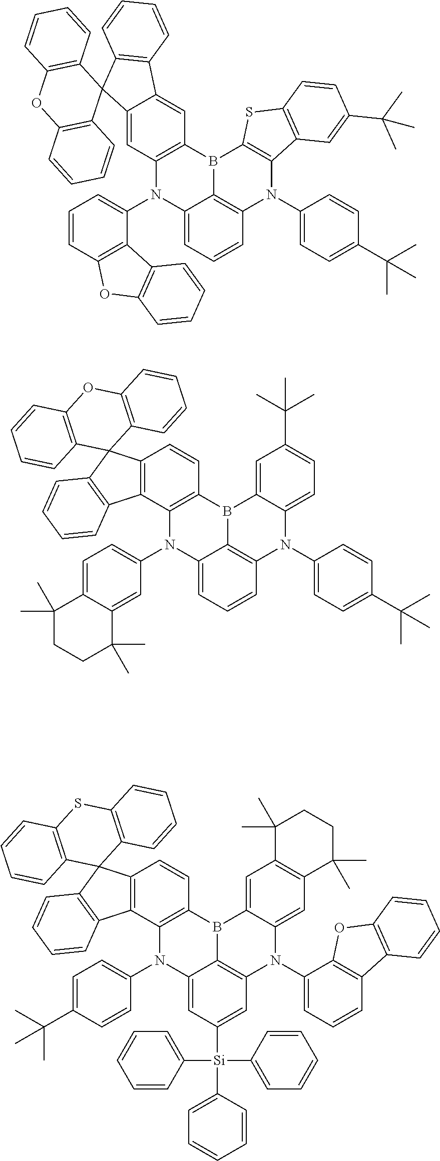 [SMILES: CC(C)(C)c1ccc(N2c3cccc4c3B(c3cc5c(cc3N4c3cccc4oc6ccccc6c34)C3(c4ccccc4Oc4ccccc43)c3ccccc3-5)c3sc4ccc(C(C)(C)C)cc4c32)cc1 ; CC(C)(C)c1ccc(N2c3ccc(C(C)(C)C)cc3B3c4ccc5c(c4N(c4ccc6c(c4)C(C)(C)CCC6(C)C)c4cccc2c43)-c2ccccc2C52c3ccccc3Oc3ccccc32)cc1 ; CC(C)(C)c1ccc(N2c3cc([Si](c4ccccc4)(c4ccccc4)c4ccccc4)cc4c3B(c3cc5c(cc3N4c3cccc4c3oc3ccccc34)C(C)(C)CCC5(C)C)c3ccc4c(c32)-c2ccccc2C42c3ccccc3Sc3ccccc32)cc1]

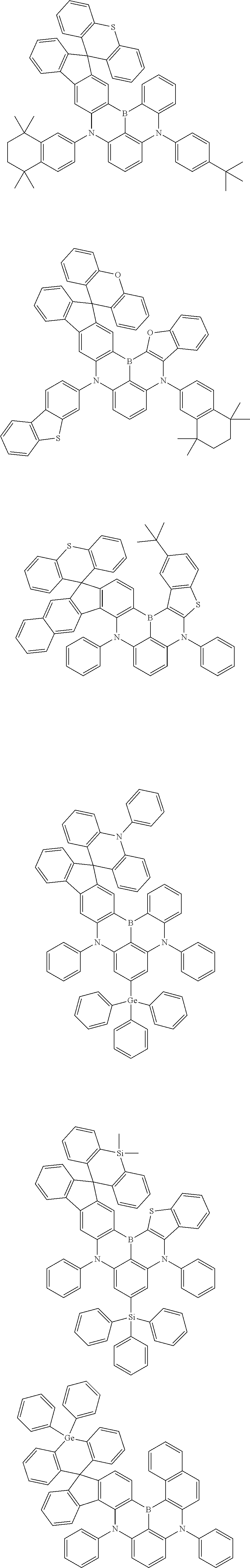

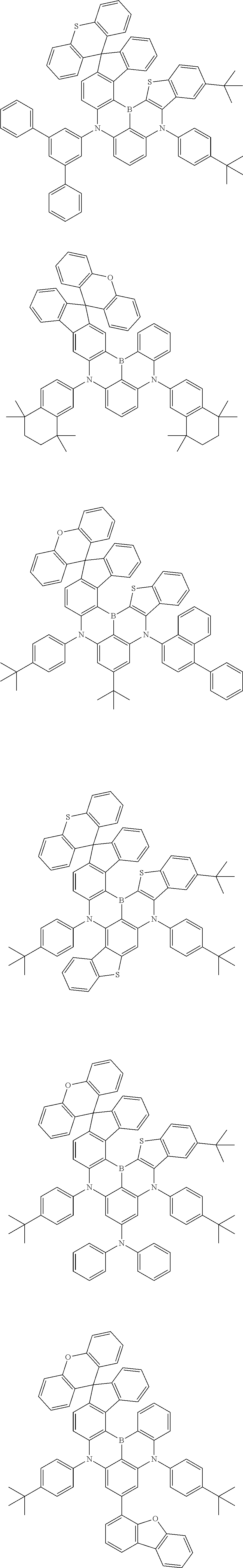

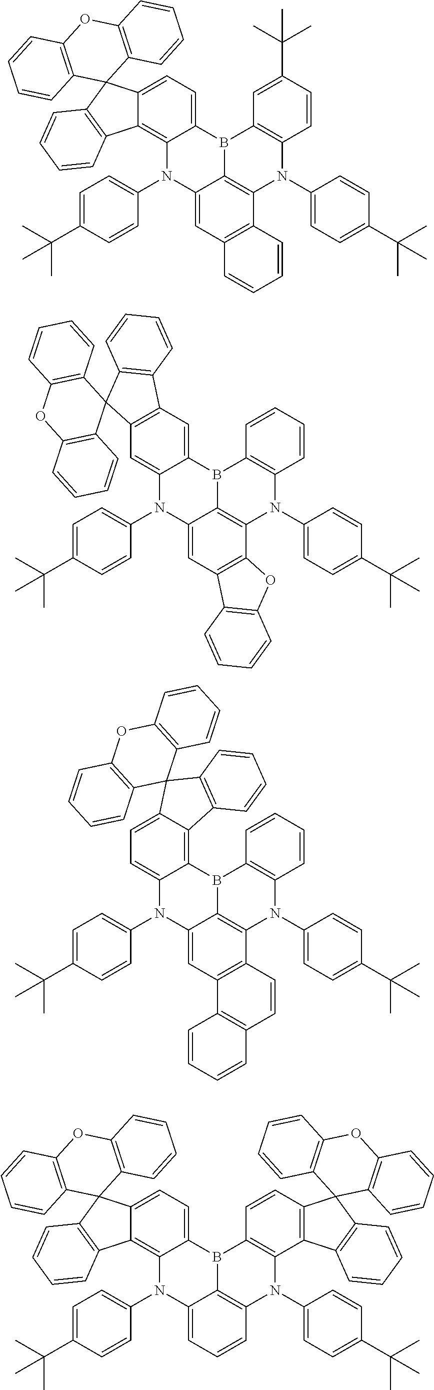

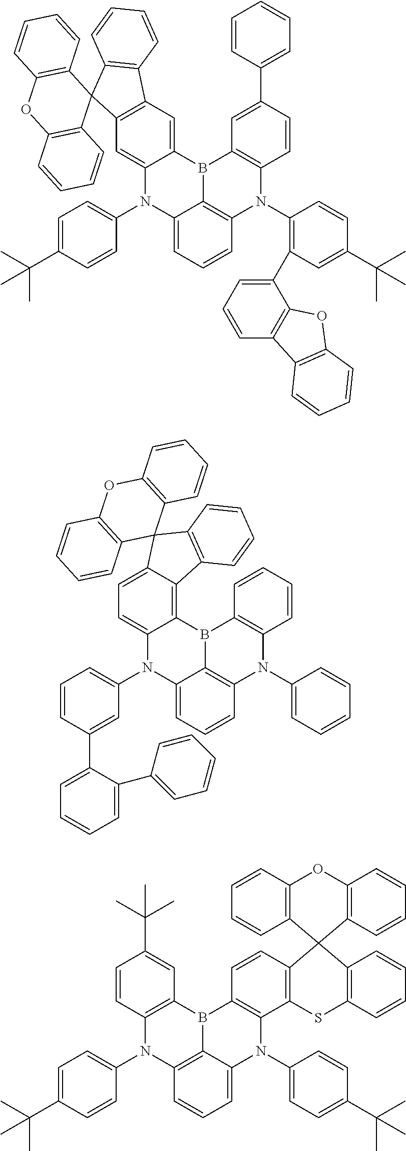

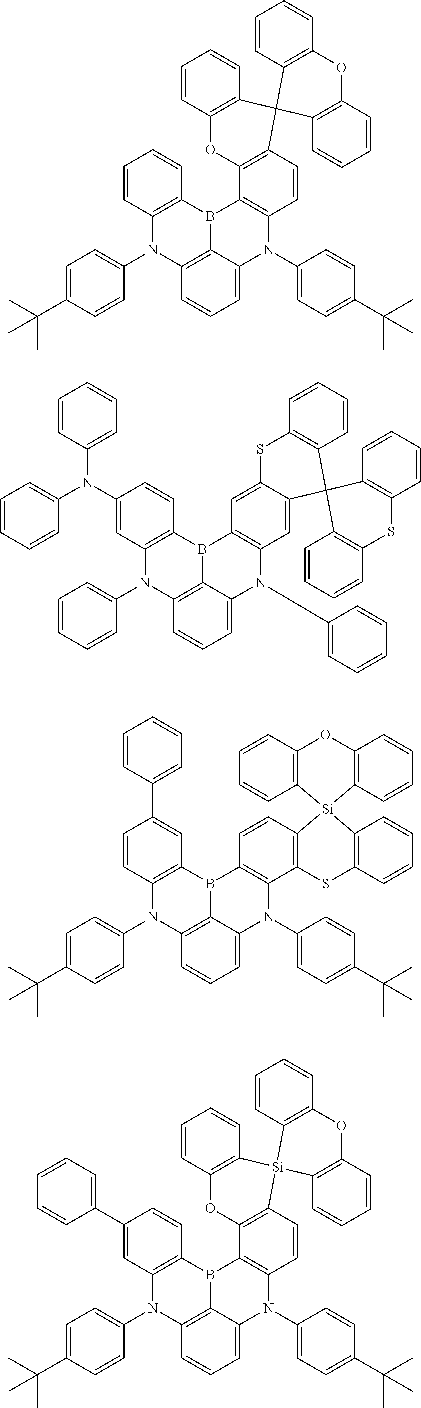

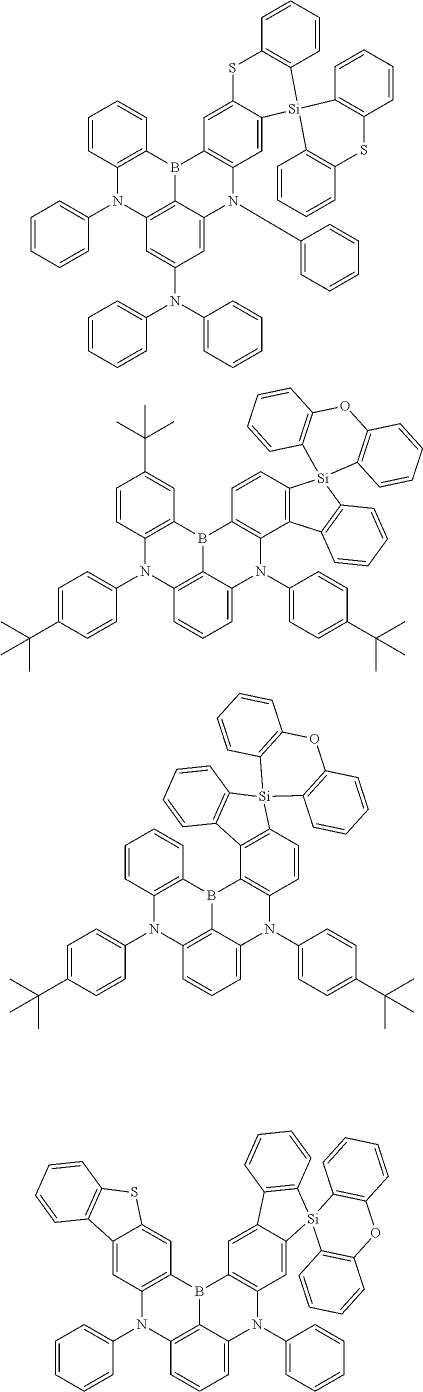

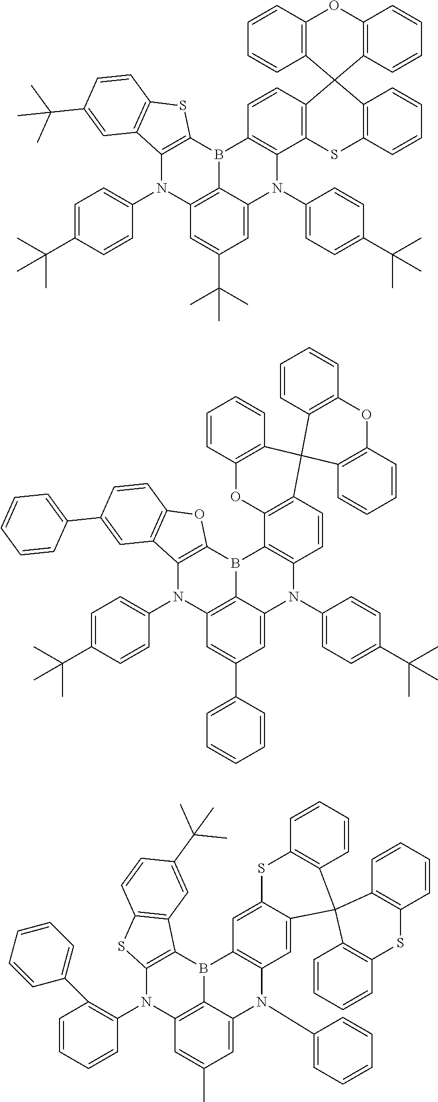 [SMILES: CC(C)(C)c1ccc(N2c3cc(C(C)(C)C)cc4c3B(c3ccc5c(c32)Sc2ccccc2C52c3ccccc3Oc3ccccc32)c2sc3ccc(C(C)(C)C)cc3c2N4c2ccc(C(C)(C)C)cc2)cc1 ; CC(C)(C)c1ccc(N2c3cc(-c4ccccc4)cc4c3B(c3oc5ccc(-c6ccccc6)cc5c3N4c3ccc(C(C)(C)C)cc3)c3c2ccc2c3Oc3ccccc3C23c2ccccc2Oc2ccccc23)cc1 ; Cc1cc2c3c(c1)N(c1ccccc1-c1ccccc1)c1sc4ccc(C(C)(C)C)cc4c1B3c1cc3c(cc1N2c1ccccc1)C1(c2ccccc2Sc2ccccc21)c1ccccc1S3]

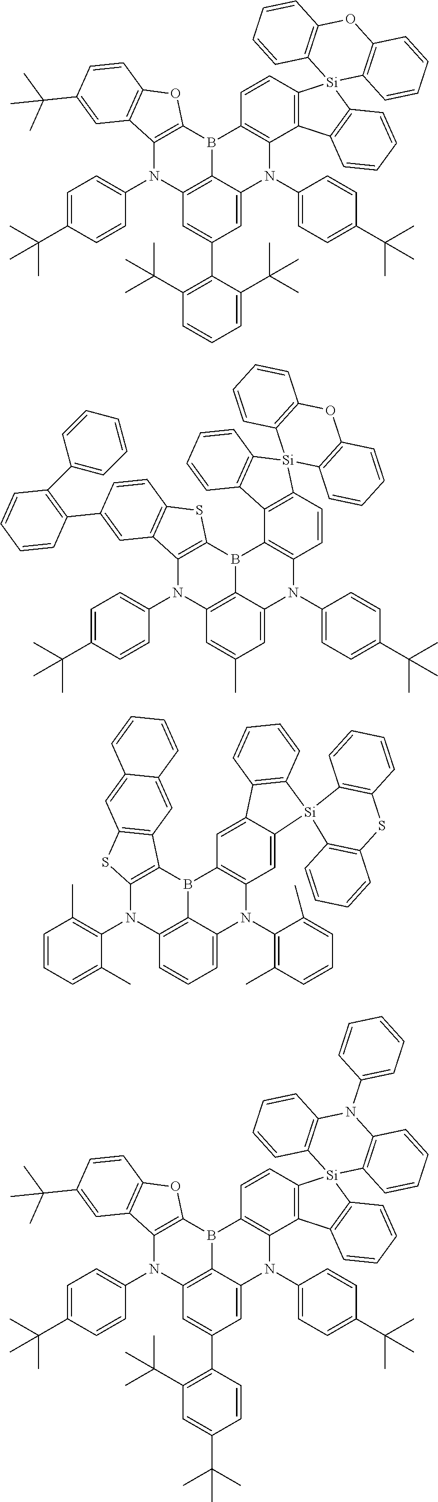

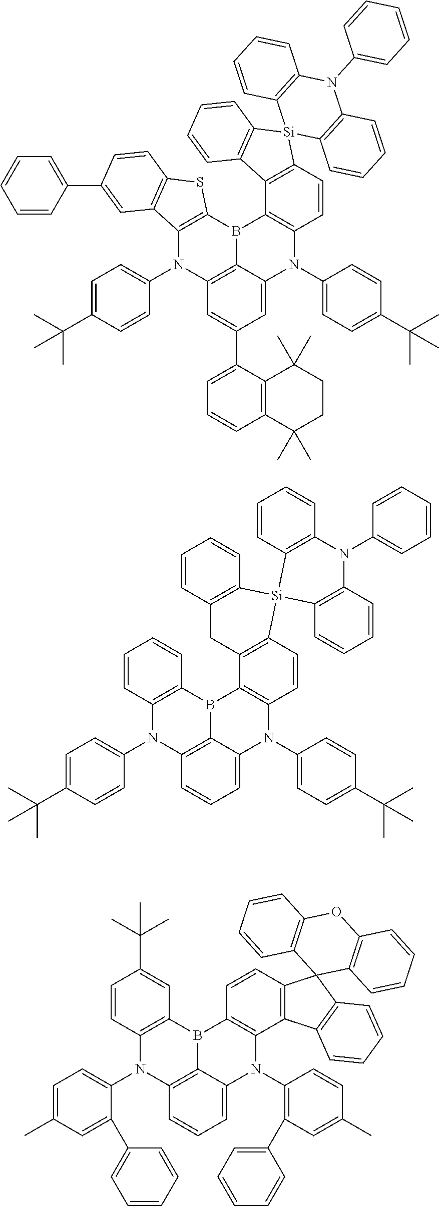

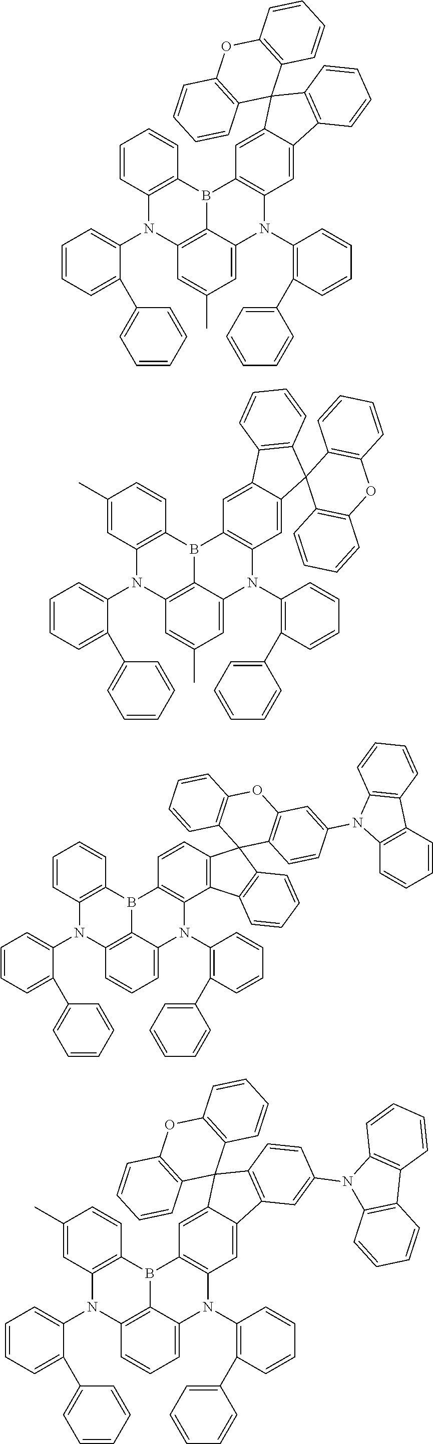

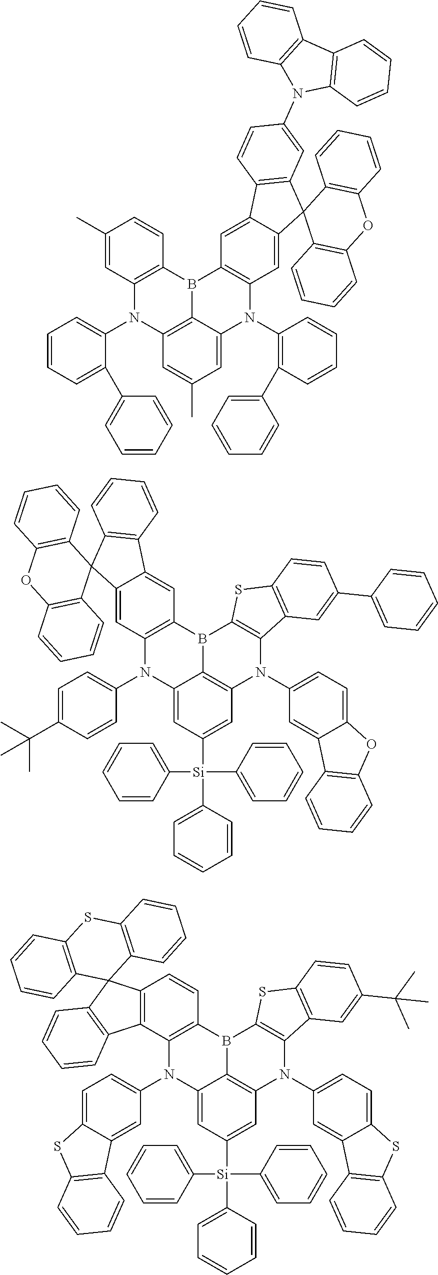

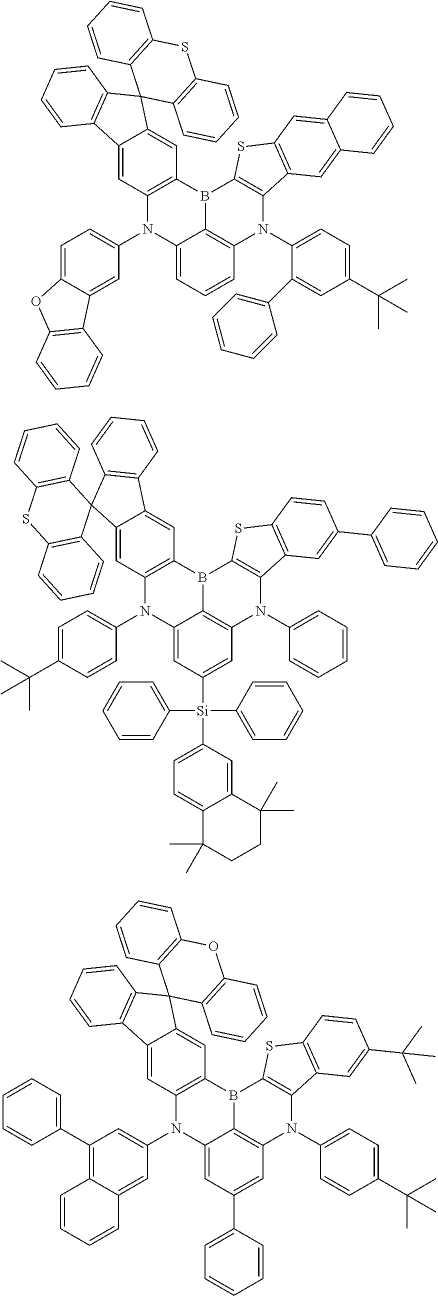

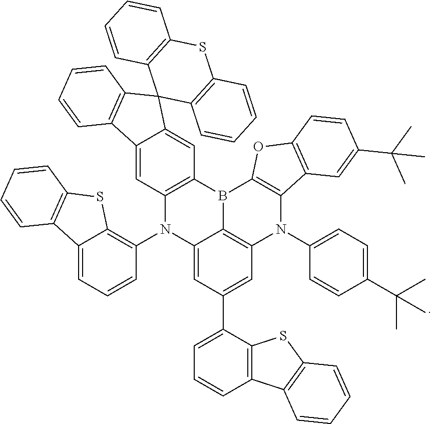 [SMILES: CC(C)(C)c1ccc(N2c3cc(-c4cccc5c4sc4ccccc45)cc4c3B(c3cc5c(cc3N4c3cccc4c3sc3ccccc34)-c3ccccc3C53c4ccccc4Sc4ccccc43)c3oc4ccc(C(C)(C)C)cc4c32)cc1]

11. An organic electroluminescent device comprising:
a first electrode;
a second electrode opposite to the first electrode; and
an organic layer interposed between the first electrode and the second electrode,
wherein the organic layer includes a light emitting layer including a host and a dopant, and
the light emitting layer includes at least one type of the organic compound represented by [Formula 1] according to claim 1.

12. The organic electroluminescent device according to claim 11, wherein the organic compound represented by [Formula 1] is used as the dopant in the light emitting layer.

13. The organic electroluminescent device according to claim 11, wherein the host in the light emitting layer includes at least one anthracene compound represented by the following [Formula 2]: 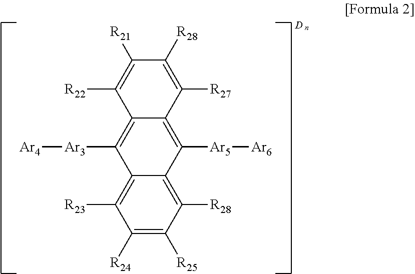
in [Formula 2],
R₂₁ to R₂₈ are the same as or different from each other, and each independently any one selected from hydrogen, deuterium, substituted or unsubstituted C₁-C₃₀ alkyl, substituted or unsubstituted C₂-C₃₀ alkynyl, substituted or unsubstituted C₂-C₃₀ alkenyl, substituted or unsubstituted C₆-C₅₀ aryl, substituted or unsubstituted C₃-C₅₀ cycloalkyl, substituted or unsubstituted C₂-C₅₀ heterocycloalkyl, substituted or unsubstituted C₂-C₅₀ heteroaryl, substituted or unsubstituted cyclic groups in which a C₃-C₃₀ aliphatic ring and a C₅-C₃₀ aromatic ring are fused together, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted amine, substituted or unsubstituted silyl, substituted or unsubstituted germanium, nitro, cyano and halogen;
Ar₃ and Ar₅ are the same as or different from each other, and each independently a single bond, or any one selected from substituted or unsubstituted C₆-C₃₀ arylene, substituted or unsubstituted C₅-C₃₀ heteroarylene, and substituted or unsubstituted divalent cyclic groups in which a C₃-C₃₀ aliphatic ring and a C₅-C₃₀ aromatic ring are fused together;
Ar₄ and Ar₆ are the same as or different from each other, and each independently any one selected from substituted or unsubstituted C₆-C₅₀ aryl, substituted or unsubstituted C₃-C₃₀ cycloalkyl, substituted or unsubstituted C₃-C₃₀ heterocycloalkyl, substituted or unsubstituted C₂-C₅₀ heteroaryl, and substituted or unsubstituted cyclic groups in which a C₃-C₃₀ aliphatic ring and a C₅-C₃₀ aromatic ring are fused together;
Dₙ means the number of hydrogen atoms of [Formula 2] replaced by deuterium atoms; and
n is an integer of 0 to 60.

14. The organic electroluminescent device according to claim 11, wherein the organic electroluminescent device is used in any one device selected from flat panel displays, flexible displays, monochromatic or white flat panel lighting systems, monochromatic or white flexible lighting systems, displays for automotives and aircraft, and displays for virtual or augmented reality.
